(19) United States
(12) Patent Application Publication
(10) Pub. No.: US 2026/0282649 A1
(43) Pub. Date: Sep. 17, 2026

(54) ORGANIC MIXTURES, AND USES THEREOF IN FIELD OF OPTOELECTRONICS

(71) Applicant: Zhejiang Brilliant Optoelectronic Technology Co.,Ltd., Taizhou (CN)

(72) Inventors: Junyou PAN, Taizhou (CN); Yanfeng LIU, Taizhou (CN)

(73) Assignee: Zhejiang Brilliant Optoelectronic Technology Co.,Ltd., Taizhou (CN)

(21) Appl. No.: 19/664,690

(22) Filed: Apr. 30, 2026

Related U.S. Application Data
(63) Continuation of application No. PCT/CN2024/129071, filed on Oct. 31, 2024.

(30) Foreign Application Priority Data
Nov. 1, 2023 (CN) 202311439799.X

(51) Int. Cl. H10K 50/12; C09K 11/06; H10K 85/10; H10K 85/40; H10K 85/60

(52) U.S. Cl. CPC H10K 50/12; C09K 11/06; H10K 85/1135; H10K 85/40; H10K 85/622; H10K 85/623; H10K 85/624; H10K 85/626; H10K 85/633; H10K 85/636; H10K 85/654; H10K 85/656; H10K 85/6572; H10K 85/6574; H10K 85/6576; H10K 85/658; C09K 2211/1022

(57) ABSTRACT

An organic mixture includes a first emitter E1 and a second emitter E2. A formulation contains an organic mixture, and at least one organic solvent. An optoelectronic device contains an organic mixture and a formulation. The optoelectronic device, in particular the organic electroluminescent device, includes the organic mixture in its light-emitting layer, thereby exhibiting long device lifetime and narrow emission spectrum.

### CROSS-REFERENCE TO RELATED APPLICATIONS

The present application is a continuation of International Application No. PCT/CN2024/129071, filed on Oct. 31, 2024, which claims priority to Chinese Patent Application No. 202311439799.X, filed on Nov. 1, 2023. All of the aforementioned applications are incorporated herein by reference in their entireties.

### TECHNICAL FIELD

The present disclosure relates to the field of organic optoelectronic material and device technology, and in particular to an organic mixture, a formulation, an optoelectronic device, and the applications thereof in the optoelectronic field.

### BACKGROUND

Due to the synthetic diversity, the low manufacturing cost, and the excellent optical and electrical properties, the organic light-emitting diodes (OLEDs) show great potential for optoelectronic device applications, such as flat-panel displays and lighting.

Luminescent material systems based on both fluorescence and phosphorescence have been developed to date. OLEDs employing conventional fluorescent/phosphorescent materials exhibit a wide emission spectrum, with their bottom-emission devices typically give emission with full width at half maximum (FWHM) exceeding 30 nm. In recent years, multi-resonance TADF materials have been successively reported, particularly OLED luminescent materials based on BN-fused ring systems. When used as the emissive layer to fabricate light-emitting devices, they demonstrate comparable or superior efficiency to conventional light-emitting materials while exhibiting narrow emission spectrum, which facilitates achieving wide color gamut for display applications.

The efficiency and lifetime performances of the OLEDs largely depend on the properties of the light-emitting materials. Currently, a class of multi-resonance thermally activated delayed fluorescence (MR-TADF) organic compounds containing fused ring systems with B and N atoms is commonly used as the light-emitting material. However, due to some drawbacks such as their extended structural conjugation, the lifetime of the corresponding OLEDs remains shorter than that of devices using conventional fluorescent materials as light-emitting materials.

Therefore, the current OLED device technology and its related light-emitting materials, especially blue-emitting materials, still require further improvement and development.

### SUMMARY

In one aspect, the present disclosure provides an organic mixture comprising a first emitter E1 and a second emitter E2, where 1) both the first emitter E1 and the second emitter E2 are fluorescent emitters; 2) the absorption spectrum of the second emitter E2 at least partially overlaps with the emission spectrum of the first emitter E1; 3) the FWHM of the emission spectrum of the second emitter E2 is ≤50 nm.

In addition or alternatively, the second emitter E2 is a compound represented by formula (1) or formula (2):

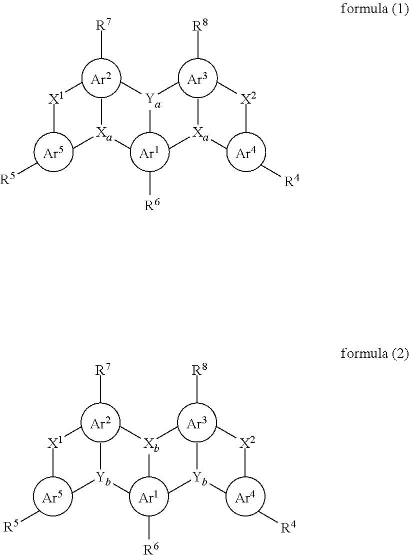

Where each of Ar¹ to Ar³ is independently selected from an aromatic group or a heteroaromatic group containing 5 to 24 ring atoms; each of Ar⁴ and Ar⁵ is independently selected from null, an aromatic group or a heteroaromatic group containing 5 to 24 ring atoms; when neither Ar⁴ nor Ar⁵ is null, each of Xₐ and X_{b} is independently selected from N, C(R⁹), or Si(R⁹); each of Yₐ and Y_{b} is independently selected from B, P═O, C(R⁹), or Si(R⁹); when Ar⁴ and/or Ar⁵ is null, each X_{b} is independently selected from N, C(R⁹), or Si(R⁹); each Yₐ is independently selected from B, P═O, C(R⁹), or Si(R⁹); each of Xₐ and Y_{b} is independently selected from N(R⁹), C(R⁹R¹⁰), Si(R⁹R¹⁰), C═O, O, C═N(R⁹), C═C(R⁹R¹⁰), P(R⁹), P(═O)R⁹, S, S═O, or SO₂; each of X¹ and X² is independently null or a bridging group; each of R⁴ to R¹⁰ is independently selected from —H, —D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, a disubstituted unit in any position of the above substituents, or any combination thereof, where one or more R⁴-R¹⁰ may form a monocyclic or polycyclic aliphatic or aromatic ring system with each other and/or with the rings bonded thereto.

In addition or alternatively, the first emitter E1 is selected from formula (1), formula (2), or aromatic amine derivatives. Further, the first emitter E1 is one of the compounds represented by formulas (1), (2), (3):

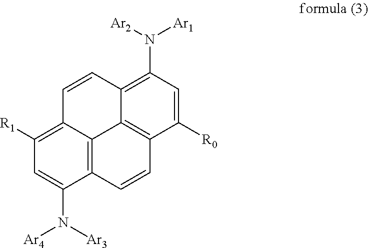

Where R₀—R₁ are defined identically as the above-mentioned R⁴; each of Ar₁ to Ar₄ is independently selected from an aromatic group or a heteroaromatic group containing 5 to 60 ring atoms.

In addition or alternatively, the organic mixture further comprises a host material H, the host material H is one of the compounds represented by formula (4-1) or formula (4-2), preferably is an anthracene derivative.

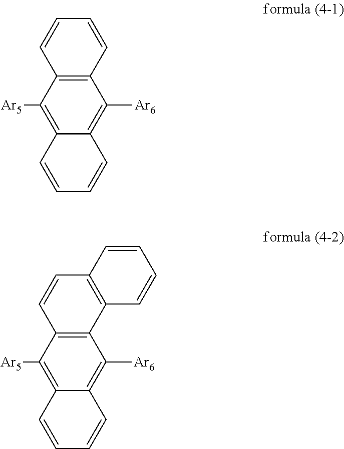

Where each of Ar₅ and Ar₆ is independently selected from an aromatic group or a heteroaromatic group containing 5 to 60 ring atoms.

In another aspect, the present disclosure also provides a formulation comprising an organic mixture as described herein, and at least one organic solvent.

In yet another aspect, the present disclosure further provides an optoelectronic device comprising an organic mixture as described herein.

In addition or alternatively, the optoelectronic device is an organic electroluminescent device comprising a substrate, an anode, an emissive layer, and a cathode in sequence, the emissive layer comprises at least one organic mixture as described herein, or the emissive layer is formed by using a formulation as described herein.

The emissive layer of the organic electroluminescent device comprises two types of emitters: a conventional fluorescent material (i.e., first emitter E1) and a BN compound with a narrow emission spectrum (i.e., second emitter E2). The first emitter E1 exhibits a long device lifetime. The absorption spectrum of the second emitter E2 at least partially overlaps with the emission spectrum of the first emitter E1, which enables Forster resonance energy transfer (FRET) between the first emitter E1 and the second emitter E2, thereby combining the advantages of both emitters to simultaneously achieve a long device lifetime and a narrow emission spectrum.

### BRIEF DESCRIPTION OF THE DRAWINGS

FIG. 1 shows the absorption (Abs) and emission (PL) spectrums of the compound E2-1.

FIG. 2 shows the absorption (Abs) and emission (PL) spectrums of the compound E2-2.

FIG. 3 shows the absorption (Abs) and emission (PL) spectrums of the compound E2-3.

FIG. 4 shows the absorption (Abs) and emission (PL) spectrums of the compound E2-4.

FIG. 5 shows the absorption (Abs) and emission (PL) spectrums of the compound E2-5.

FIG. 6 shows the absorption (Abs) and emission (PL) spectrums of the compound E2-9.

FIG. 7 shows the absorption (Abs) and emission (PL) spectrums of the compound E1-1, and the absorption (Abs) spectrum of the compound E2-1.

FIG. 8 shows the absorption (Abs) and emission (PL) spectrums of the compound E1-2, and the absorption (Abs) spectrum of the compound E2-1.

FIG. 9 shows the absorption (Abs) and emission (PL) spectrums of the compound E1-2, and the absorption (Abs) spectrum of the compound E2-2.

FIG. 10 shows the absorption (Abs) and emission (PL) spectrums of the compound E1-2, and the absorption (Abs) spectrum of the compound E2-3.

FIG. 11 shows the absorption (Abs) and emission (PL) spectrums of the compound E1-2, and the absorption (Abs) spectrum of the compound E2-4.

FIG. 12 shows the absorption (Abs) and emission (PL) spectrums of the compound E1-2, and the absorption (Abs) spectrum of the compound E2-5.

FIG. 13 shows the absorption (Abs) and emission (PL) spectrums of the compound E1-3, and the absorption (Abs) spectrum of the compound E2-5.

FIG. 14 shows the absorption (Abs) and emission (PL) spectrums of the compound E1-3, and the absorption (Abs) spectrum of the compound E2-9.

### DETAILED DESCRIPTION OF THE EMBODIMENTS

The present disclosure provides an organic mixture, a formulation, an optoelectronic device (especially an organic electroluminescent device), and the applications thereof in the optoelectronic field.

In order to facilitate understanding of the present disclosure, the present disclosure will be described in detail below with reference to the accompanying drawings, in which the preferred embodiments of the present disclosure are shown. The present disclosure may be embodied in many different forms and is not limited to the embodiments described herein.

Rather, these embodiments are provided so that the understanding of the disclosure of the present disclosure will be more thorough.

Unless otherwise defined, all technical and scientific terms used herein have the same meaning as commonly understood by one of ordinary skill in the art belonging to the present disclosure. The terms used herein in the description of the present disclosure are used only for the purpose of describing specific embodiments and are not intended to be limiting of the present disclosure. As used herein, the term “and/or” includes any and all combinations of one or more of the relevant listed items.

In the description of the embodiments, the numerical range indicated by using “~” indicates a range including numerical values described before and after “~” as a minimum value and a maximum value, respectively.

In the description of the embodiments, the substituent may further be substituted by another substituent. The term “substituent a” may refer to group a being substituted by a substituent, where the substituent may be either unsubstituted or further substituted by at least one substituent.

As used herein, the term “and/or” describes the associative relationship between related objects, indicating that three possible relationships may exist. For example, “A and/or B” may represent the situation where A exists alone, A and B exist simultaneously, or B exists alone. Here, A and B may be singular or plural. The character “/” herein generally indicates that the related objects before and after the character form an “or” relationship.

As used herein, the term “at least one” refers to one or more, the term “a plurality of” refers to two or more. The phrase “at least one of the following” or similar expressions refers to any combination of the listed items, including any single item or any combination of multiple items. For example, “at least one of a, b, or c” or “at least one of a, b, and c” may represent: a, b, c, a-b (i.e., a and b), a-c, b-c, or a-b-c, where a, b, and c may each be a single element or multiple elements.

It should be understood that, in various embodiments of the present disclosure, the numerical order of processes does not dictate their execution sequence. Some or all steps may be executed in parallel or in any sequential order. The execution order of each process shall be determined by its function and inherent logic, and shall in no way limit the implementation process of the embodiments as described herein.

The terms used in the embodiments of the present disclosure are solely for the purpose of describing specific embodiments and are not intended to limit the scope of the present disclosure. The singular forms “a”, “an”, “the”, and “as described” as used in the embodiments of the present disclosure and in the claims are to be construed to include plural references unless the context clearly dictates otherwise.

The term “OLED” is the abbreviation for “Organic Light-Emitting Diode”, which refers to an organic electroluminescent diode, also known as organic electroluminescent display or organic electroluminescence semiconductor. OLED is a current-driven organic light-emitting device, whose luminescence results from charge carrier injection and recombination, with the luminous intensity being directly proportional to the injected current. The holes generated at the anode and electrons generated at the cathode of an OLED moves under electric field and inject into the hole-transport layer and the electron-transport layer respectively, before migrating toward the emissive layer. Upon meeting in the emissive layer, these charge carriers form excitons that excite the emissive molecules, ultimately resulting in visible light emission.

The term “TADF” is the abbreviation for “Thermally Activated Delayed Fluorescence”, which essentially refers to a reverse intersystem crossing (RISC) from triplet excited state to the singlet excited state through thermal activation, with the energy level of triplet excited state and the singlet excited state of a molecule being close. Conventional luminescence includes fluorescence and phosphorescence, which represent radiative transition from excited singlet and triplet states to the ground state, respectively. The significant energy gap between the lowest singlet state and lowest triplet state typically prevents excitons from returning to the singlet states once converted to triplet states through intersystem crossing (ISC).

As used herein, the terms “host material”, “matrix material” have the same meaning, and they are interchangeable with each other.

As used herein, the terms “metal organic clathrate”, “metal organic complex”, and “organometallic complex” have the same meaning, and they are interchangeable with each other.

As used herein, the terms “formulation”, “printing ink”, and “ink” have the same meaning, and they are interchangeable with each other.

In embodiments of the present disclosure, the energy level structure of the organic materials, singlet energy level (E_{S1}), triplet energy level (E_{T1}), highest occupied molecular orbital (HOMO), and lowest unoccupied molecular orbital (LUMO) play key roles. The determination of these energy levels is introduced as follows.

HOMO and LUMO energy levels can be measured by optoelectronic effect, for example, by XPS (X-ray photoelectron spectroscopy), UPS (UV photoelectron spectroscopy), or by cyclic voltammetry (hereinafter referred to as CV). Recently, quantum chemical simulation methods, such as density functional theory (hereinafter referred to as DFT), have become effective methods for calculating the molecular orbital energy levels.

The singlet energy level E_{S1} of the organic materials can be determined by the emission spectrum. The triplet energy level E_{T1} of the organic materials can be measured by low-temperature time-resolved spectroscopy. E_{S1} and E_{T1} can also be calculated by quantum simulation (for example, by time-dependent DFT), for instance with the commercial software Gaussian 09W (Gaussian Inc.), the specific simulation method can be found in CN110892543B or as described in the following embodiments. ΔE_{ST} is defined as (E_{S1}-E_{T1}).

It should be noted that the absolute values of HOMO, LUMO, E_{S1} and E_{T1} may depend on the measurement method or calculation method used. Even for the same method, different ways of evaluation, for example, using either the onset or peak value of a CV curve as reference, may result in different HOMO/LUMO values. Therefore, reasonable and meaningful comparison should be carried out by employing the same measurement and evaluation methods.

In the embodiments of the present disclosure, the values of HOMO, LUMO, E_{S1} and E_{T1} are based on the time-dependent DFT simulation, which however should not exclude the applications of other measurement or calculation methods.

In the disclosure, (HOMO-1) is defined as the energy level of the second highest occupied molecular orbital, (HOMO-2) is defined as the energy level of the third highest occupied molecular orbital, and so on. (LUMO+1) is defined as the energy level of the second lowest unoccupied molecular orbital, (LUMO+2) is defined as the energy level of the third lowest occupied molecular orbital, and so on.

In one aspect, the present disclosure provides an organic mixture comprising a first emitter E1 and a second emitter E2, where 1) both the first emitter E1 and the second emitter E2 are fluorescent emitters; 2) the absorption spectrum of the second emitter E2 at least partially overlaps with the emission spectrum of the first emitter E1; 3) the FWHM of the emission spectrum of the second emitter E2 is ≤50 nm.

In some embodiments, the absorption spectrum of the second emitter E2 is on the short wavelength side of the emission spectrum of the first emitter E1,

In some embodiments, the absorption spectrum of the second emitter E2 is on the long wavelength side of the emission spectrum of the first emitter E1,

In some embodiments, the FWHM of the emission spectrum of the second emitter E2≤45 nm, preferably ≤40 nm, more preferably ≤35 nm, and most preferably ≤30 nm.

In some embodiments, the photoluminescence quantum yield (PLQY) of the second emitter E2 and/or the first emitter E1≥60%, preferably ≥65%, more preferably ≥70%, further preferably ≥80%, and most preferably ≥85%.

In some embodiments, the second emitter E2 is a compound represented by formula (1) or formula (2), more preferably by formula (1):

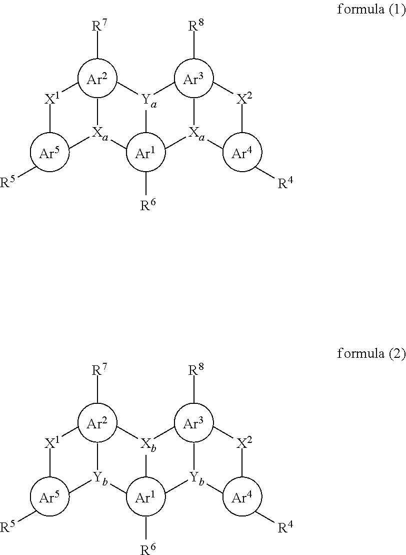

Where each of Ar¹ to Ar³ is independently selected from an aromatic group or a heteroaromatic group containing 5 to 24 ring atoms; each of Ar⁴ and Ar⁵ is independently selected from null, an aromatic group or a heteroaromatic group containing 5 to 24 ring atoms; when neither Ar⁴ nor Ar⁵ is null, each of Xₐ and X_{b} is independently selected from N, C(R⁹), or Si(R⁹); each of Yₐ and Y_{b} is independently selected from B, P═O, C(R⁹), or Si(R⁹); when Ar⁴ and/or Ar⁵ is null, each X_{b} is independently selected from N, C(R⁹), or Si(R⁹); each Yₐ is independently selected from B, P═O, C(R⁹), or Si(R⁹); each of Xₐ and Y_{b} is independently selected from N(R⁹), C(R⁹R¹⁰), Si(R⁹R¹⁰), C═O, O, C═N(R⁹), C═C(R⁹R¹⁰), P(R⁹), P(═O)R⁹, S, S═O, or SO₂; each of X¹ and X² is independently null or a bridging group; each of R⁴ to R¹⁰ is independently selected from —H, —D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, a disubstituted unit in any position of the above substituents, or any combination thereof, where one or more R⁴-R¹⁰ may form a monocyclic or polycyclic aliphatic or aromatic ring system with each other and/or with the rings bonded thereto.

In some embodiments, each of R⁴ to R¹⁰ is independently selected from —H, —D, a C₁-C₁₀ linear alkyl group, a C₁-C₁₀ linear haloalkyl group, a C₁-C₁₀ linear alkoxy group, a C₁-C₁₀ linear thioalkoxy group, a C₃-C₁₀ branched/cyclic alkyl group, a C₃-C₁₀ branched/cyclic haloalkyl group, a C₃-C₁₀ branched/cyclic alkoxy group, a C₃-C₁₀ branched/cyclic thioalkoxy group, a C₃-C₁₀ branched/cyclic silyl group, a C₁-C₁₀ ketone group, a C₂-C₁₀ alkoxycarbonyl group, a C₇-C₁₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, —NO₂, —CF₃, —Cl, —Br, —F, —I, a cross-linkable group, a substituted/unsubstituted aromatic or heteroaromatic group containing 5 to 20 ring atoms, an aryloxy or heteroaryloxy group containing 5 to 20 ring atoms, an arylamine or heteroarylamine group containing 5 to 20 ring atoms, or any combination thereof, where one or more R⁴-R¹⁰ may form a monocyclic or polycyclic aliphatic or aromatic ring system with each other and/or with the rings bonded thereto.

In some embodiments, the second emitter E2 is one of the compounds represented by formula (1a) or formula (2a), more preferably by formula (1a):

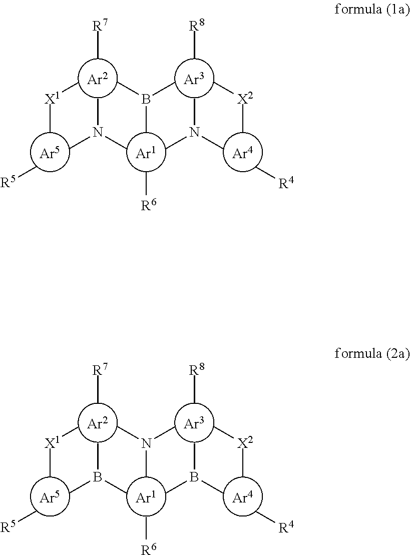

Where Ar¹-Ar³, Ar⁴—Ar⁵, X¹, X², and R⁴-R⁸ are defined identically as described herein.

In some embodiments, each of X¹ and X² is independently O or S; in some embodiments, each of X¹ and X² is O.

In some embodiments, at least one of X¹ or X² is null; particularly preferably, both are null, in which case the second emitter E2 is one of the compounds represented by formula (1b) or formula (2b), more preferably by formula (1b):

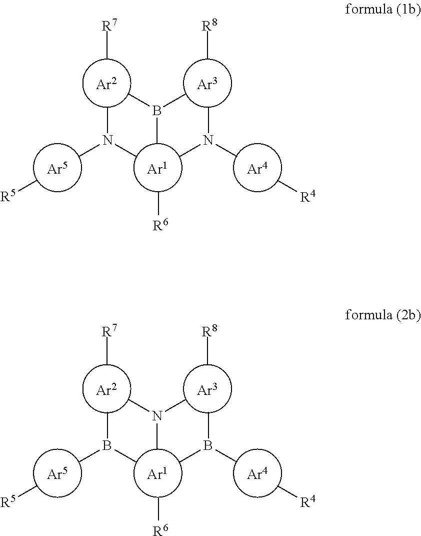

Where Ar¹—Ar³, Ar⁴—Ar⁵, and R⁴-R⁸ are defined identically as described herein.

In some embodiments, at least one of X¹ or X² is a single bond; particularly preferably, both are single bonds, in which case the second emitter E2 is one of the compounds represented by formula (1c) or formula (2c), more preferably by formula (1c):

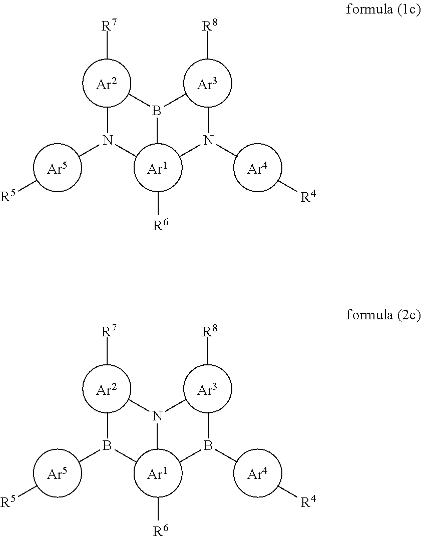

Where Ar¹—Ar³, Ar⁴—Ar⁵, and R⁴-R⁸ are defined identically as described herein.

In some embodiments, X¹, X² at each occurrence are the same or different di-bridging group; the preferred di-bridging group is selected from the group consisting of:

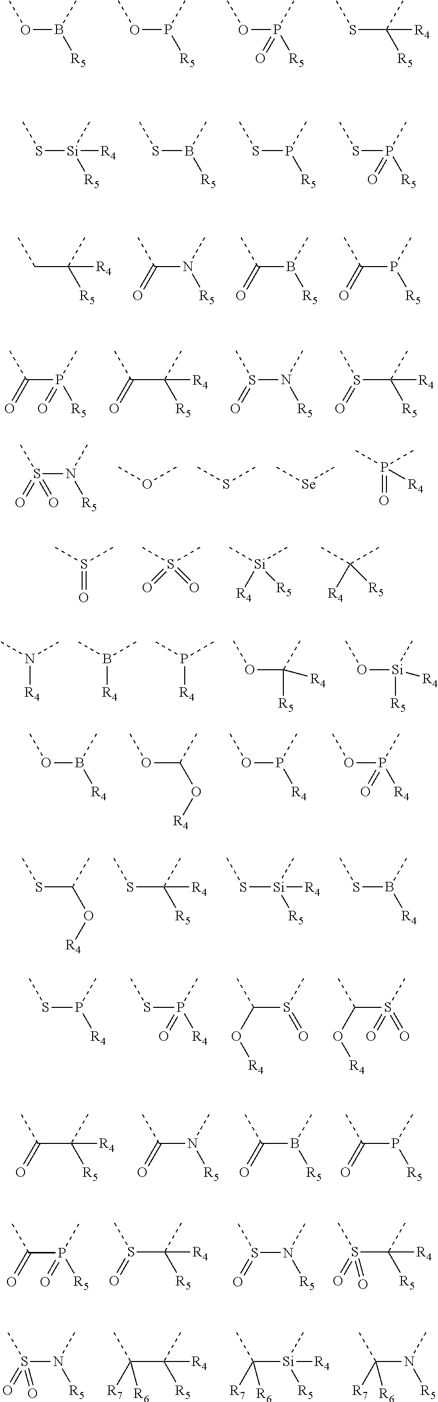

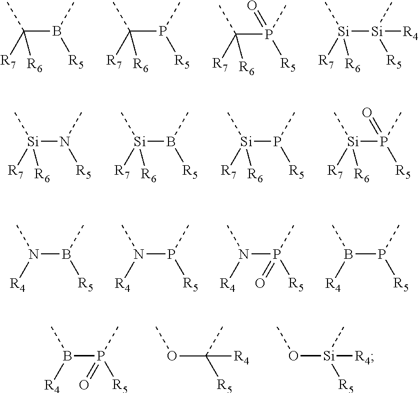

Where R₄, R₅, R₆, and R₇ are defined identically as the above-mentioned R⁴, and the dashed bonds refer to the covalent bonds connecting to the adjacent structural units.

For the purposes of the present disclosure, the aromatic ring system contains 5 to 10 carbon atoms in the ring system, the heteroaromatic ring system contains 1 to 10 carbon atoms and at least one heteroatom in the ring system, provided that the total number of carbon atoms and heteroatoms is at least 4. The heteroatoms are preferably selected from Si, N, P, O, S and/or Ge, particularly preferably selected from Si, N, P, O and/or S. For the purposes of the present disclosure, the aromatic or heteroaromatic ring systems contain not only aromatic or heteroaromatic groups, but also have a plurality of aryl or heteroaryl groups linked by short non-aromatic units (<10% of non-H atoms, preferably <5% of non-H atoms, such as C, N or O atoms). Therefore, a system such as 9,9′-spirobifluorene, 9,9-diarylfluorene, triarylamine, diaryl ether, and the like is also considered to be aromatic ring systems for the purposes of this disclosure.

For the purposes of the present disclosure, the any H atom on the first emitter E1 or the second emitter E2 may be optionally substituted with R⁴. R⁴ is defined as described herein, which may be preferably selected from: (1) a C₁-C₁₀ alkyl group, particularly preferably selected from the following groups: methyl, ethyl, n-propyl, isopropyl, cyclopropyl, n-butyl, isobutyl, sec-butyl, t-butyl, cyclobutyl, 2-methylbutyl, n-pentyl, n-hexyl, cyclohexyl, n-heptyl, cycloheptyl, n-octyl, cyclooctyl, 2-methylheptyl, trifluoromethyl, pentafluoroethyl, 2,2,2-trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, or octenyl; (2) a C₁-C₁₀ alkoxy group, particularly preferably methoxy, ethoxy, n-propoxy, isopropoxy, n-butoxy, isobutoxy, sec-butoxy, tert-butoxy, or 2-methylbutoxy; (3) a C₂-C₁₀ aryl or heteroaryl group, which may be monovalent or divalent depending on the application, and in each case can also be optionally substituted with R⁴ and may be attached to an aromatic or heteroaromatic ring at any desired position, particularly preferably selected from the following: benzene, naphthalene, anthracene, dihydropyrene, chrysene, pyrene, fluoranthene, naphthacene, pentacene, benzopyrene, furan, benzofuran, isobenzofuran, dibenzofuran, thiophene, benzothiophene, isobenzothiophene, thiofluorene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenimidazole, pyridimidazole, pyrazine-imidazole, quinoxaline-imidazole, oxazole, benzoxazole, naphthoxazole, anthracenazole, phenoxazole, isoxazole, 1,2-thiazole, 1,3-thiazole, benzothiazole, pyridazine, benzopyridazine, pyrimidine, benzopyrimidine, quinoxaline, pyrazine, phenazine, 1,5-naphthyridine, azocarbazole, benzocholine, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thinadiazole, 1,2,4-thiadiazole, 1,2,5-thiadiazole, 1,3,4-thiadiazole, 1,3,5-triazine, 1,2,4-triazine, 1,2,3-triazine, tetrazole. 1,2,4,5-tetrazine, 1,2,3,4-tetrazine, 1,2,3,5-tetrazine, purine, pteridine, indolizine, or benzothiadiazole. For the purposes of the present disclosure, aromatic and heteroaromatic ring systems are particularly considered to be, in addition to the above-mentioned aryl and heteroaryl groups, also refer to biphenylene, terphenylene, fluorene, spirobifluorene, dihydrophenanthrene, tetrahydropyrene, cis-indenofluorene, or trans-indenofluorene.

In some embodiments, Ar₁—Ar⁵ of the second emitter E2 at each occurrence are the same or different and are each independently selected from the group consisting of aromatic or heteroaromatic groups with 5 to 20 ring atoms; preferably 5 to 18 ring atoms, more preferably 5 to 15 ring atoms; and most preferably 5 to 10 ring atoms; they may be unsubstituted or substituted with one or two R⁴. Preferred aromatic or heteraromatic groups include benzene, naphthalene, anthracene, phenanthrene, pyridine, pyrene, or thiophene.

In some embodiments, each of Ar¹ to Ar⁵ is independently selected from the group consisting of:

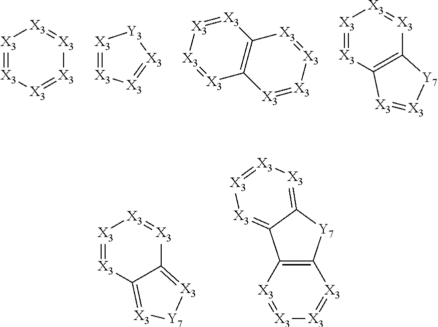

Where each X₃ is independently CR¹¹ or N; each Y₇ is independently selected from NR¹¹, CR¹²R¹³, SiR¹⁴R¹⁵, C(═O), S, or O; R^{D}, R¹², R¹³, R¹⁴, and R¹⁵ are defined identically as the above-mentioned R⁴.

Further, each of Ar¹ to Ar⁵ is independently selected from one of the following structural formulas or any combination thereof, which can be further arbitrarily substituted:

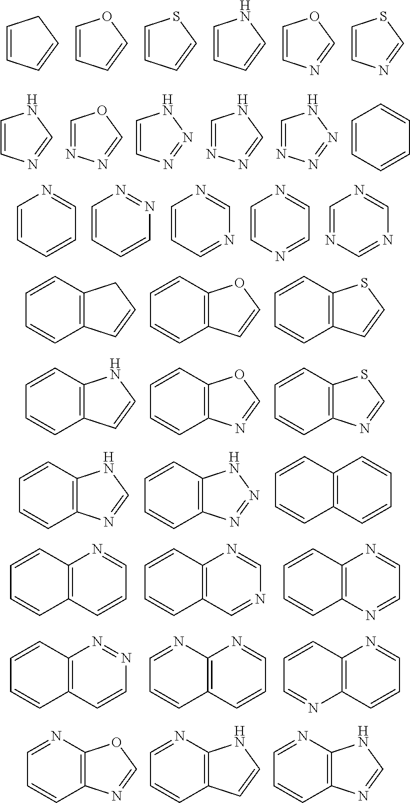

In some embodiments, each of Ar¹ to Ar⁵ is a phenyl group.

In some embodiments, at least one of Ar⁴ or Ar⁵ is null; particularly preferably, both are null, in which case the second emitter E2 is selected from the group consisting of:

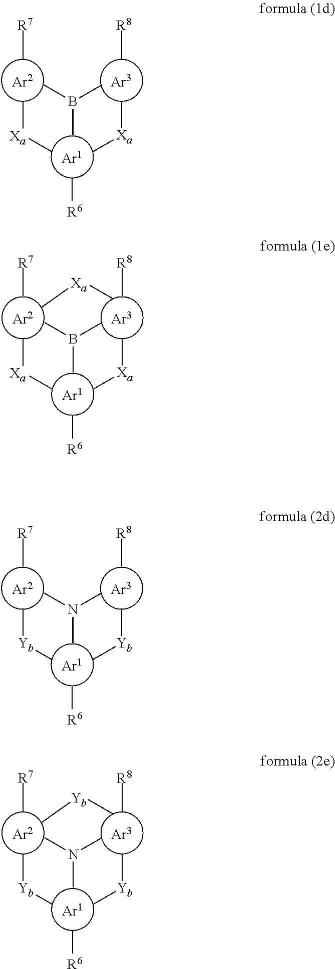

Where Ar¹—Ar³, Xₐ, Y_{b}, and R⁶—R⁸ are defined identically as described herein.

Preferably, each Xₐ in the formulas (1d) and (1e) is independently selected from N(R⁹), C(R⁹R¹⁰), Si(R⁹R¹⁰), O, or S.

Preferably, each Y_{b} in the formulas (2d) and (2e) is independently selected from C═O, O, S, P(═O)R⁹, S═O, or SO₂; and particularly preferably from C═O.

In some embodiments, the second emitter E2 is selected from the group consisting of:

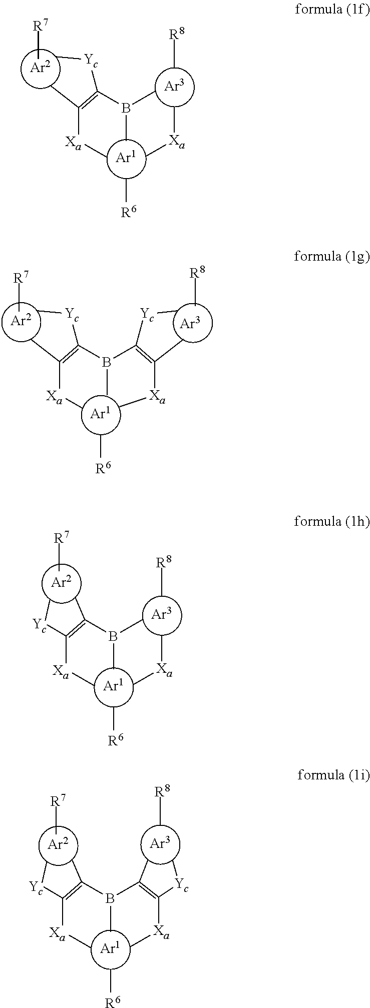

Where each Y_{c} is independently O or S; Ar¹—Ar³, Xₐ, and R⁶—R⁸ are defined identically as described herein.

In some embodiments, each of Ar² and Ar³ is preferably selected from the following structural units, which can be further arbitrarily substituted:

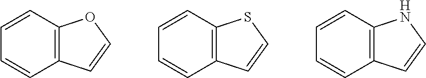

In some embodiments, in the structural units represented by formulas (1)-(1i), (2)-(2e), where R⁴-R⁸ on multiple occurrences may be the same or different, comprising the following structural units or any combination thereof:

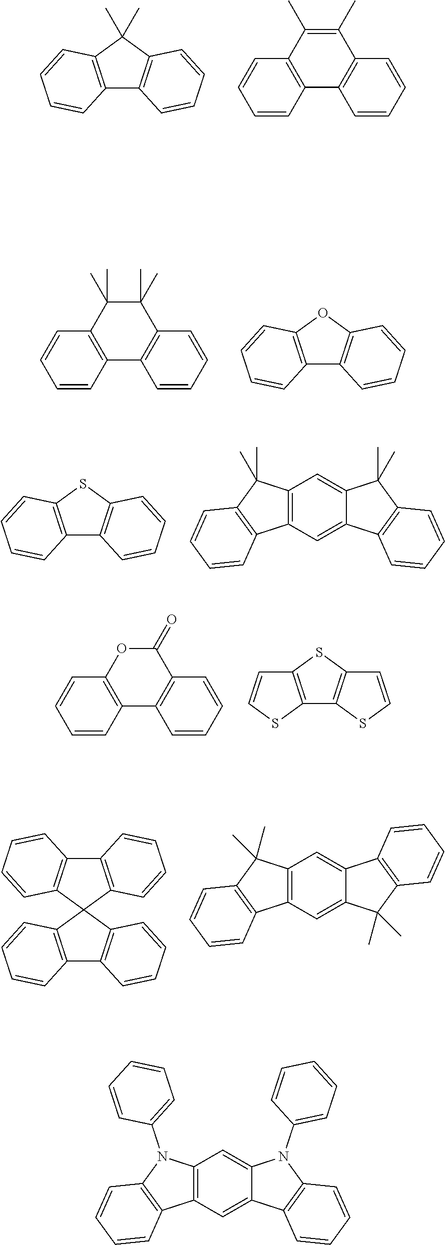

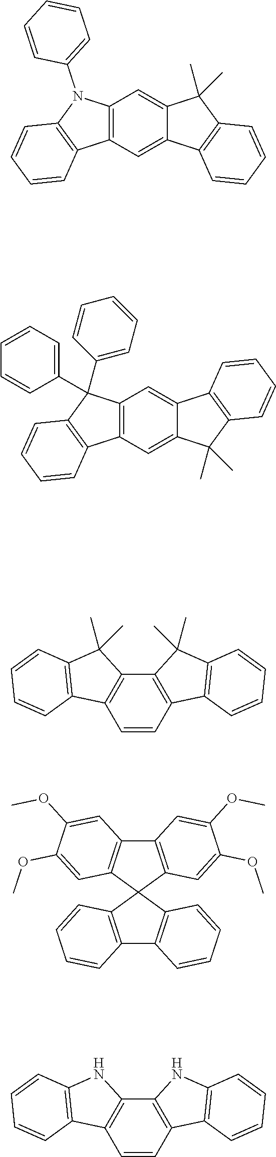

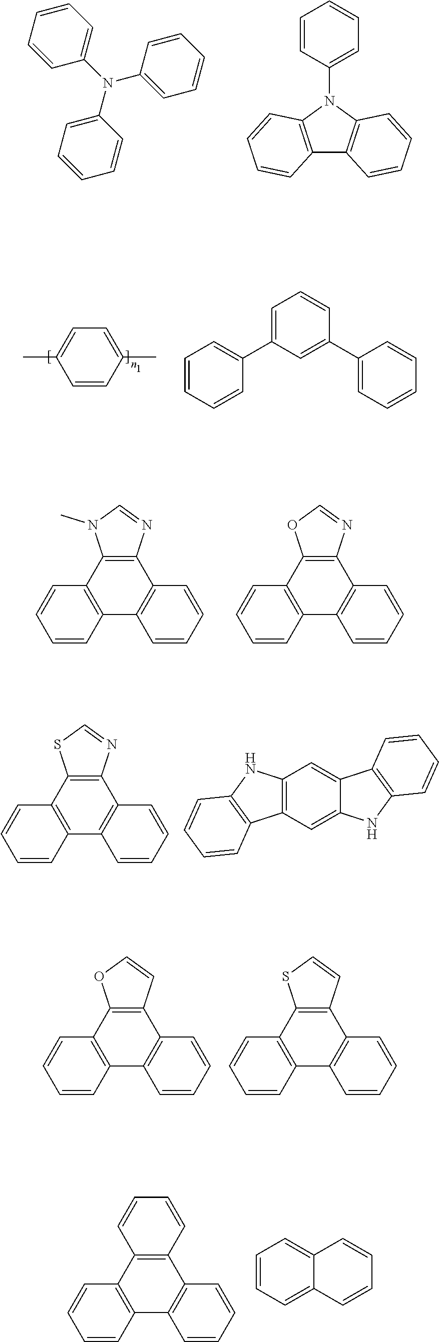

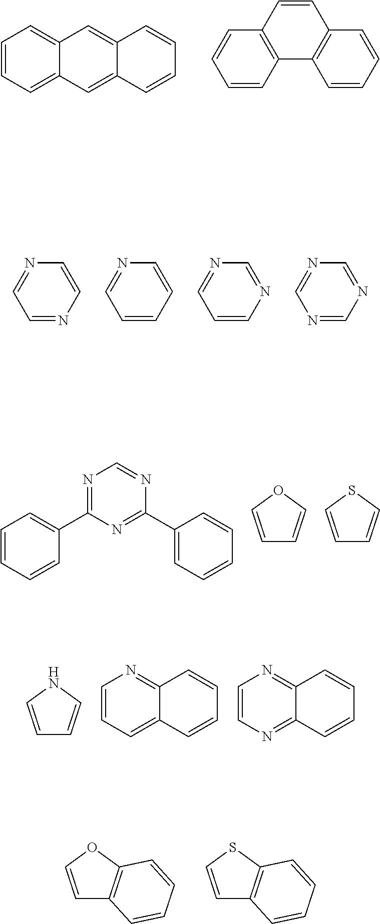

Where n₁ is an integer from 1 to 4.

In some embodiments, the second emitter E2 is selected from the group consisting of:

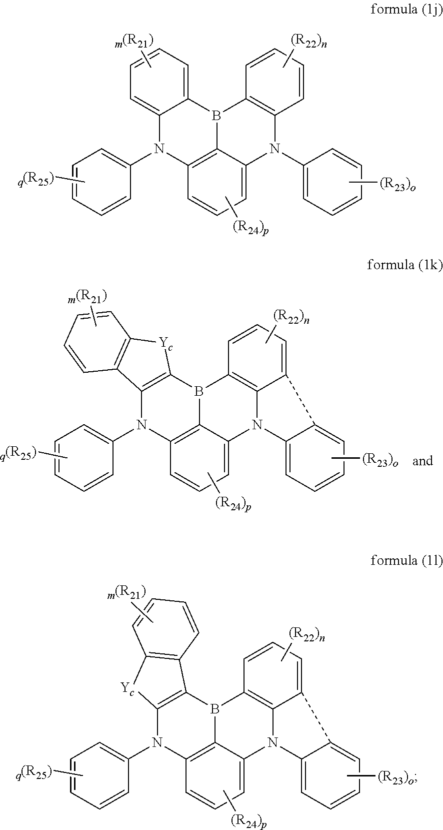

Where each Y_{c} is defined identically as described herein; each of R₂₁ to R₂₅ is independently selected from —D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, —NO₂, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, where one or more R₂₁—R₂₅ may form a monocyclic or polycyclic aliphatic or aromatic ring system with each other and/or with the rings bonded thereto; m and n are are integers from 0 to 4, independently; o and q are are integers from 0 to 5, independently; p is an integer from 0 to 3; each dotted line independently represents null or a single bond.

Preferably, each of R₂₁ to R₂₅ is independently selected from —D, a C₁-C₁₀ linear alkyl group, a C₁-C₁₀ linear alkoxy group, a C₁-C₁₀ linear thioalkoxy group, a C₃-C₁₀ branched/cyclic alkyl group, a C₃-C₁₀ branched/cyclic alkoxy group, a C₃-C₁₀ branched/cyclic thioalkoxy group, a C₃-C₁₀ branched/cyclic silyl group, a C₁-C₁₀ ketone group, a C₂-C₁₀ alkoxycarbonyl group, a C₇-C₁₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, —NO₂, —CF₃, —Cl, —Br, —F, a cross-linkable group, a substituted/unsubstituted aromatic or heteroaromatic group containing 5 to 20 ring atoms, an aryloxy or heteroaryloxy group containing 5 to 20 ring atoms, or any combination thereof, where one or more R₂₁—R₂₅ may form a monocyclic or polycyclic aliphatic or aromatic ring system with each other and/or with the rings bonded thereto.

In some embodiments, the second emitter E2 is selected from the group consisting of:

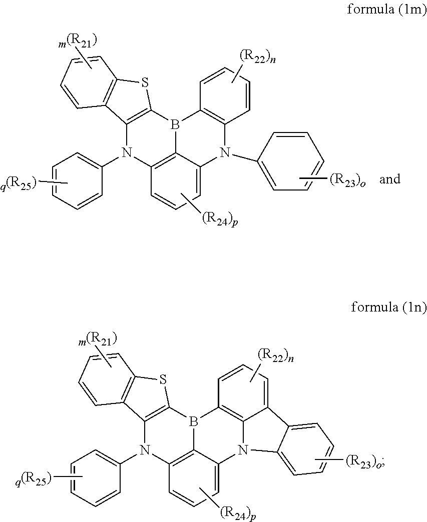

Where R₂₁, R₂₂, R₂₃, R₂₄, R₂₅, m, n, o, q, and p are defined identically as described herein.

In some embodiments, the second emitter E2 is selected from the group consisting of:

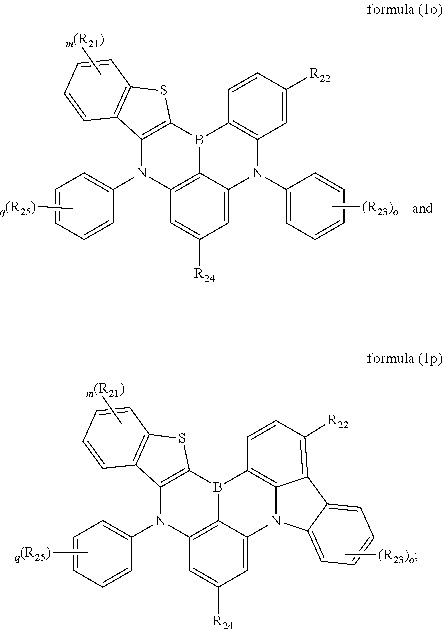

Where R₂₁, R₂₂, R₂₃, R₂₄, R₂₅, m, o, and q are defined identically as described herein.

In some embodiments, R₂₂ and R₂₄ are the same or different in formulas (1m), (1n), (1o), and (1p), and are each independently selected from an aromatic group or a heteroaromatic group with 5 to 40 ring atoms; preferably 6 to 40 ring atoms; more preferably 6 to 30 ring atoms; and most preferably 6 to 20 ring atoms.

In some embodiments, R₂₂ and R₂₄ are the same or different in formulas (1m), (1n), (1o), and (1p), and are each independently a C₁-C₂₀ linear alkyl group or a C₁-C₂₀ ketone group.

In some embodiments, R₂₂ and R₂₄ are the same or different in formulas (1m), (1n), (1o), and (1p), and are each independently selected from an electron-donating group, an aromatic group consisting of benzene rings, a branched aliphatic group with large steric hindrance, and/or any combination thereof.

In some embodiments, R₂₂ and R₂₄ are the same or different in formulas (1m), (1n), (1o), and (1p), and are each independently selected from the group consisting of:

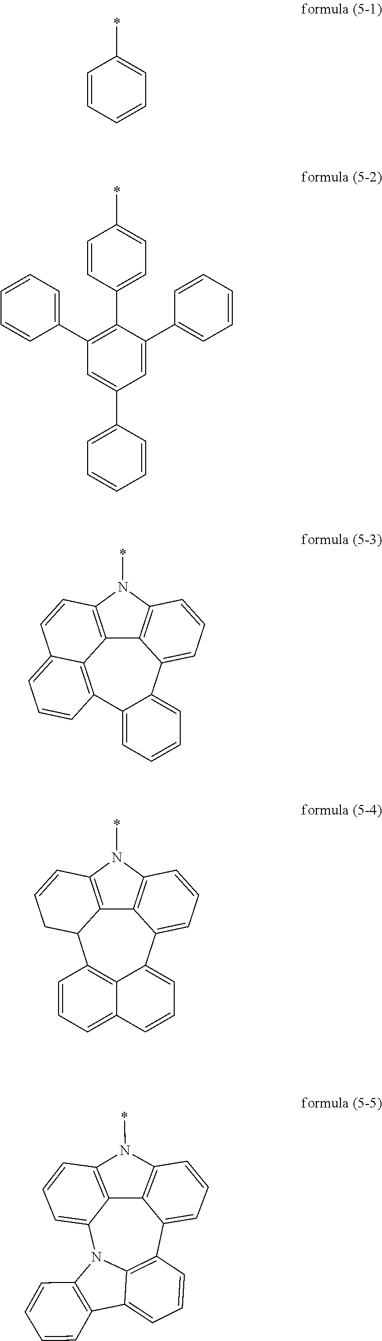 [SMILES: *c1ccccc1 ; *c1ccc(-c2c(-c3ccccc3)cc(-c3ccccc3)cc2-c2ccccc2)cc1 ; *n1c2cccc3c2c2c4c(cccc4ccc21)-c1ccccc1-3 ; *n1c2c3c4c(cccc41)-c1cccc4cccc(c14)C3CC=C2 ; *n1c2cccc3c4cccc5c6ccccc6n(c6cccc1c6c32)c45]

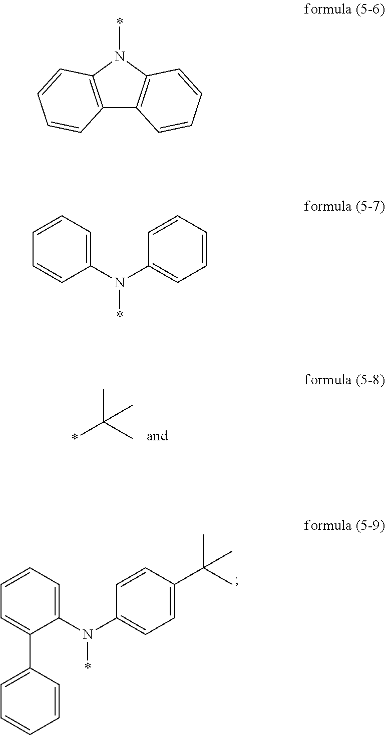

Where each * independently represents a bonding position.

In some embodiments, the S1-T1 of the second emitter E2≤0.30 eV, preferably ≤0.25 eV, more preferably ≤0.20 eV, further preferably ≤0.15 eV, and most preferably ≤0.10 eV.

In some embodiments, in the organic mixture as described herein, each of the second emitter E2 and the first emitter E1 is a small molecule or a polymer, preferably is a small molecule.

In some embodiments, the organic mixture does not comprise any resin.

Furthermore, the H atoms or the CH₂ groups on an individual aromatic ring or heteroaromatic ring may be substituted with R. R is selected from C₁-C₄₀ alkyl groups, preferably selected from the group consisting of: methyl, ethyl, n-propyl, isopropyl, cyclopropyl, n-butyl, isobutyl, sec-butyl, t-butyl, cyclobutyl, methylbutyl, n-pentyl, sec-pentyl, cyclopentyl, n-hexyl, cyclohexyl, n-heptyl, cycloheptyl, n-octyl, cyclooctyl, ethylhexyl, trifluoromethyl, pentafluoroethyl, trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, and octynyl; C₁-C₄₀ alkoxy groups, such as methoxy, trifluoromethoxy, ethoxy, n-propoxy, isopropoxy, n-butoxy, isobutoxy, sec-butoxy, tert-butoxy, and methylbutoxy.

Examples of the second emitter E2 (which may also apply to the emitter E1) are list below, but not limited to:

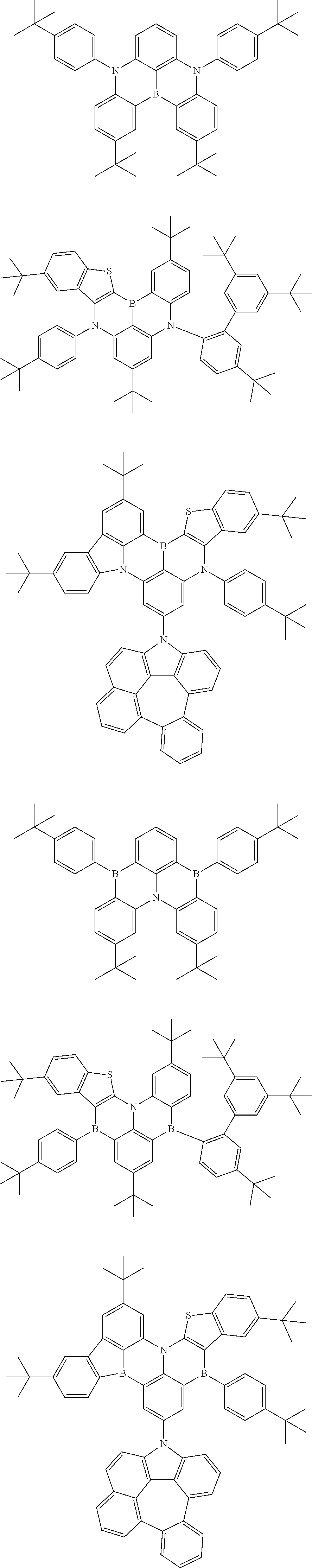

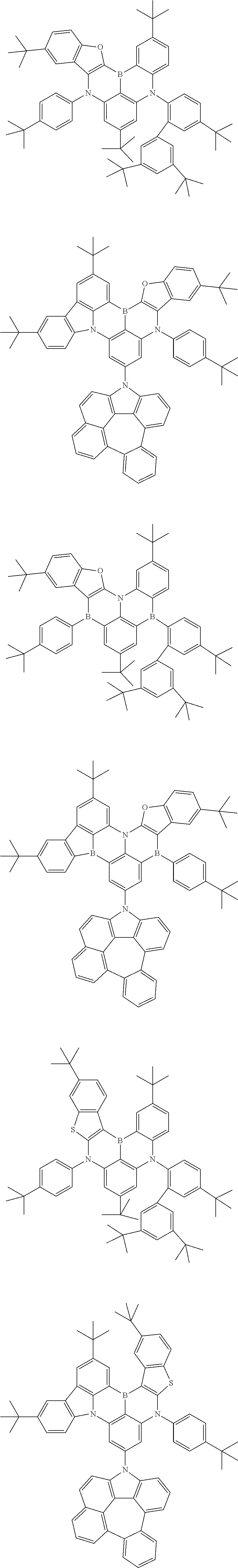

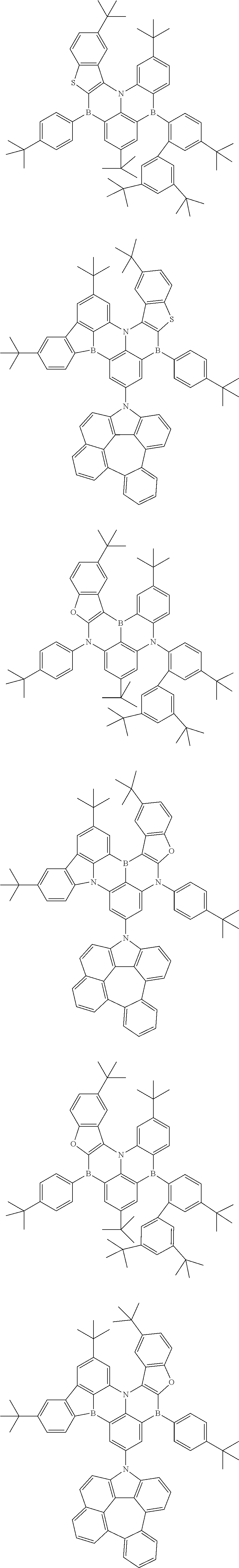

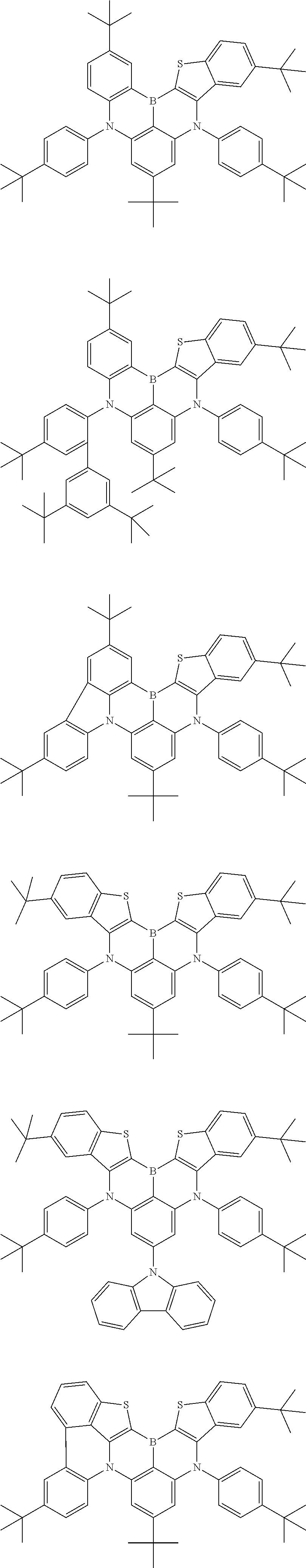

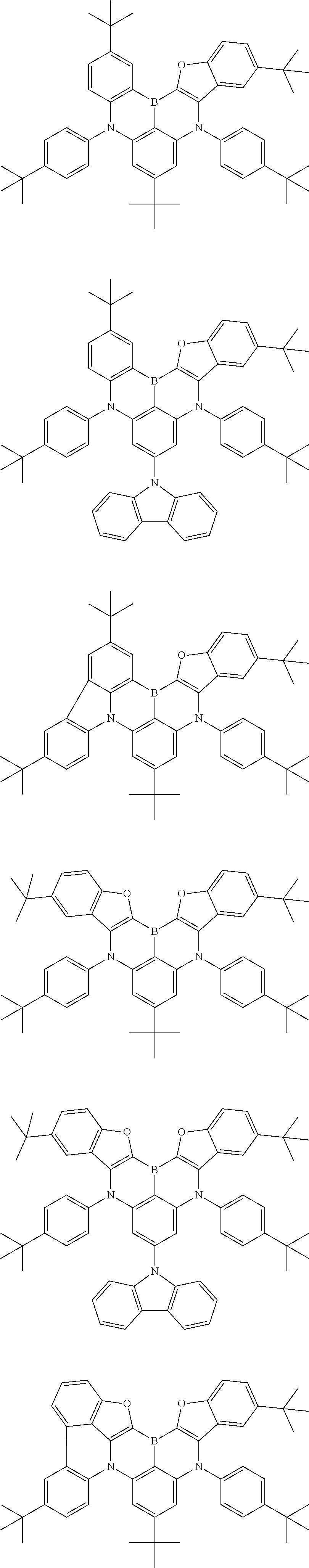

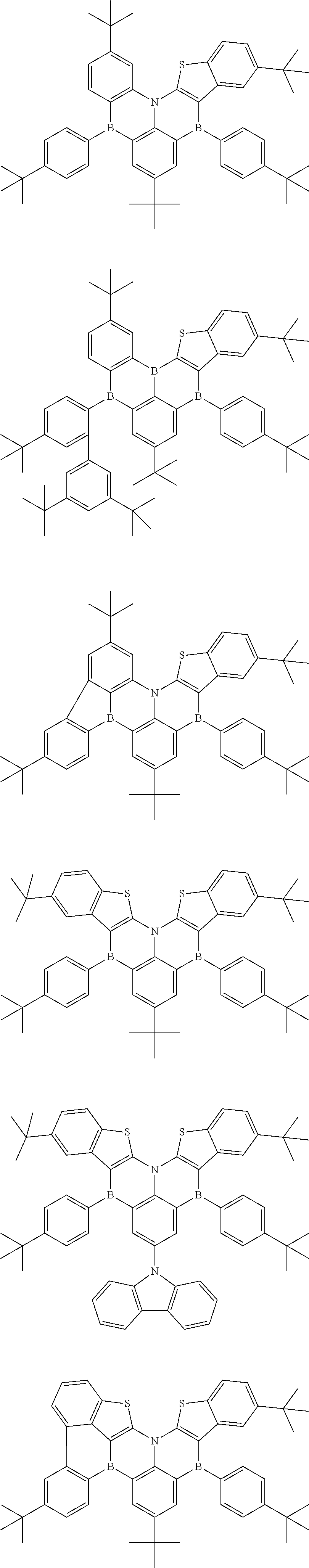

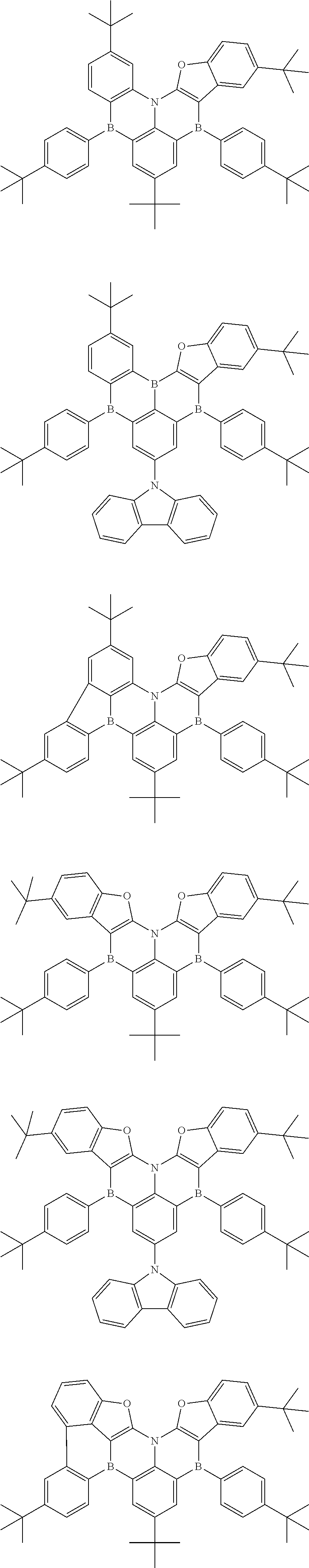

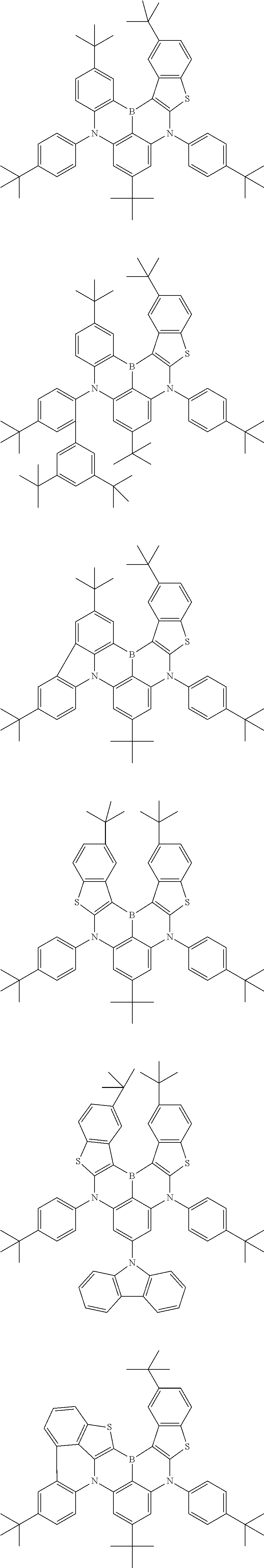

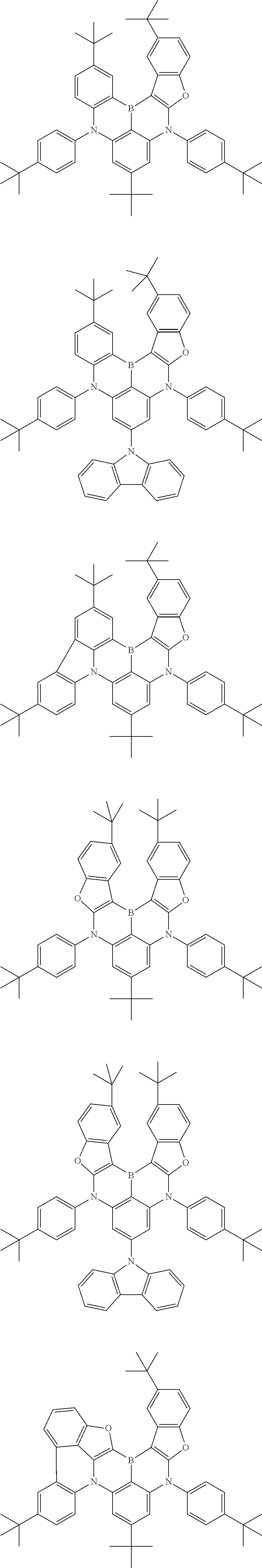

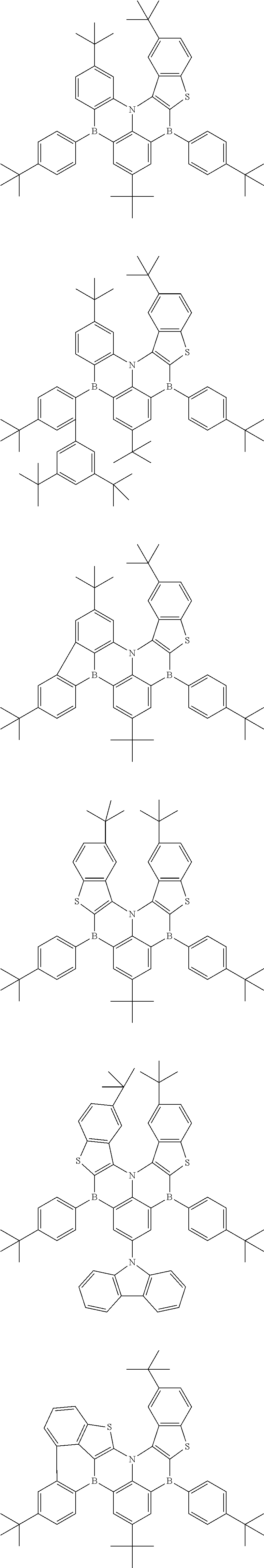

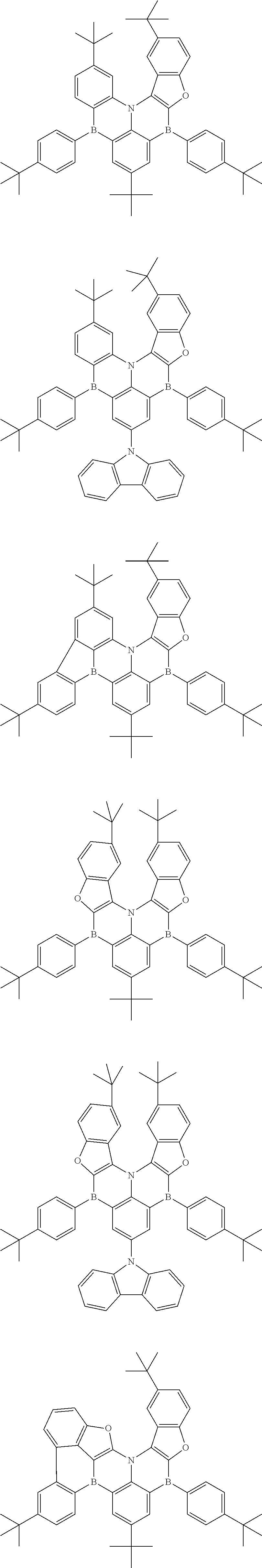

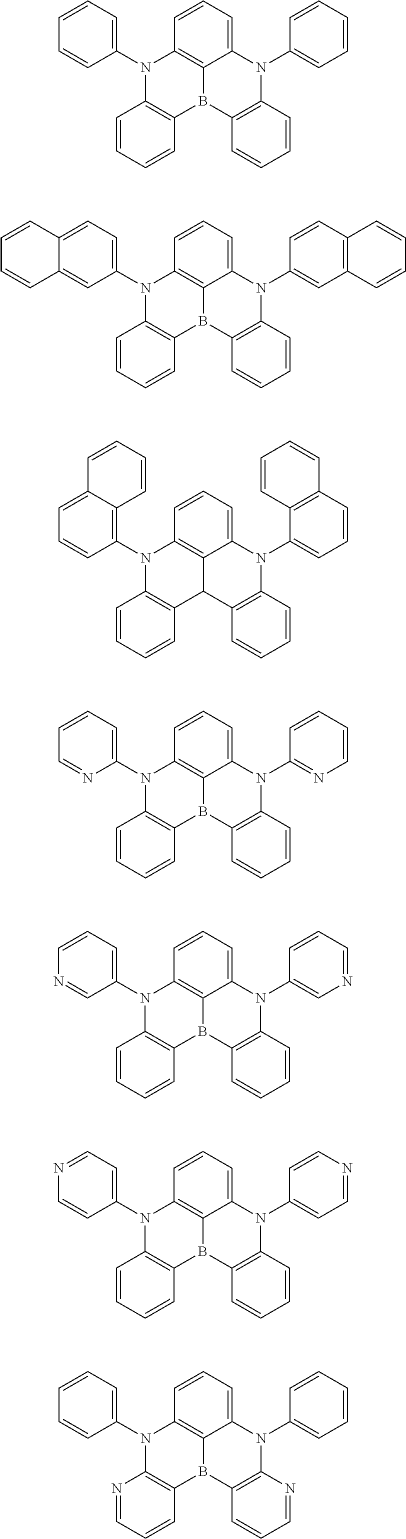

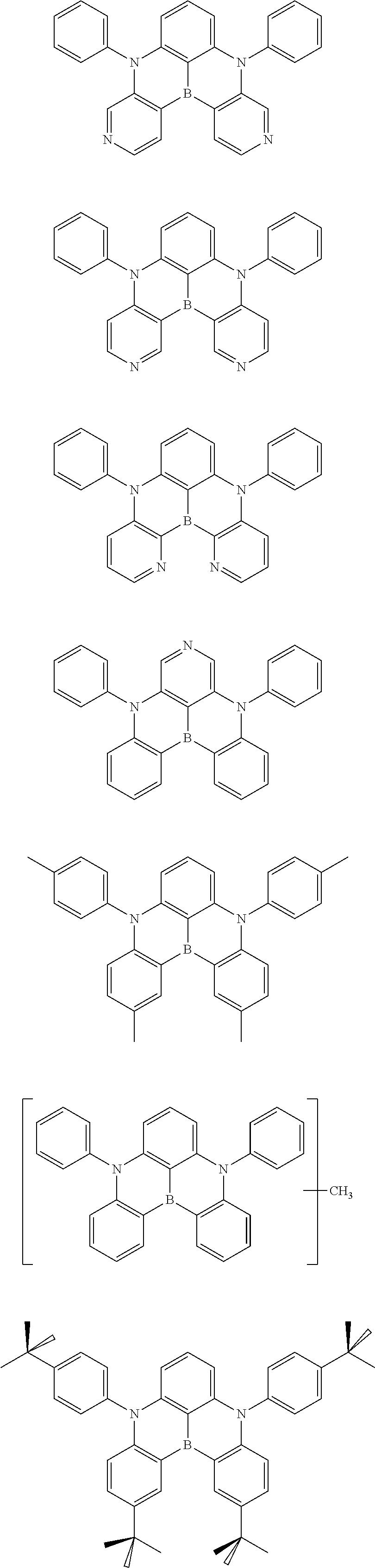

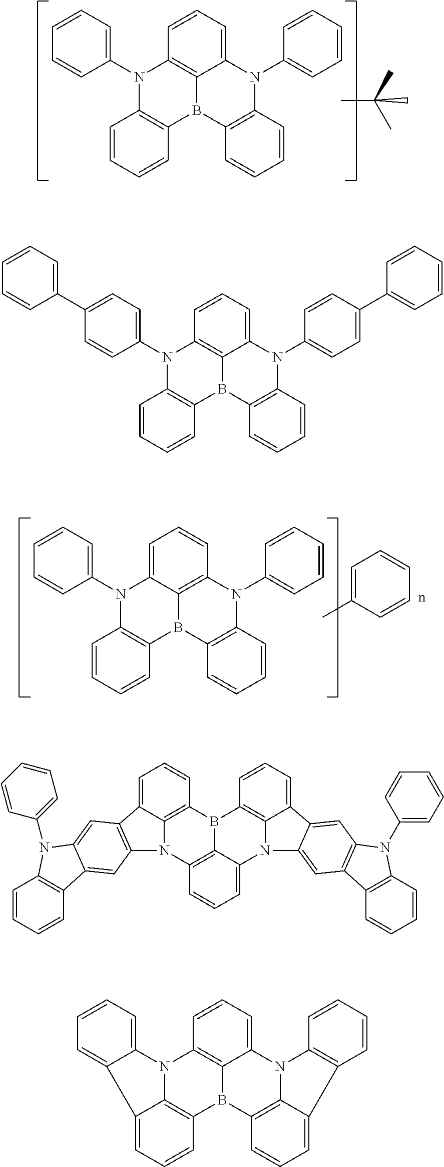

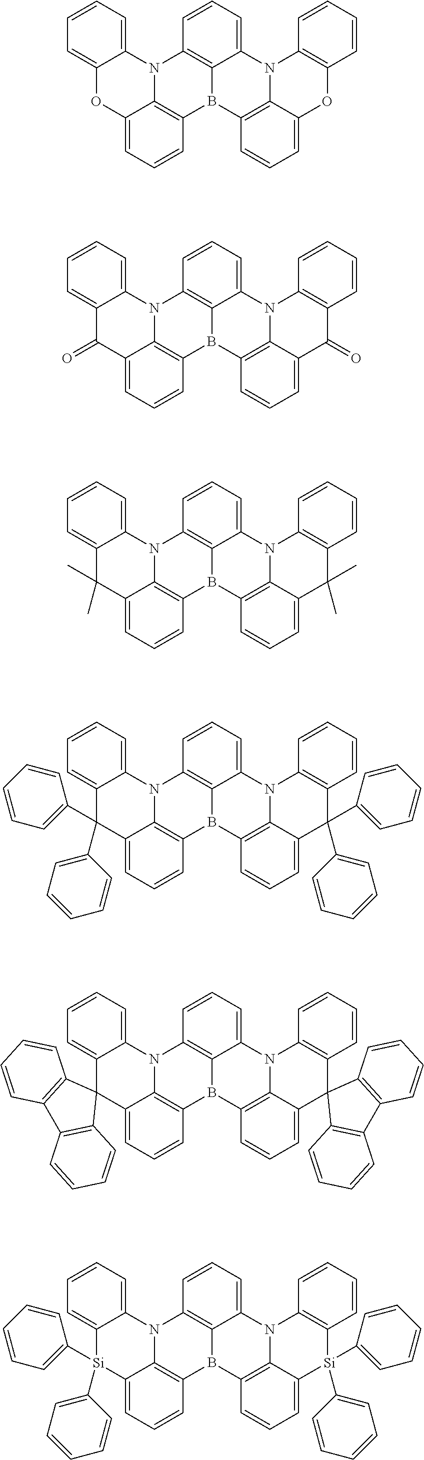 [SMILES: c1ccc2c(c1)Oc1cccc3c1N2c1cccc2c1B3c1cccc3c1N2c1ccccc1O3 ; O=c1c2ccccc2n2c3c(cccc13)B1c3c-2cccc3-n2c3ccccc3c(=O)c3cccc1c32 ; CC1(C)c2ccccc2N2c3cccc4c3B(c3cccc1c32)c1cccc2c1N4c1ccccc1C2(C)C ; c1ccc(C2(c3ccccc3)c3ccccc3N3c4cccc5c4B(c4cccc2c43)c2cccc3c2N5c2ccccc2C3(c2ccccc2)c2ccccc2)cc1 ; c1ccc2c(c1)-c1ccccc1C21c2ccccc2N2c3cccc4c3B(c3cccc1c32)c1cccc2c1N4c1ccccc1C21c2ccccc2-c2ccccc21 ; c1ccc([Si]2(c3ccccc3)c3ccccc3N3c4cccc5c4B(c4cccc2c43)c2cccc3c2N5c2ccccc2[Si]3(c2ccccc2)c2ccccc2)cc1]

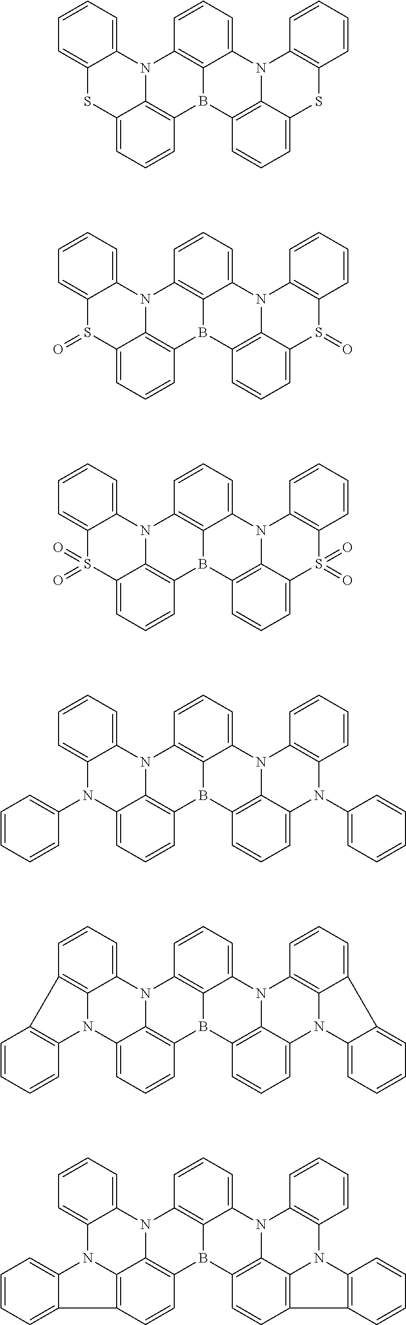 [SMILES: c1ccc2c(c1)Sc1cccc3c1N2c1cccc2c1B3c1cccc3c1N2c1ccccc1S3 ; O=S1c2ccccc2N2c3cccc4c3B(c3cccc1c32)c1cccc2c1N4c1ccccc1S2=O ; O=S1(=O)c2ccccc2N2c3cccc4c3B(c3cccc1c32)c1cccc2c1N4c1ccccc1S2(=O)=O ; c1ccc(N2c3ccccc3N3c4cccc5c4B(c4cccc2c43)c2cccc3c2N5c2ccccc2N3c2ccccc2)cc1 ; c1cc2c3c(c1)N1c4c(cccc4-n4c5ccccc5c5cccc1c54)B3c1cccc3c1N2c1cccc2c4ccccc4n-3c12 ; c1ccc2c(c1)N1c3cccc4c3B(c3ccc5c6ccccc6n-2c5c31)c1ccc2c3ccccc3n3c2c1N4c1ccccc1-3]

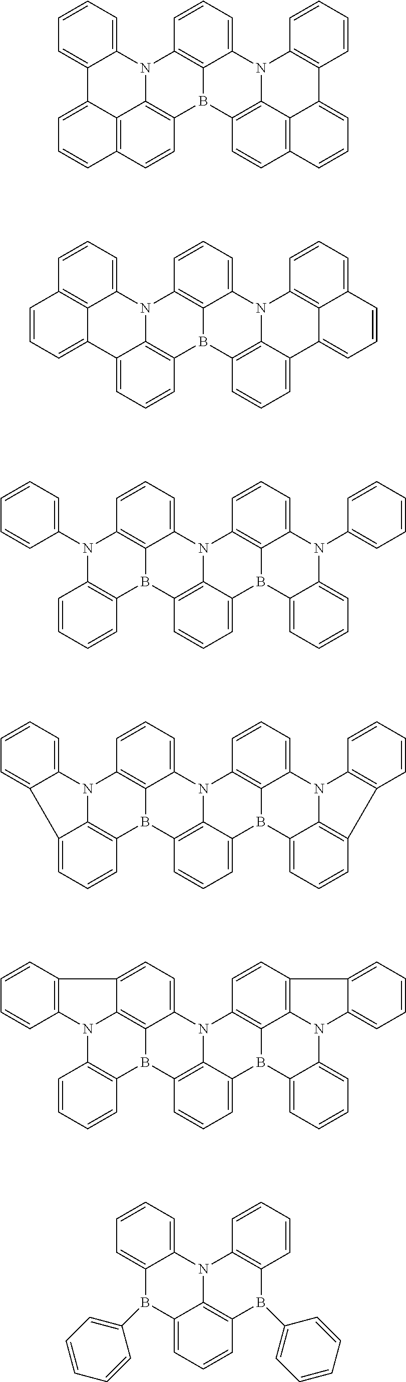 [SMILES: c1ccc2c(c1)-c1cccc3ccc4c(c13)N2c1cccc2c1B4c1ccc3cccc4c3c1N2c1ccccc1-4 ; c1cc2c3c(c1)-c1cccc4cccc(c14)N3c1cccc3c1B2c1cccc2c1N3c1cccc3cccc-2c13 ; c1ccc(N2c3ccccc3B3c4cccc5c4N(c4cccc2c43)c2cccc3c2B5c2ccccc2N3c2ccccc2)cc1 ; c1cc2c3c(c1)B1c4c(cccc4-n4c5ccccc5c5cccc1c54)N3c1cccc3c1B2c1cccc2c4ccccc4n-3c12 ; c1ccc2c(c1)B1c3cccc4c3N(c3ccc5c6ccccc6n-2c5c31)c1ccc2c3ccccc3n3c2c1B4c1ccccc1-3 ; c1ccc(B2c3ccccc3N3c4ccccc4B(c4ccccc4)c4cccc2c43)cc1]

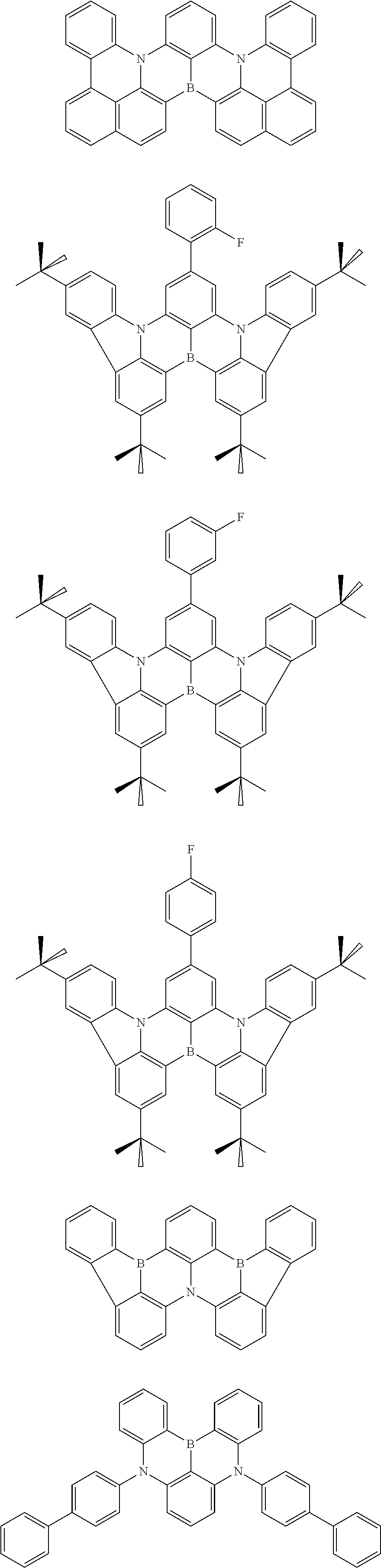

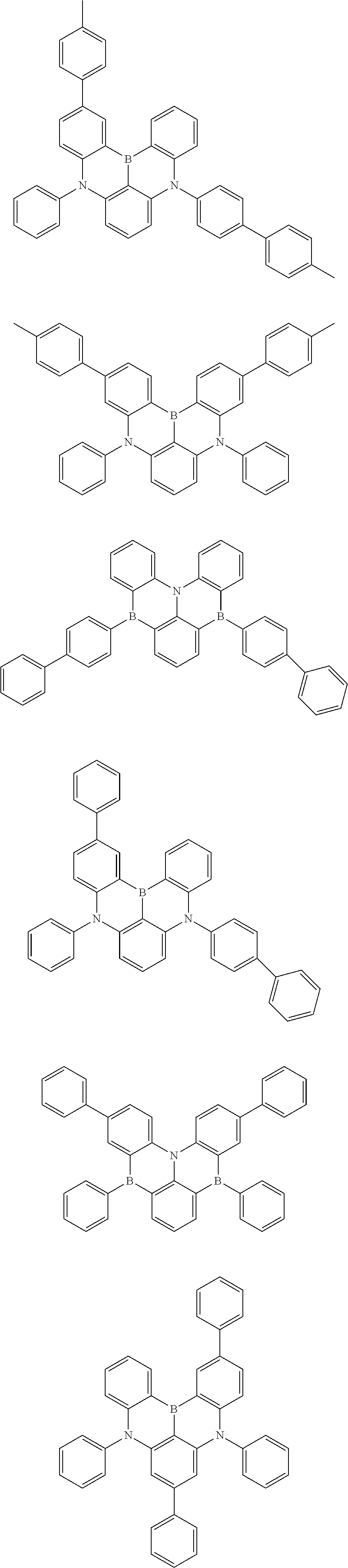

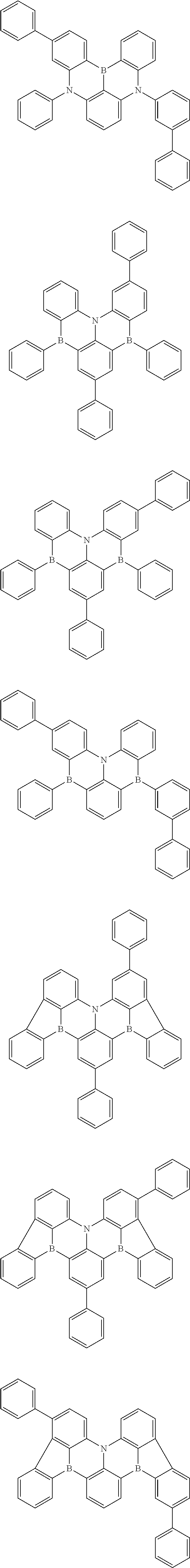

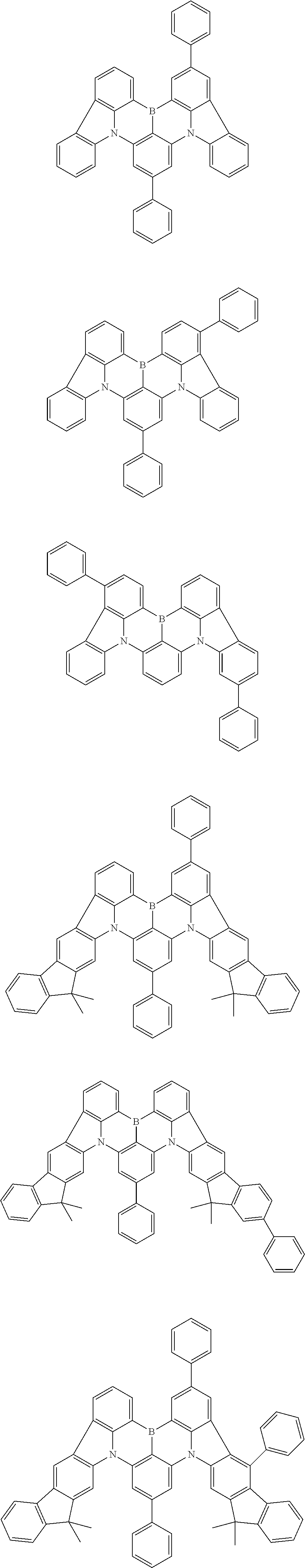

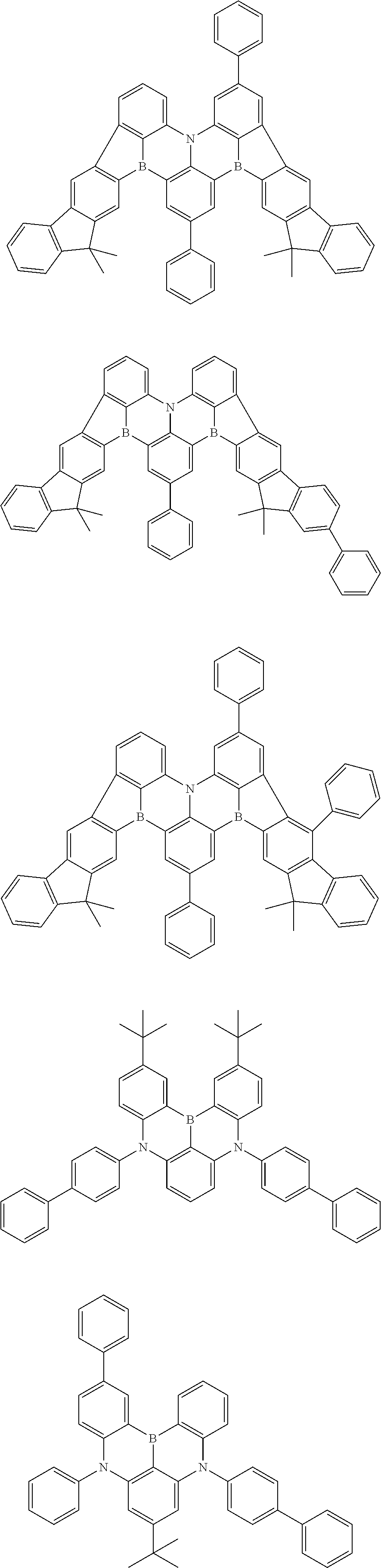

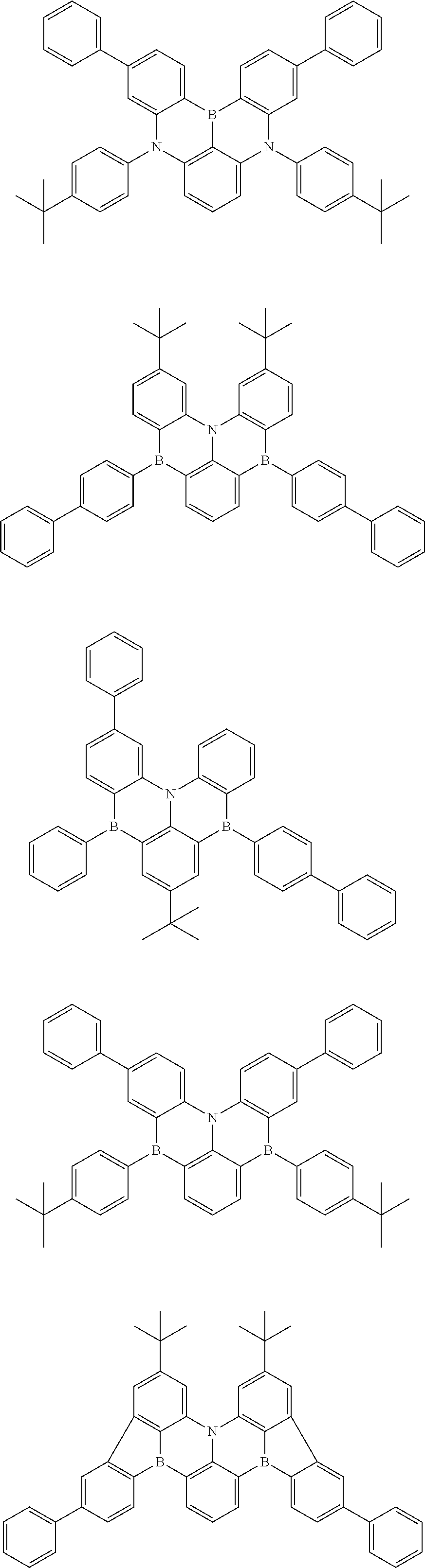

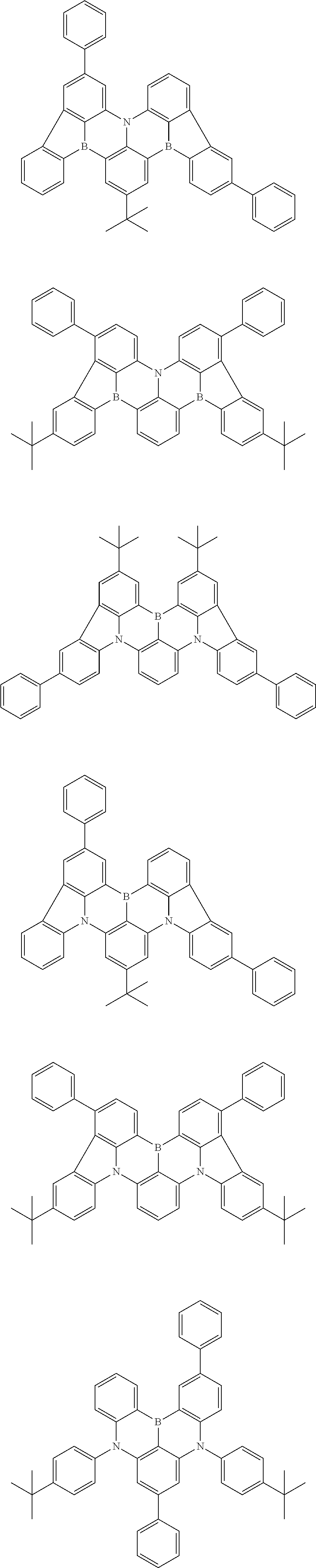

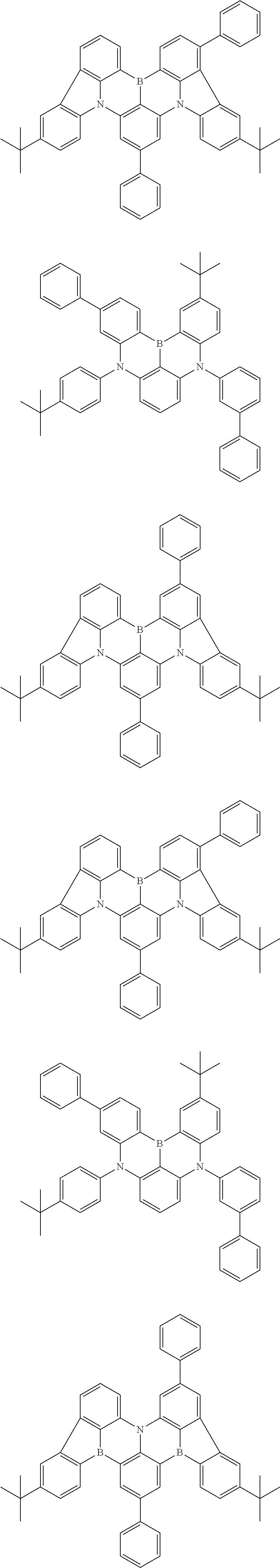

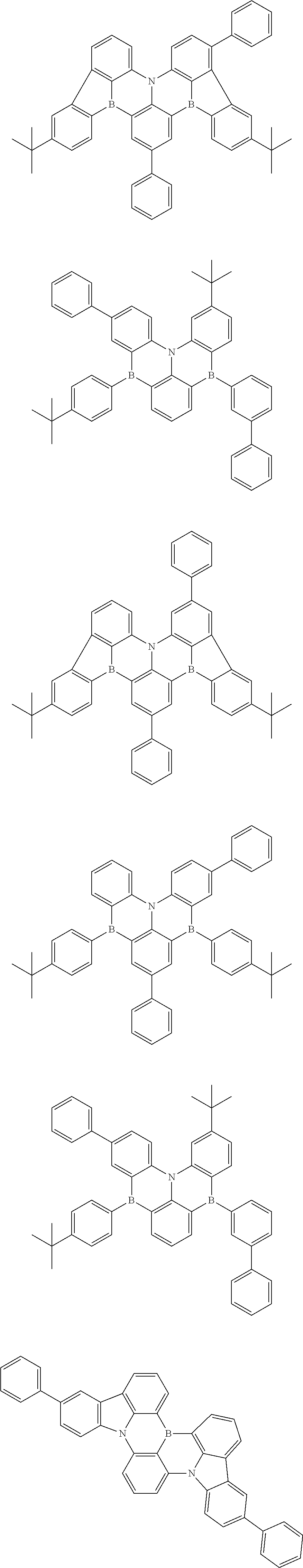

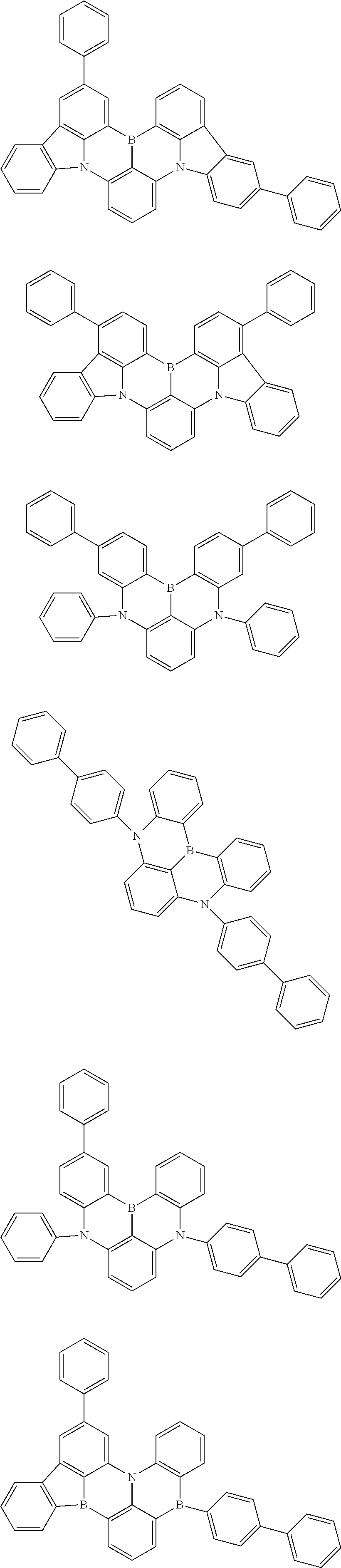 [SMILES: c1ccc(-c2ccc3c(c2)c2cccc4c2n3-c2cccc3c2B4c2cc(-c4ccccc4)cc4c5ccccc5n-3c24)cc1 ; c1ccc(-c2ccc3c4c2c2ccccc2n4-c2cccc4c2B3c2ccc(-c3ccccc3)c3c5ccccc5n-4c23)cc1 ; c1ccc(-c2ccc3c(c2)N(c2ccccc2)c2cccc4c2B3c2ccc(-c3ccccc3)cc2N4c2ccccc2)cc1 ; c1ccc(-c2ccc(N3c4ccccc4B4c5ccccc5N(c5ccc(-c6ccccc6)cc5)c5cccc3c54)cc2)cc1 ; c1ccc(-c2ccc(N3c4ccccc4B4c5cc(-c6ccccc6)ccc5N(c5ccccc5)c5cccc3c54)cc2)cc1 ; c1ccc(-c2ccc(B3c4ccccc4N4c5cc(-c6ccccc6)cc6c5B(c5ccccc5-6)c5cccc3c54)cc2)cc1]

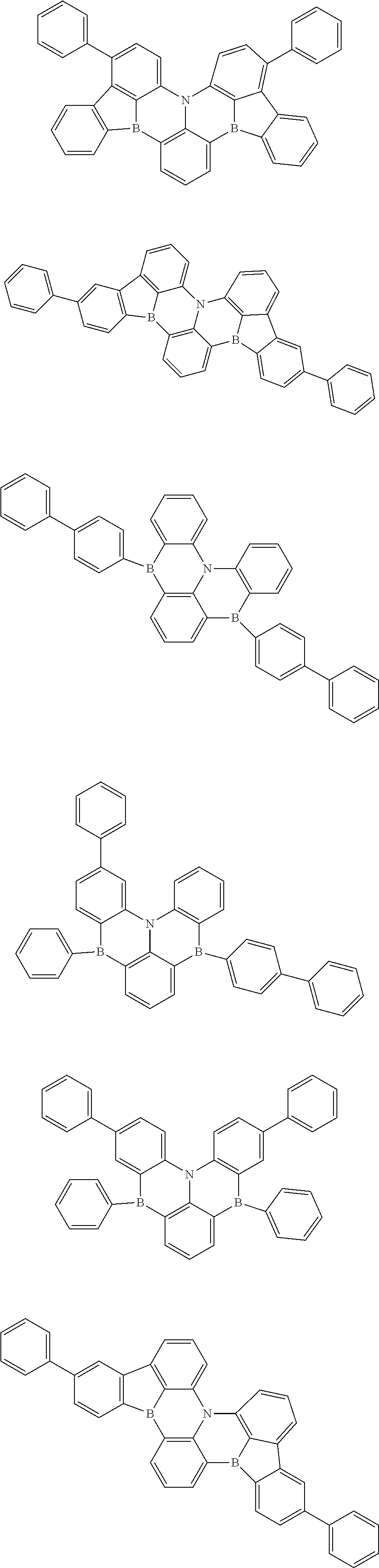 [SMILES: c1ccc(-c2ccc3c4c2-c2ccccc2B4c2cccc4c2N3c2ccc(-c3ccccc3)c3c2B4c2ccccc2-3)cc1 ; c1ccc(-c2ccc3c(c2)-c2cccc4c2B3c2cccc3c2N4c2cccc4c2B3c2ccc(-c3ccccc3)cc2-4)cc1 ; c1ccc(-c2ccc(B3c4ccccc4N4c5ccccc5B(c5ccc(-c6ccccc6)cc5)c5cccc3c54)cc2)cc1 ; c1ccc(B2c3ccc(-c4ccccc4)cc3N3c4ccccc4B(c4ccc(-c5ccccc5)cc4)c4cccc2c43)cc1 ; c1ccc(B2c3cc(-c4ccccc4)ccc3N3c4ccc(-c5ccccc5)cc4B(c4ccccc4)c4cccc2c43)cc1 ; c1ccc(-c2ccc3c(c2)-c2cccc4c2B3c2cccc3c2N4c2cccc4c2B3c2ccc(-c3ccccc3)cc2-4)cc1]

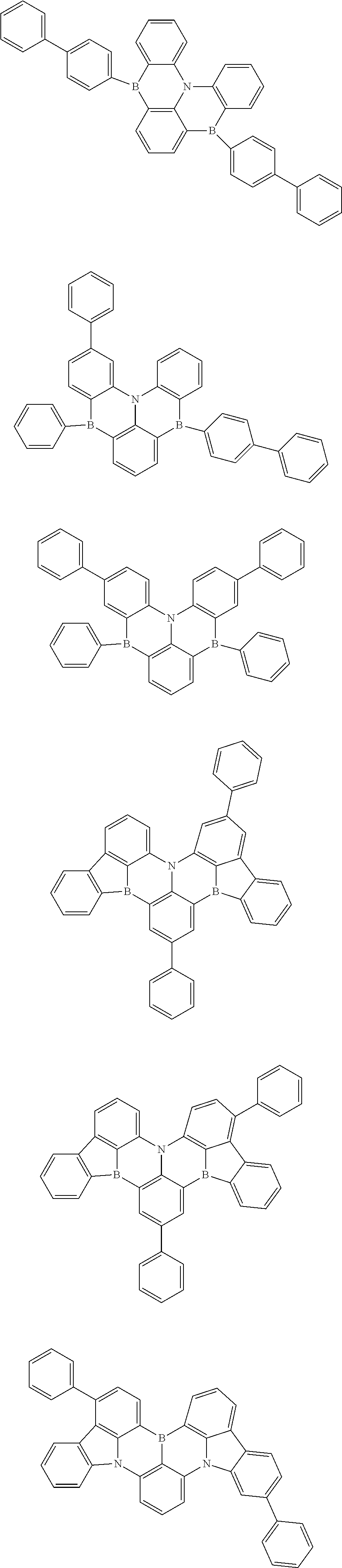 [SMILES: c1ccc(-c2ccc(B3c4ccccc4N4c5ccccc5B(c5ccc(-c6ccccc6)cc5)c5cccc3c54)cc2)cc1 ; c1ccc(B2c3ccc(-c4ccccc4)cc3N3c4ccccc4B(c4ccc(-c5ccccc5)cc4)c4cccc2c43)cc1 ; c1ccc(B2c3cc(-c4ccccc4)ccc3N3c4ccc(-c5ccccc5)cc4B(c4ccccc4)c4cccc2c43)cc1 ; c1ccc(-c2cc3c4c(c2)B2c5ccccc5-c5cc(-c6ccccc6)cc(c52)N4c2cccc4c2B3c2ccccc2-4)cc1 ; c1ccc(-c2cc3c4c(c2)B2c5ccccc5-c5c(-c6ccccc6)ccc(c52)N4c2cccc4c2B3c2ccccc2-4)cc1 ; c1ccc(-c2ccc3c4cccc5c4n(c3c2)-c2cccc3c2B5c2ccc(-c4ccccc4)c4c5ccccc5n-3c24)cc1]

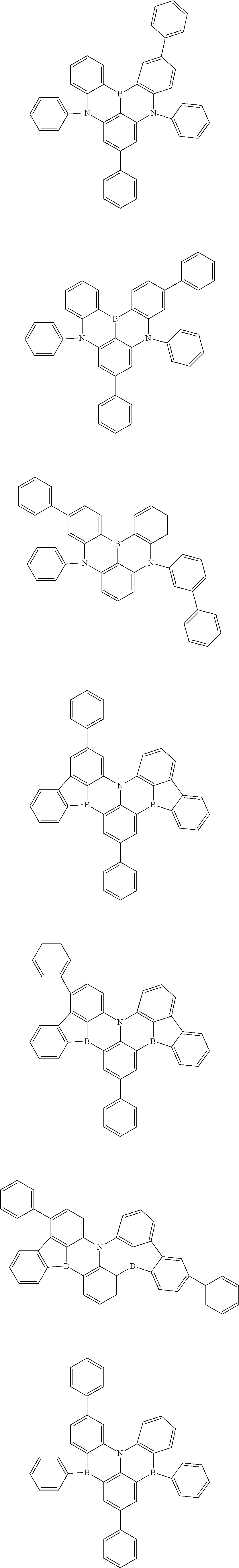

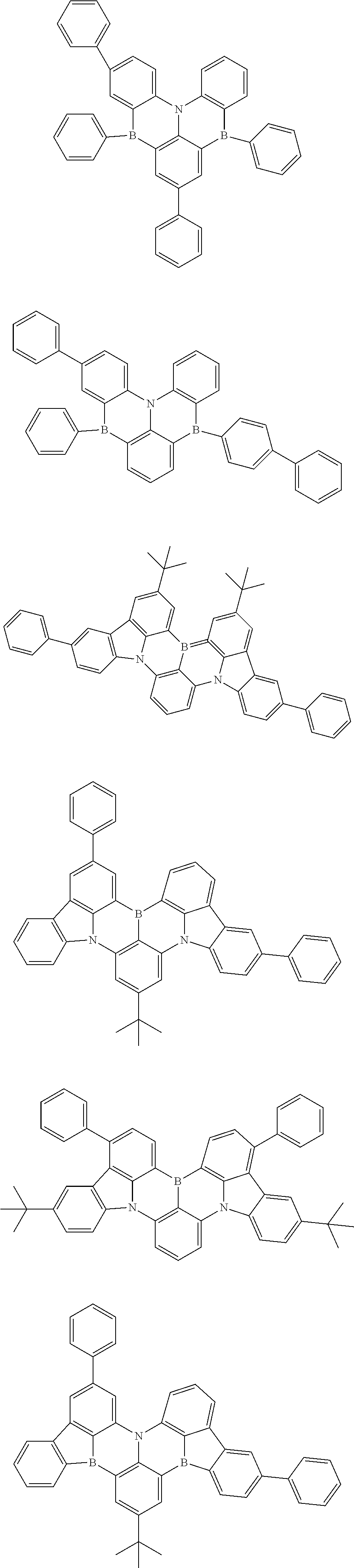

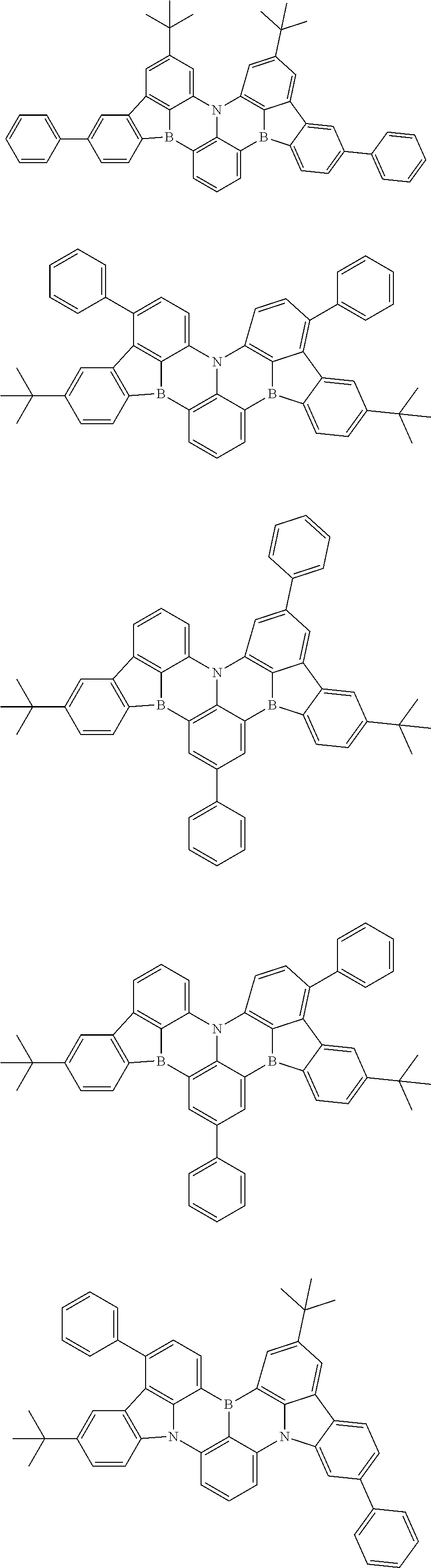

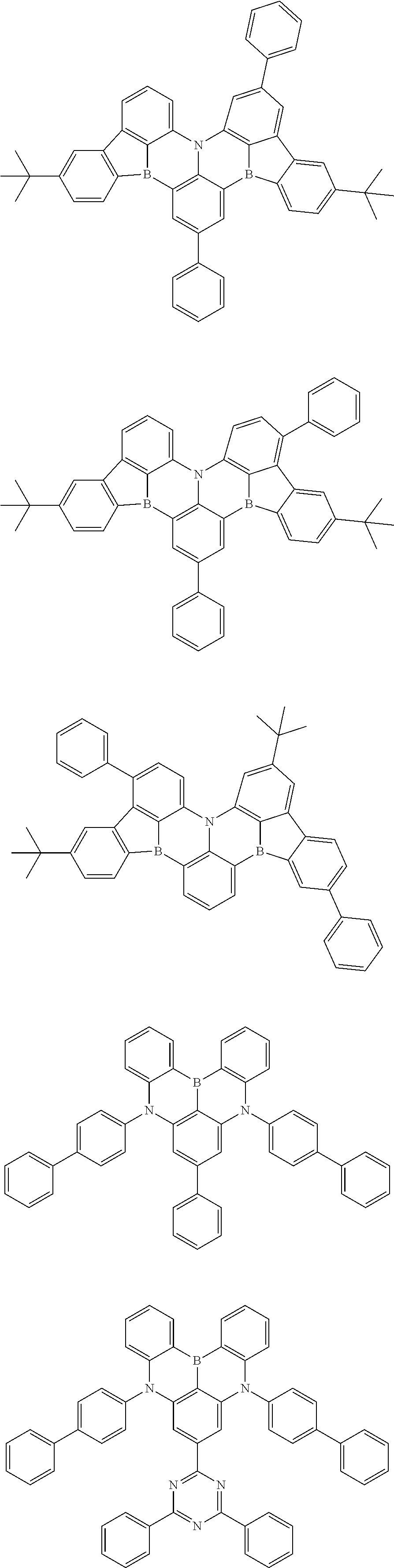

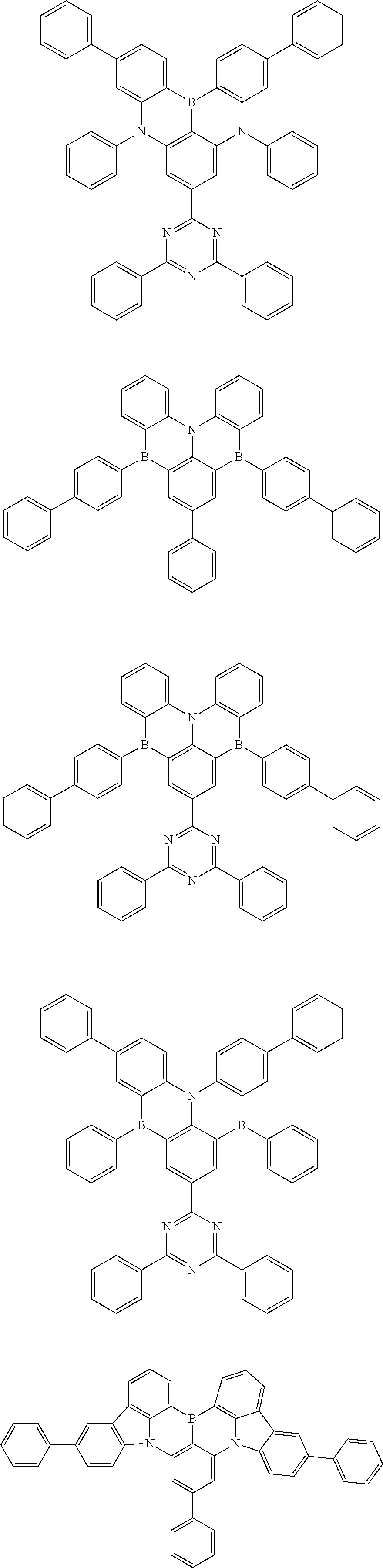

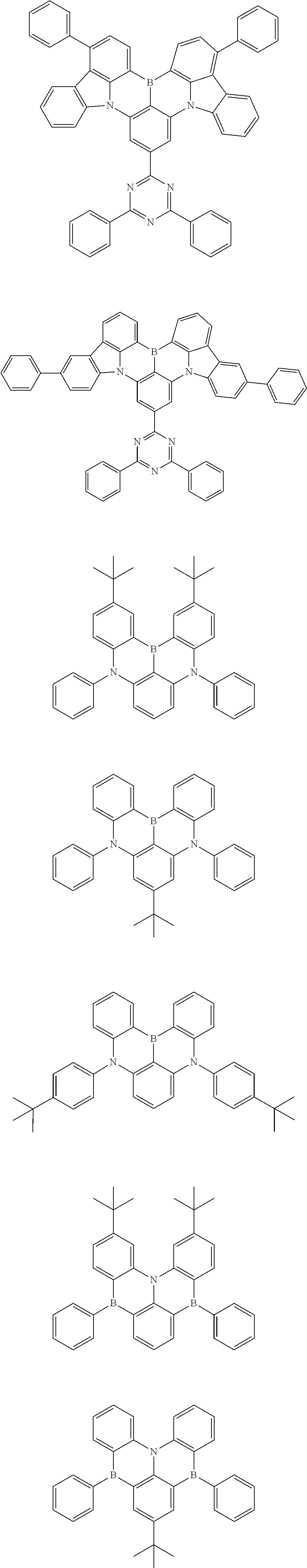

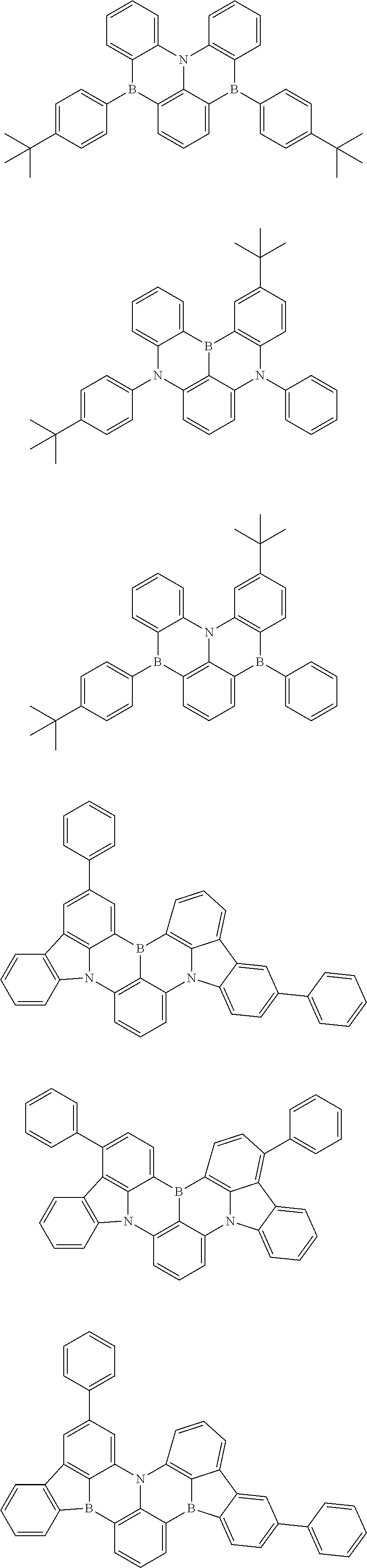

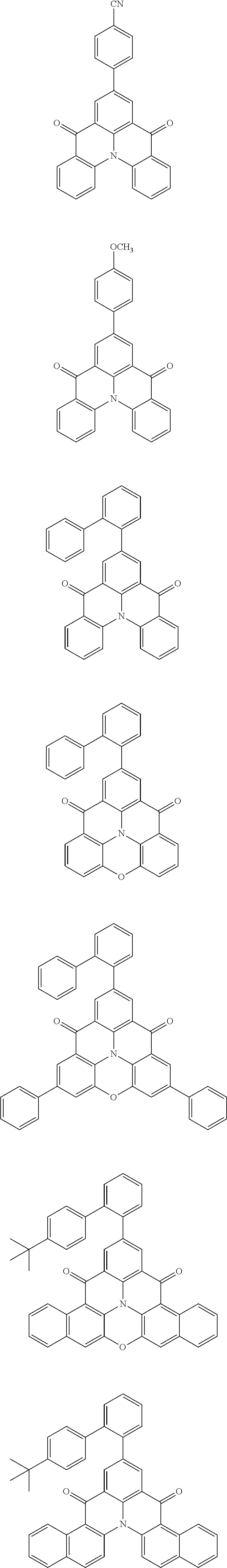

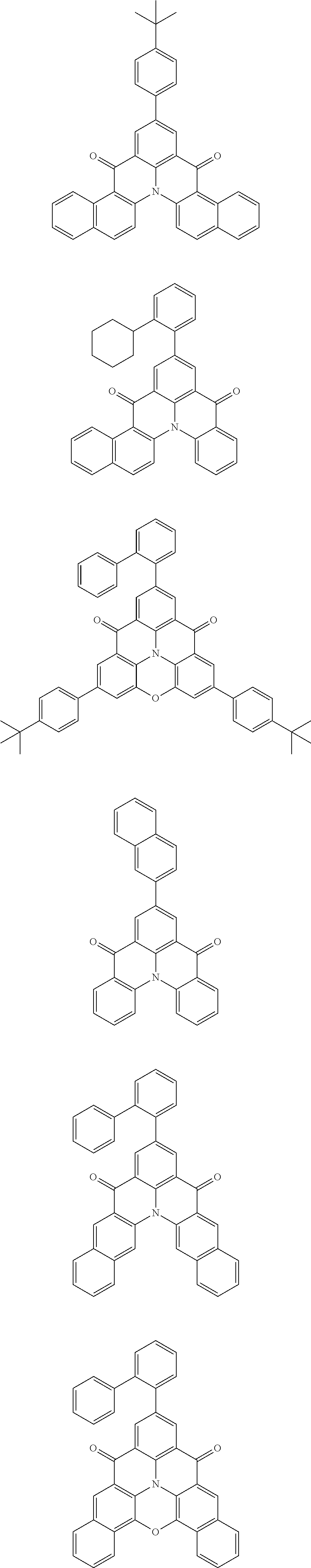 [SMILES: CC(C)(C)c1ccc(-c2cc3c(=O)c4c5ccccc5ccc4n4c5ccc6ccccc6c5c(=O)c(c2)c34)cc1 ; O=c1c2ccccc2n2c3ccc4ccccc4c3c(=O)c3cc(-c4ccccc4C4CCCCC4)cc1c32 ; CC(C)(C)c1ccc(-c2cc3c4c(c2)c(=O)c2cc(-c5ccccc5-c5ccccc5)cc5c(=O)c6cc(-c7ccc(C(C)(C)C)cc7)cc(c6n4c25)O3)cc1 ; O=c1c2ccccc2n2c3ccccc3c(=O)c3cc(-c4ccc5ccccc5c4)cc1c32 ; O=c1c2cc3ccccc3cc2n2c3cc4ccccc4cc3c(=O)c3cc(-c4ccccc4-c4ccccc4)cc1c32 ; O=c1c2cc3ccccc3c3c2n2c4c(c5ccccc5cc4c(=O)c4cc(-c5ccccc5-c5ccccc5)cc1c42)O3]

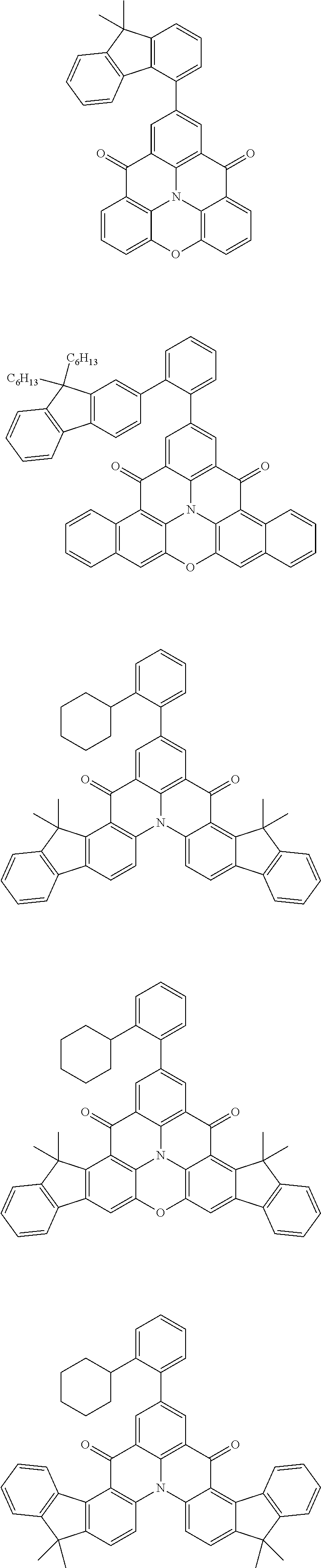

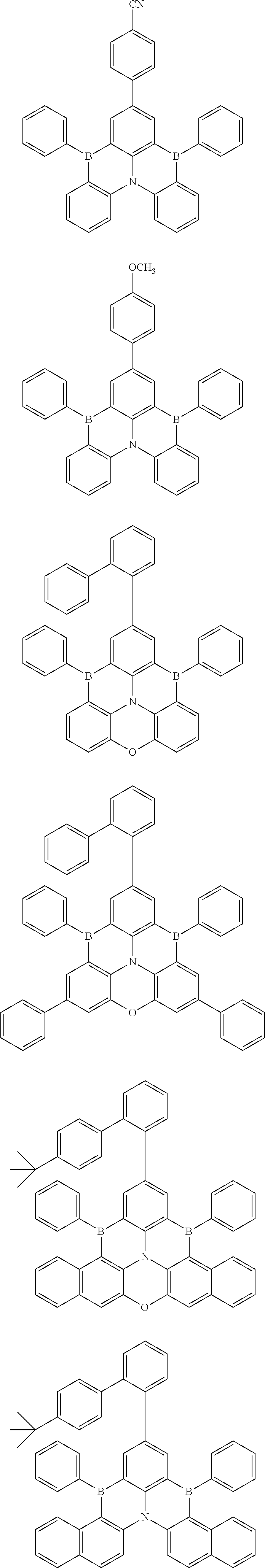

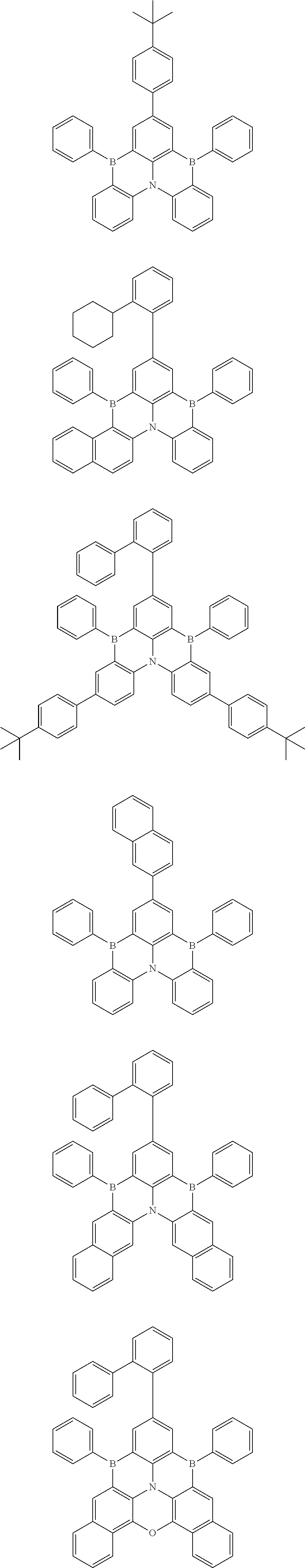

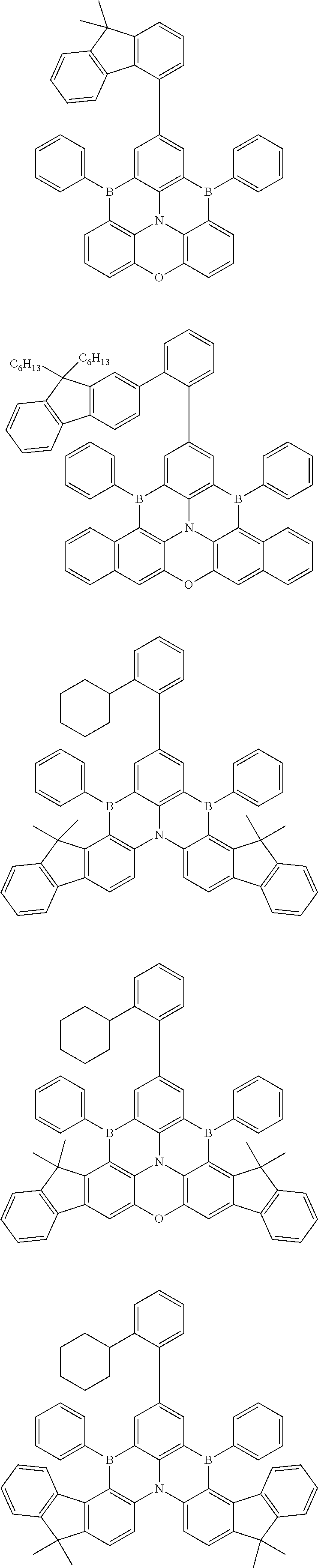

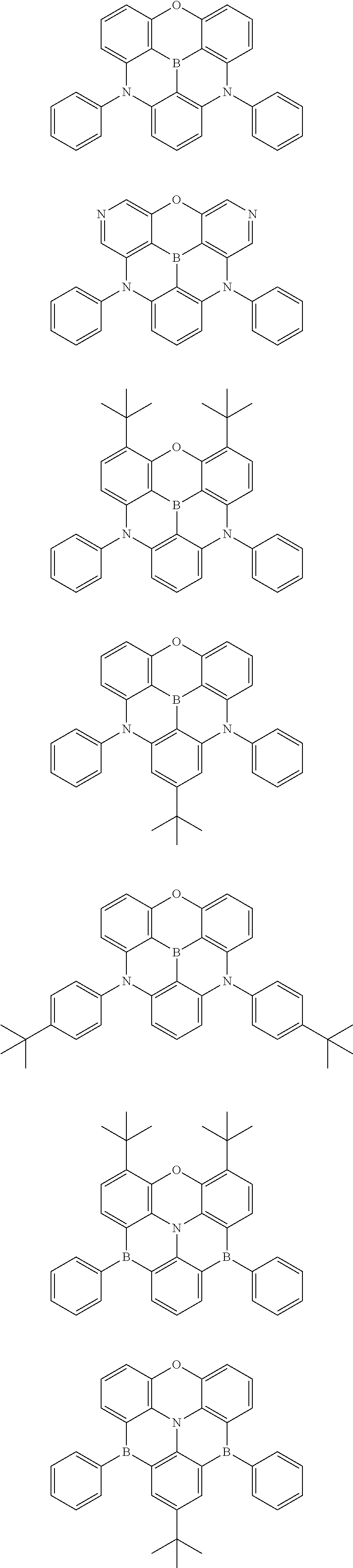

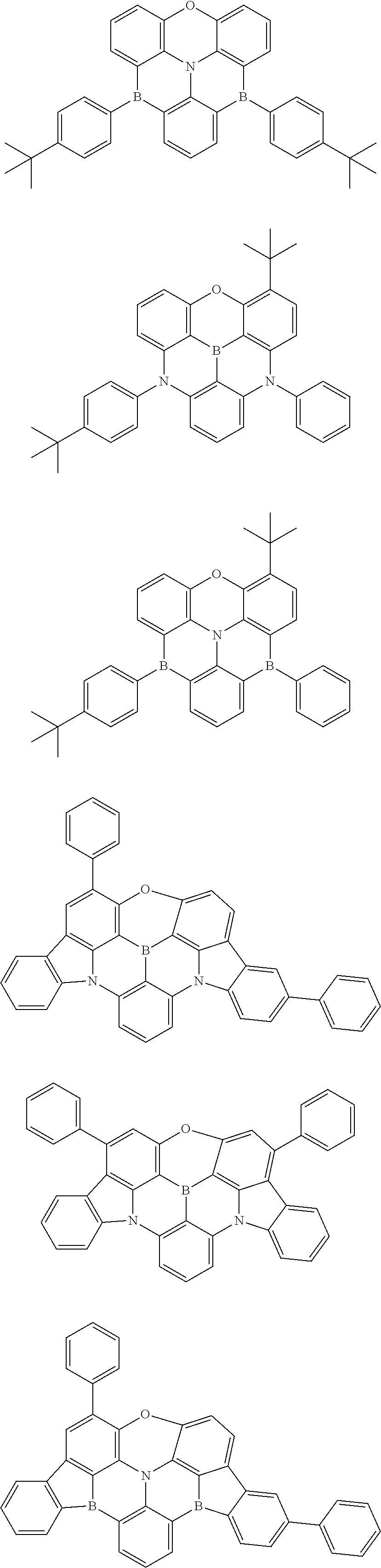

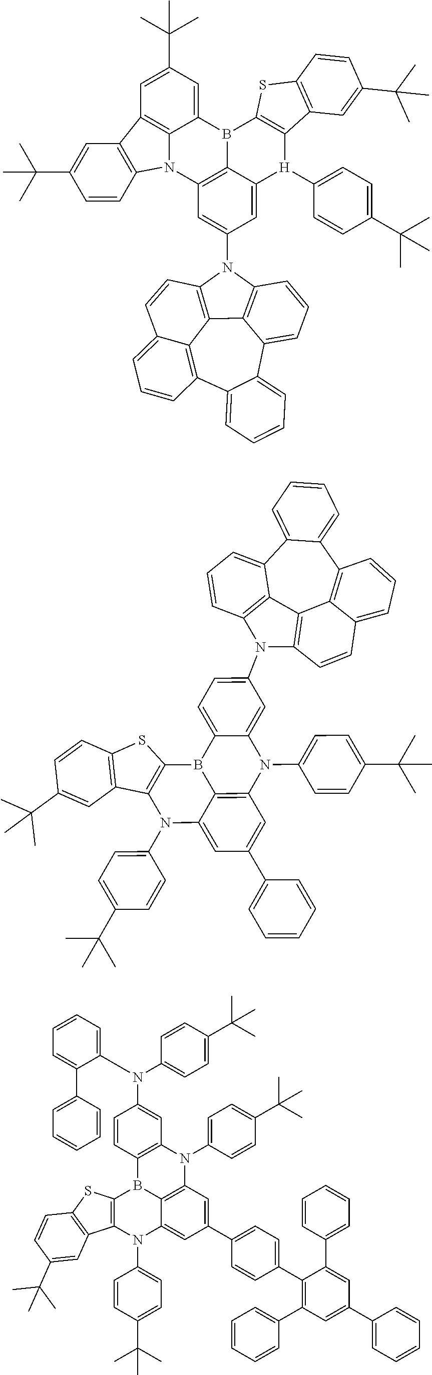

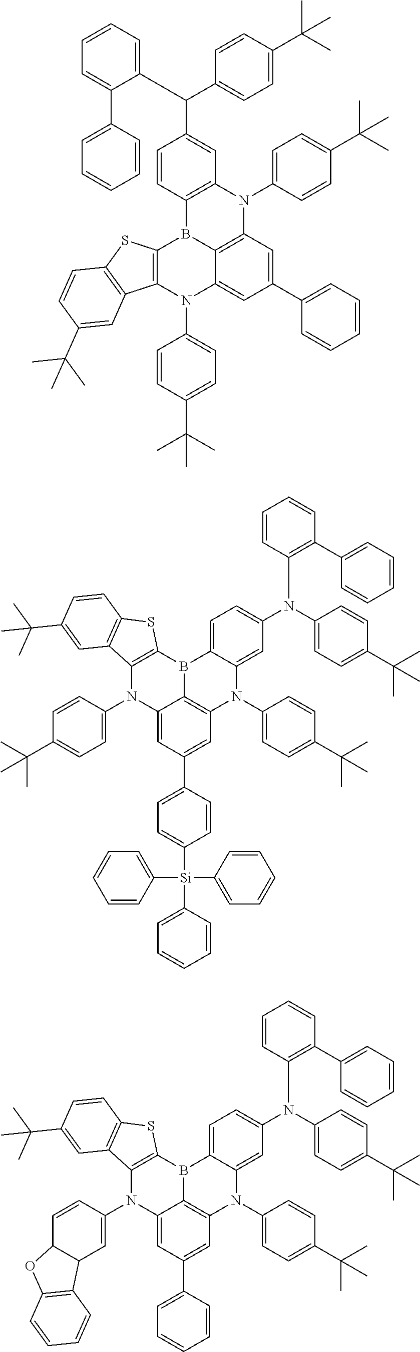

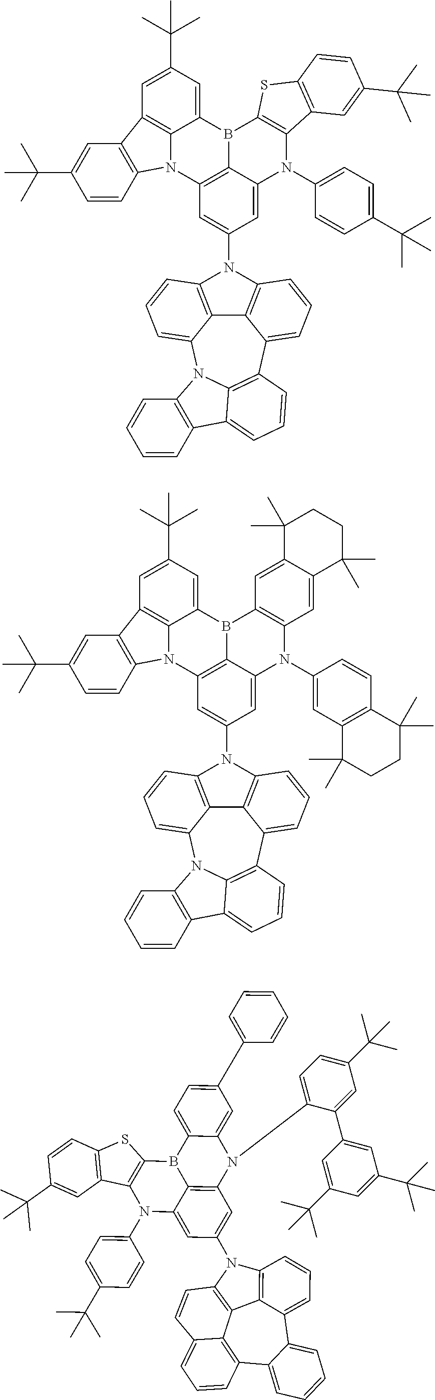

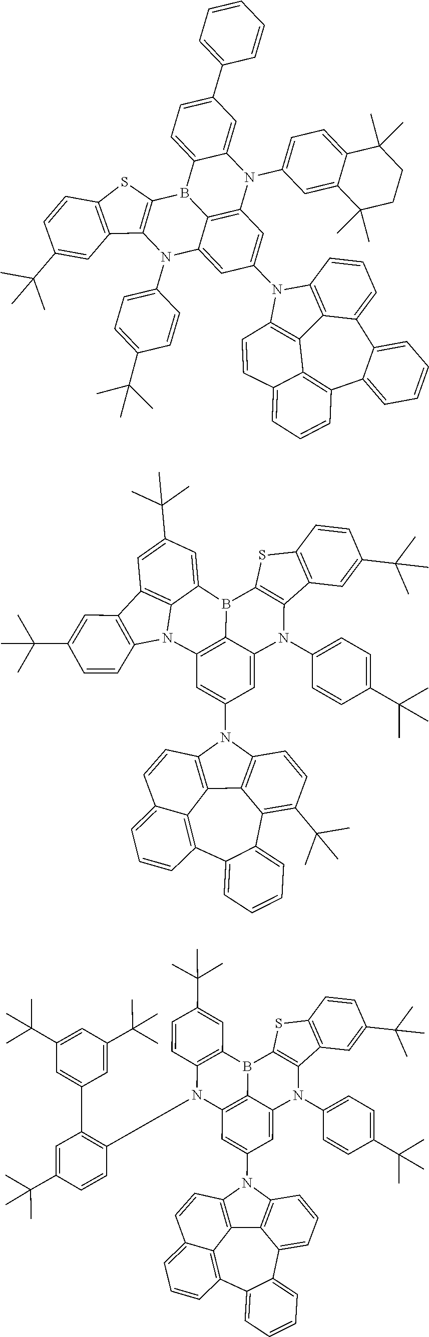

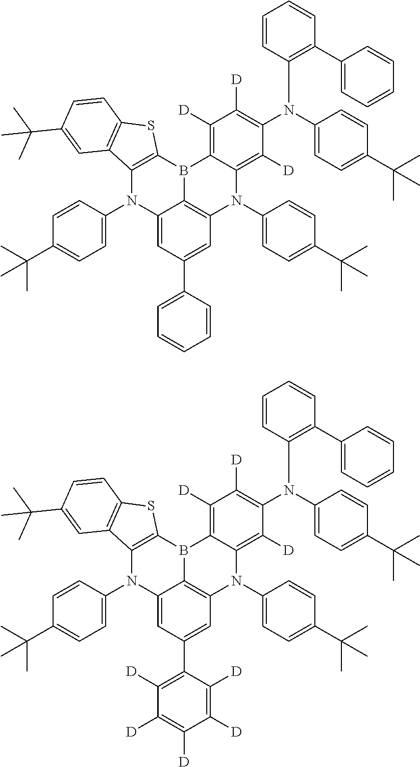

In some embodiments, the first emitter E1 is one of the compounds represented by formulas (1), (2), (1a)-(1e), (2a)-(2e), (1f)-(1i), (1j)-(1l).

In some embodiments, the first emitter E1 is a conventional fluorescent emitter (i.e., singlet emitter). The conventional singlet emitter tends to have a long conjugated π-electron system. Hitherto, there have been many examples of styryl amines and derivatives thereof as disclosed in WO2001021729A1, and indenofluorenes and derivatives thereof as disclosed in WO2008006449A1 and WO2007140847, and pyrene-containing triarylamine derivatives as disclosed in KR20060006760A.

In some embodiments, the first emitter E1 can be selected from the group consisting of monostyrylamines, distyrylamines, tristyrylamines, tetrastyrylamines, styrenphosphines, styrenethers, and arylamines.

A monostyrylamine refers to a compound containing one unsubstituted or substituted styryl group and at least one amine, most preferably an aromatic amine. A distyrylamine refers to a compound containing two unsubstituted or substituted styryl groups and at least one amine, most preferably an aromatic amine. A tristyrylamine refers to a compound containing three unsubstituted or substituted styryl groups and at least one amine, most preferably an aromatic amine. A tetrastyrylamine refers to a compound containing four unsubstituted or substituted styryl groups and at least one amine, most preferably an aromatic amine. A preferred styryl group is stilbene, which may be further substituted. The definitions for corresponding phosphines and ethers are similar to those for amines. An aryl amine or aromatic amine refers to a compound containing three unsubstituted or substituted aromatic rings or heterocyclic systems directly linked to a nitrogen atom. Among these aromatic or heterocyclic ring systems, at least one is preferably a fused ring system and most preferably contains at least 14 aromatic ring atoms. Preferred examples include aromatic anthrylamines, aromatic anthryldiamines, aromatic pyrenamines, aromatic pyrenediamines, aromatic chrysenamines, and aromatic chrysenediamines. An aromatic anthrylamine refers to a compound in which a diarylamino group is directly attached to an anthracene, most preferably at the 9-position. An aromatic anthryldiamine refers to a compound in which two diarylamino groups are directly attached to an anthracene, most preferably at the 9,10-positions. The definitions for aromatic pyrenamine, aromatic pyrenediamine, aromatic chrysenamine, and aromatic chrysenediamine are similar, where the diarylamino group is most preferably attached to the 1- or 1,6-positions of pyrene.

Examples of conventional singlet emitters based on vinylamines and arylamines, which are also preferred, may be found in the following patent application publications: WO2006000388A1, JP08053397A, and US2006210830A, the entire contents of which are hereby incorporated herein by reference.

Examples of conventional singlet emitters based on stilbene and its derivatives may be found in U.S. Pat. No. 5,121,029A.

Further preferred conventional singlet emitter can be selected from the group consisting of indenofluorene-amine and indenofluorene-diamine, as disclosed in WO2006122630A1, benzoindenofluorene-amine and benzoindenofluorene-diamine, as disclosed in WO2008006449A1, dibenzoindenofluorene-amine and dibenzoindenofluorene-diamine, as disclosed in WO2007140847A1.

Further preferred conventional singlet emitters can be selected from fluorene-based fused-ring systems disclosed in US2016099411A1, and US2016204355A1.

More preferred conventional singlet emitters may be pyrene derivatives, such as the structures disclosed in US2013175509A1; pyrene triarylamine derivatives, such as the pyrene triarylamine derivatives containing dibenzofuran units as disclosed in CN102232068B; and other pyrene triarylamine derivatives with specific structures, such as those disclosed in CN105037173A. Other materials that can be used as singlet emitter include polycyclic aromatic hydrocarbon compounds, in particular selected from the derivatives of the following compounds: anthracene such as 9,10-di(2-naphthyl)anthracene, naphthalene, tetraphenyl, xanthene, phenanthrene, pyrene such as 2,5,8,11-tetra-t-butylatedylene, indenoperylene, phenylene (benzo fused ring such as 4,4′-(bis(9-ethyl-3-carbazovinylene)-1,1′-biphenyl)), periflanthene, decacyclene, coronene, fluorene, spirobifluorene, arylpyren (e.g., US20060222886A1), arylenevinylene (e.g. U.S. Pat. Nos. 5,121,029A, 5,130,603A), cyclopentadiene such as tetraphenylcyclopentadiene, rubrene, coumarin, rhodamine, quinacridone, pyrane such as 4-(dicyanoethylene)-6-(4-dimethylaminostyryl-2-methyl)-4H-pyrane (DCM), thiapyran, bis (azinyl) imine-boron compounds (e.g. US20070092753A1), bis (azinyl) methene compounds, carbostyryl compounds, oxazone, benzoxazole, benzothiazole, benzimidazole, or diketopyrrolopyrrole. Some conventional singlet emitter materials may be found in the following patent: US20070252517A1. The patents listed above are specially incorporated herein by reference in their entirety.

On the other hand, the singlet emitter can be a 3,7,12-substituted benzo[k]fluoranthene derivative, as disclosed in WO2014034891A1.

Another class of preferred singlet emitters may be fused-ring compounds exhibiting the MR-TADF effect, such as those disclosed in EP4119634A1.

Here are some examples of suitable singlet emitters:

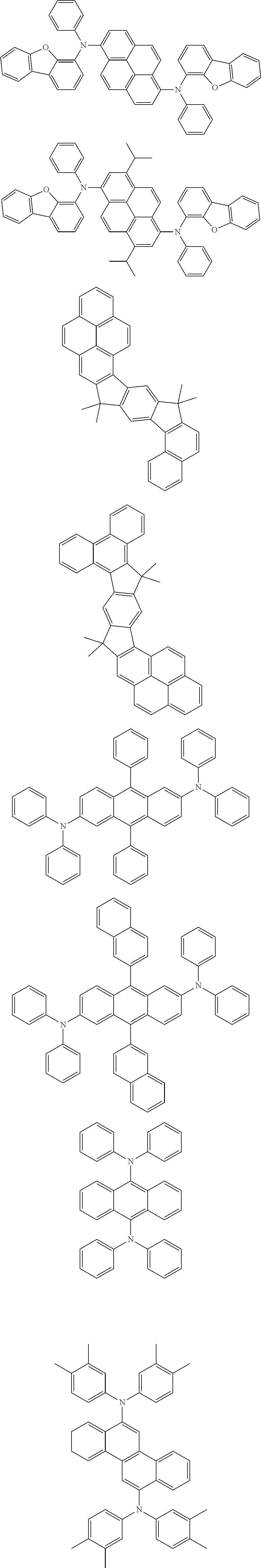

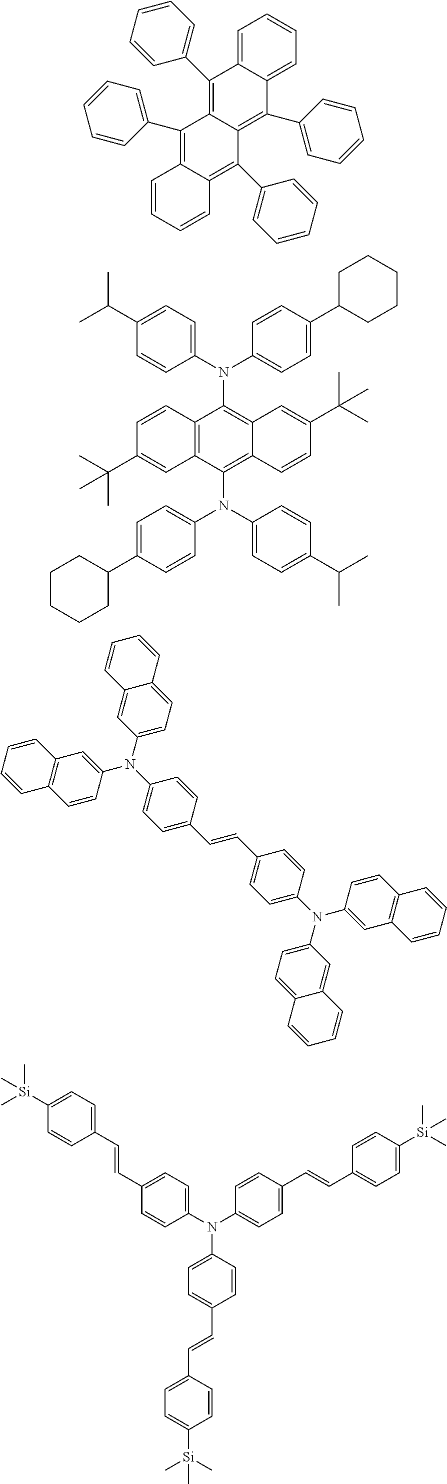

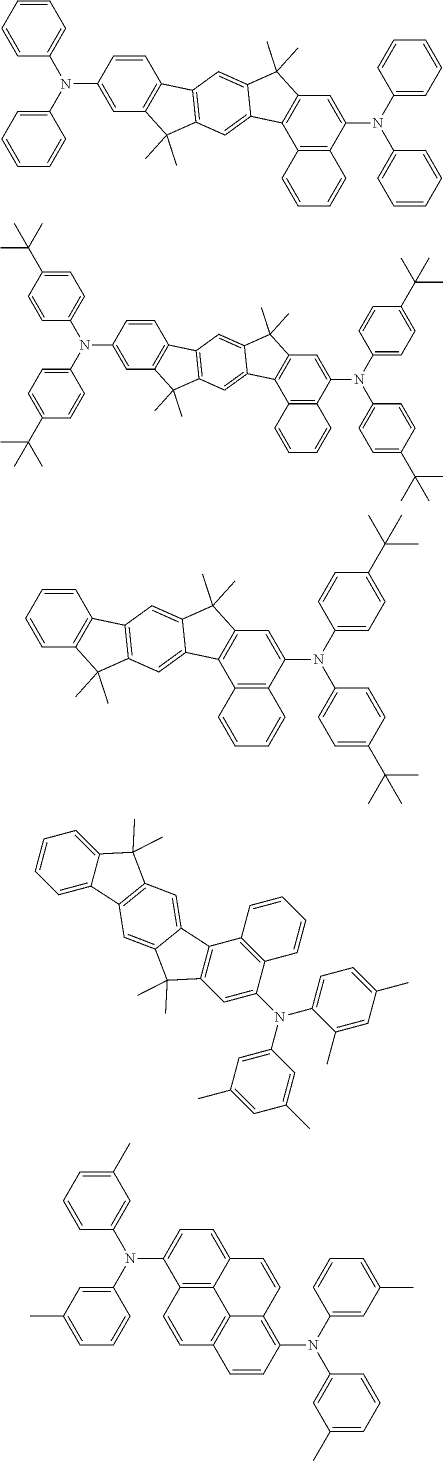

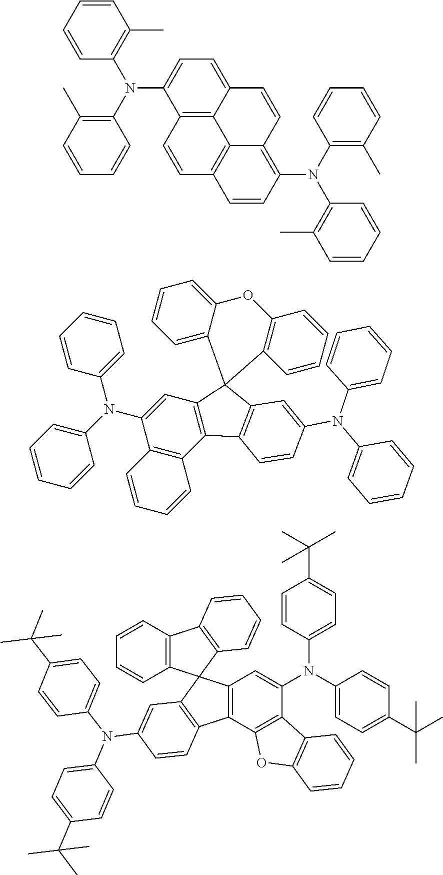

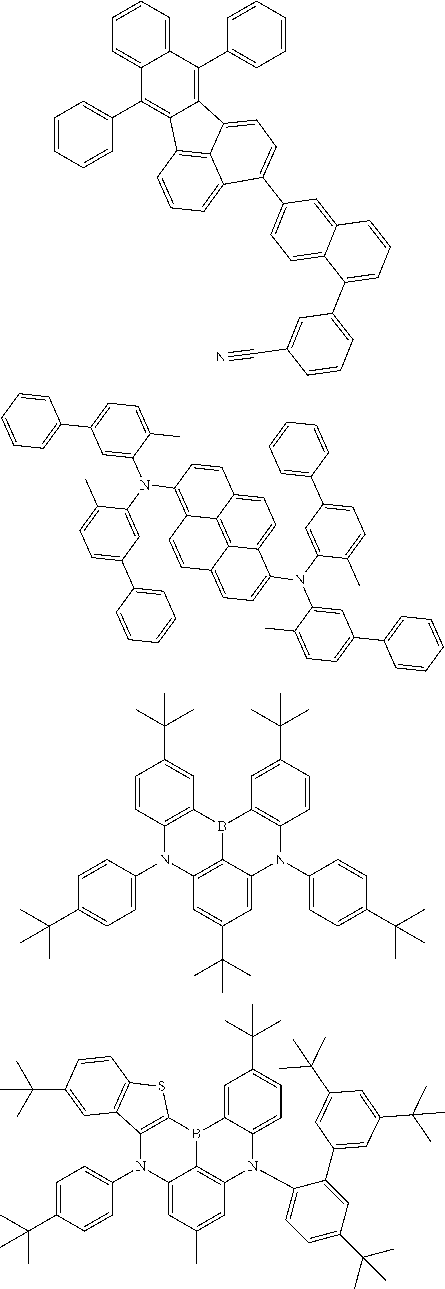

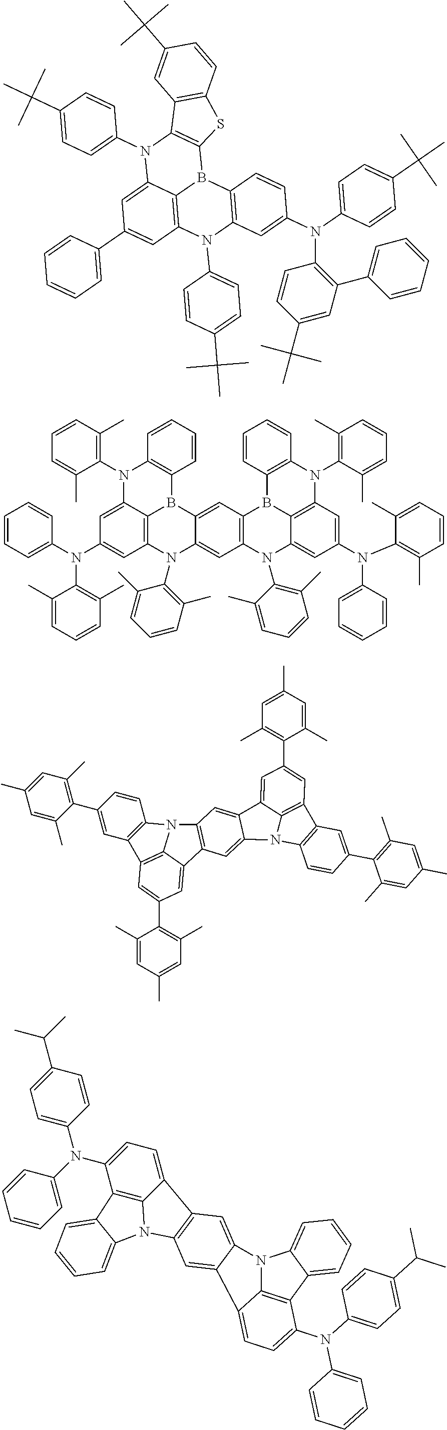

In some embodiments, the first emitter E1 is neither a thermally activated delayed fluorescent (TADF) compound with a D-A structure nor a compound exhibiting aggregation-induced emission (AIE) properties, for stability considerations.

In some embodiments, the S1-T1 of the first emitter E1≥0.25 eV, preferably ≥0.3 eV.

In some embodiments, the first emitter E1 is a compound represented by formula (3):

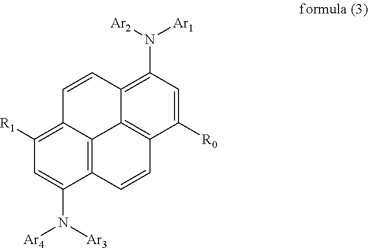

Where R₀—R₁ are defined identically as the above-mentioned R⁴;

Each of Ar₁ to Ar₄ is independently selected from an aromatic group or a heteroaromatic group containing 5 to 60 ring atoms; preferably selected from an aromatic group or a heteroaromatic group containing 6 to 40 ring atoms; more preferably selected from an aromatic group or a heteroaromatic group containing 6 to 30 ring atoms; and most preferably selected from an aromatic group or a heteroaromatic group containing 6 to 20 ring atoms;

In some embodiments, the first emitter E1 is one of the compounds represented by:

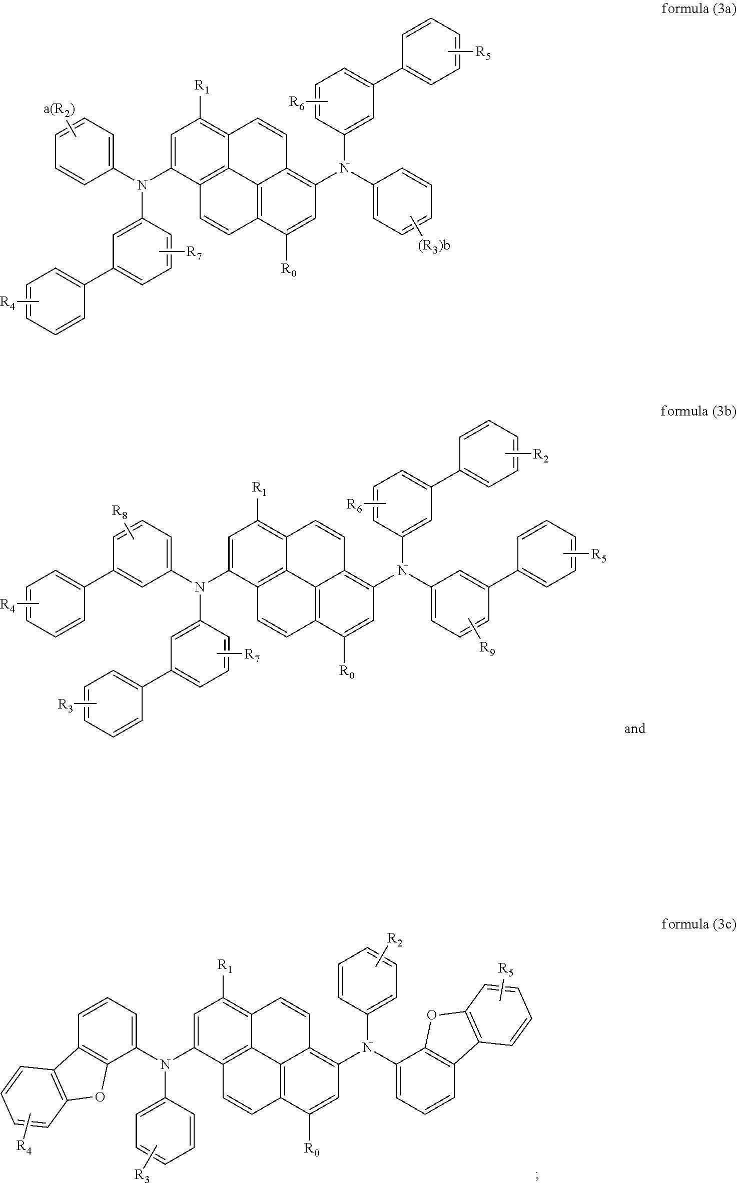

Where R₀—R₉ are defined identically as the above-mentioned R⁴; a and b are integers from 0 to 2, independently.

Examples of conventional singlet emitters that can be used as the first emitters E1 are listed below:

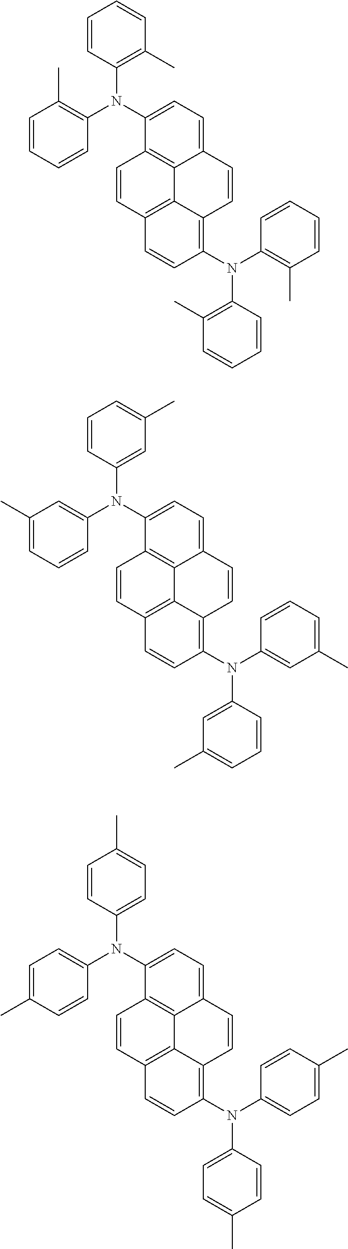

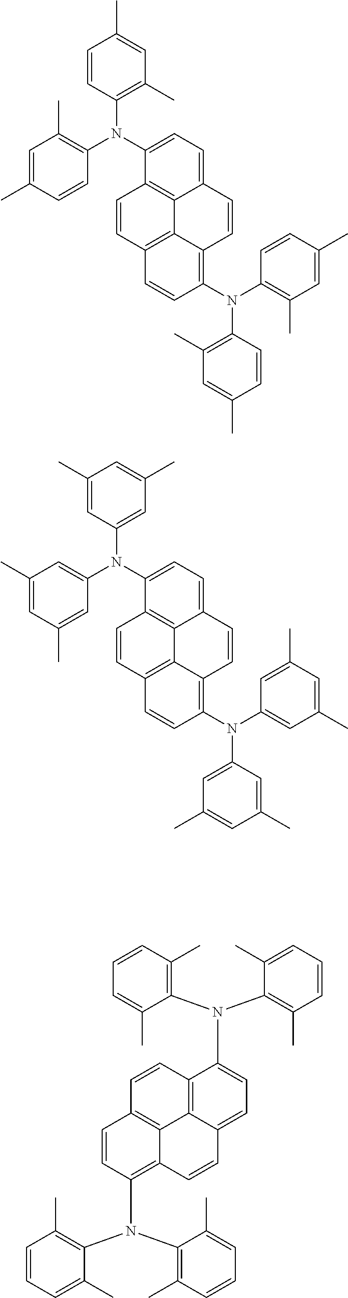

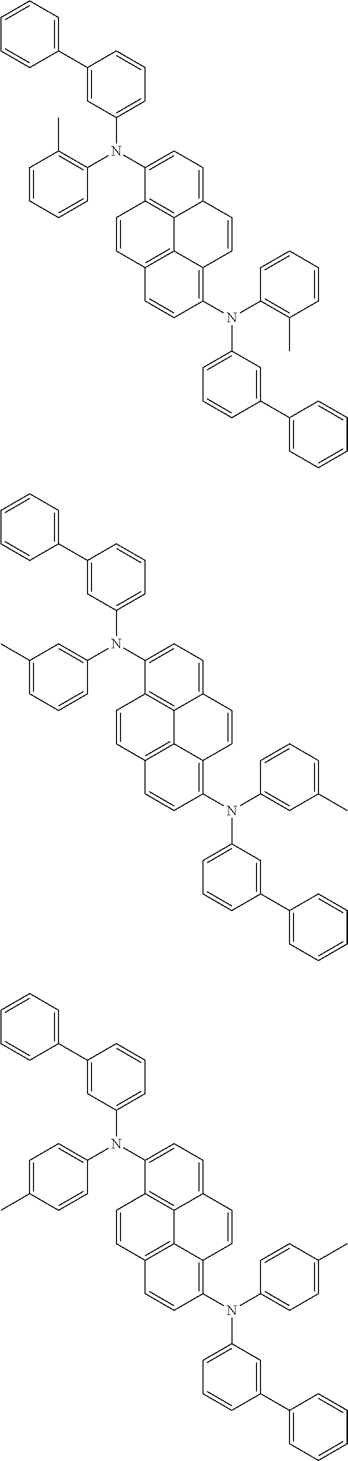 [SMILES: Cc1ccccc1N(c1cccc(-c2ccccc2)c1)c1ccc2ccc3c(N(c4cccc(-c5ccccc5)c4)c4ccccc4C)ccc4ccc1c2c43 ; Cc1cccc(N(c2cccc(-c3ccccc3)c2)c2ccc3ccc4c(N(c5cccc(C)c5)c5cccc(-c6ccccc6)c5)ccc5ccc2c3c54)c1 ; Cc1ccc(N(c2cccc(-c3ccccc3)c2)c2ccc3ccc4c(N(c5ccc(C)cc5)c5cccc(-c6ccccc6)c5)ccc5ccc2c3c54)cc1]

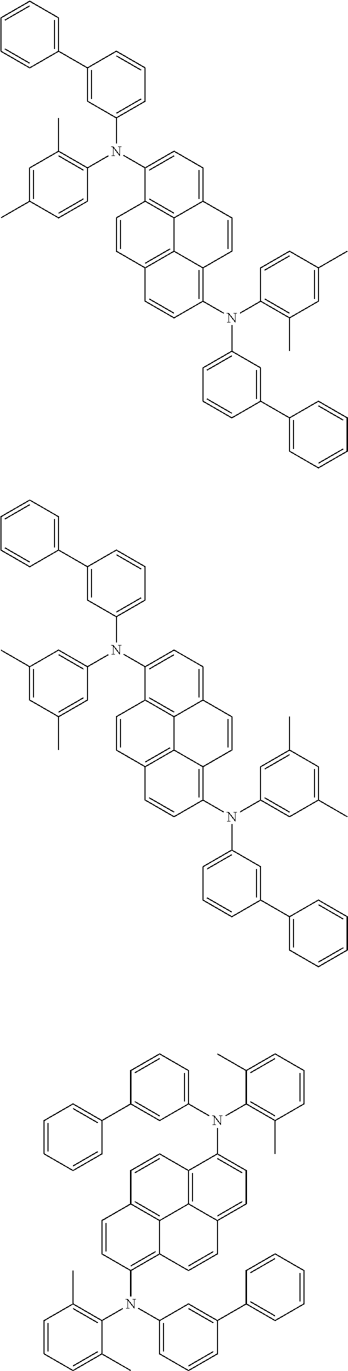 [SMILES: Cc1ccc(N(c2cccc(-c3ccccc3)c2)c2ccc3ccc4c(N(c5cccc(-c6ccccc6)c5)c5ccc(C)cc5C)ccc5ccc2c3c54)c(C)c1 ; Cc1cc(C)cc(N(c2cccc(-c3ccccc3)c2)c2ccc3ccc4c(N(c5cc(C)cc(C)c5)c5cccc(-c6ccccc6)c5)ccc5ccc2c3c54)c1 ; Cc1cccc(C)c1N(c1cccc(-c2ccccc2)c1)c1ccc2ccc3c(N(c4cccc(-c5ccccc5)c4)c4c(C)cccc4C)ccc4ccc1c2c43]

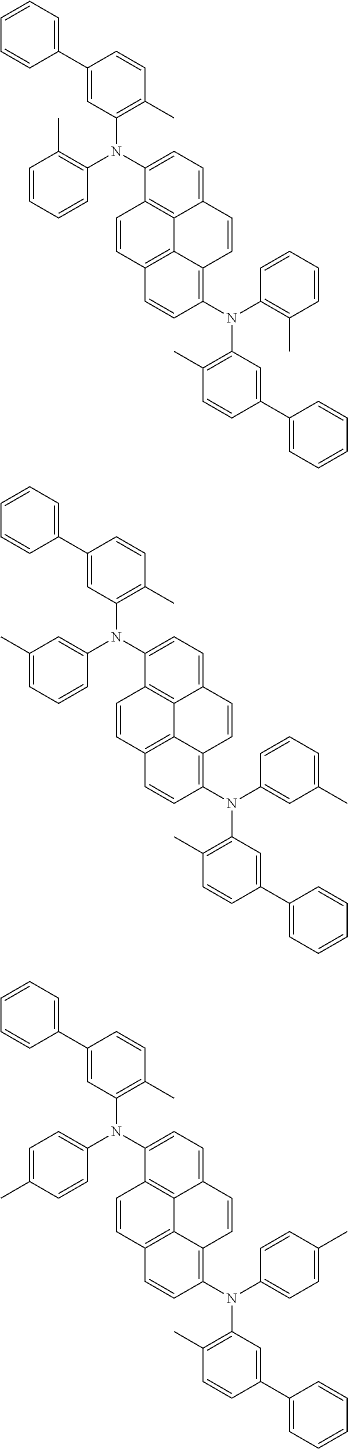 [SMILES: Cc1ccccc1N(c1cc(-c2ccccc2)ccc1C)c1ccc2ccc3c(N(c4ccccc4C)c4cc(-c5ccccc5)ccc4C)ccc4ccc1c2c43 ; Cc1cccc(N(c2cc(-c3ccccc3)ccc2C)c2ccc3ccc4c(N(c5cccc(C)c5)c5cc(-c6ccccc6)ccc5C)ccc5ccc2c3c54)c1 ; Cc1ccc(N(c2cc(-c3ccccc3)ccc2C)c2ccc3ccc4c(N(c5ccc(C)cc5)c5cc(-c6ccccc6)ccc5C)ccc5ccc2c3c54)cc1]

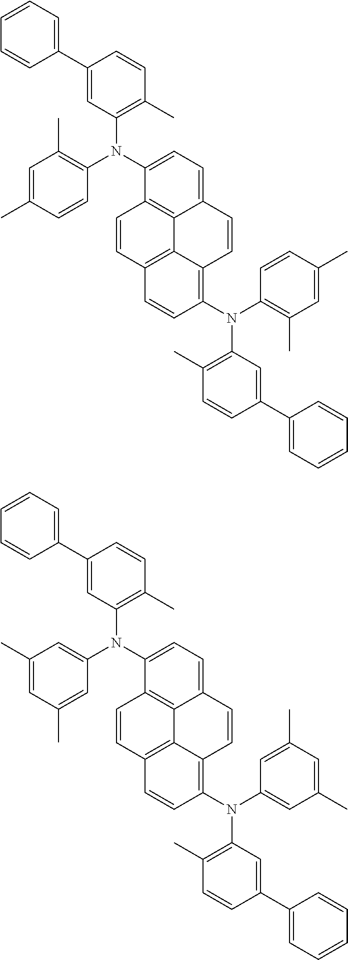 [SMILES: Cc1ccc(N(c2cc(-c3ccccc3)ccc2C)c2ccc3ccc4c(N(c5ccc(C)cc5C)c5cc(-c6ccccc6)ccc5C)ccc5ccc2c3c54)c(C)c1 ; Cc1cc(C)cc(N(c2cc(-c3ccccc3)ccc2C)c2ccc3ccc4c(N(c5cc(C)cc(C)c5)c5cc(-c6ccccc6)ccc5C)ccc5ccc2c3c54)c1]

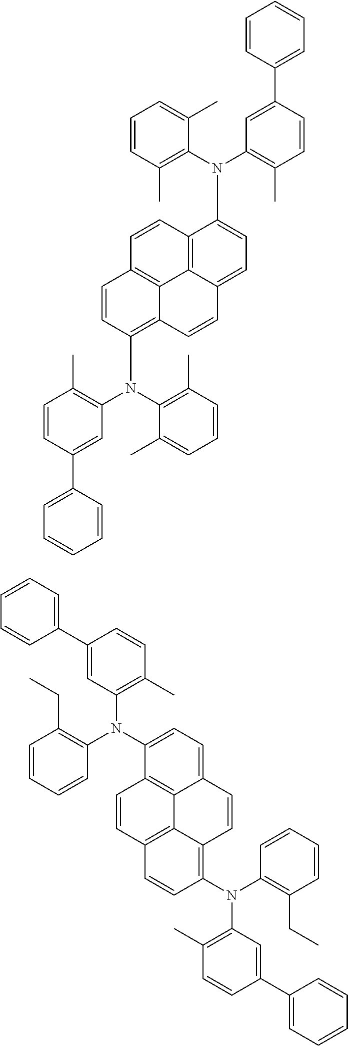

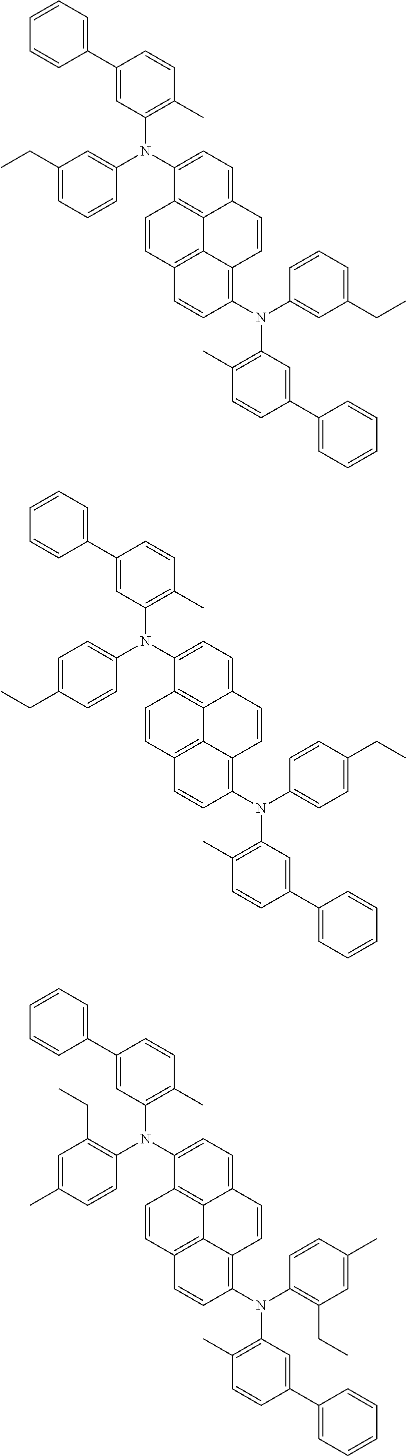

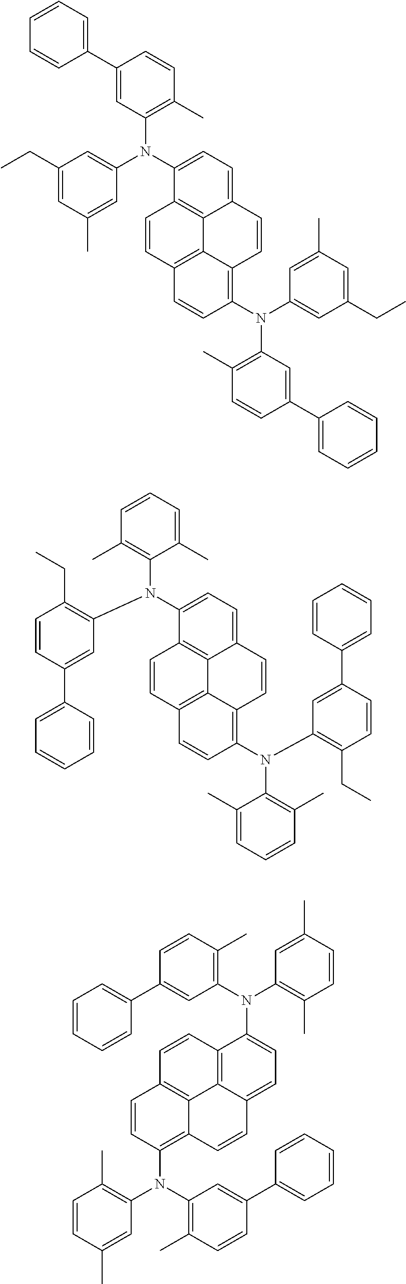 [SMILES: CCc1cc(C)cc(N(c2cc(-c3ccccc3)ccc2C)c2ccc3ccc4c(N(c5cc(C)cc(CC)c5)c5cc(-c6ccccc6)ccc5C)ccc5ccc2c3c54)c1 ; CCc1ccc(-c2ccccc2)cc1N(c1c(C)cccc1C)c1ccc2ccc3c(N(c4cc(-c5ccccc5)ccc4CC)c4c(C)cccc4C)ccc4ccc1c2c43 ; Cc1ccc(C)c(N(c2cc(-c3ccccc3)ccc2C)c2ccc3ccc4c(N(c5cc(C)ccc5C)c5cc(-c6ccccc6)ccc5C)ccc5ccc2c3c54)c1]

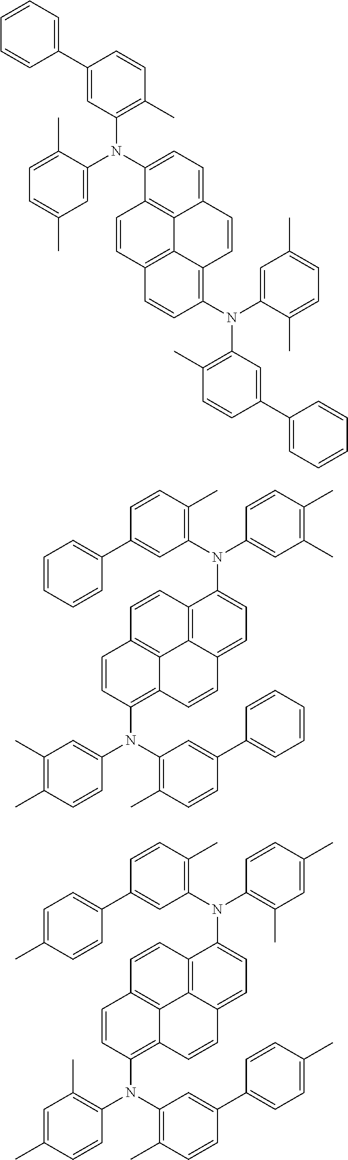

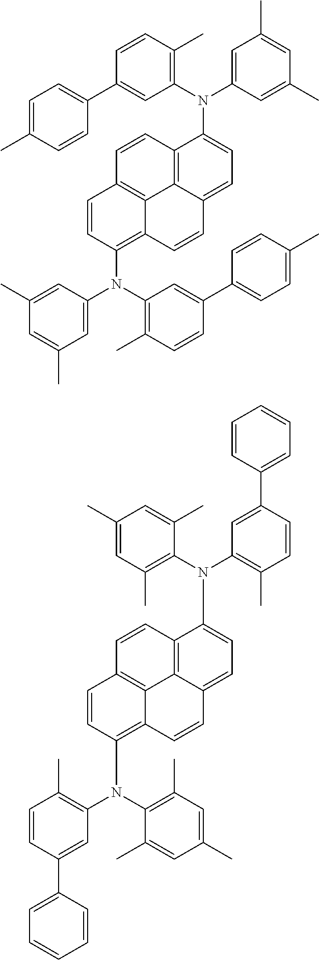

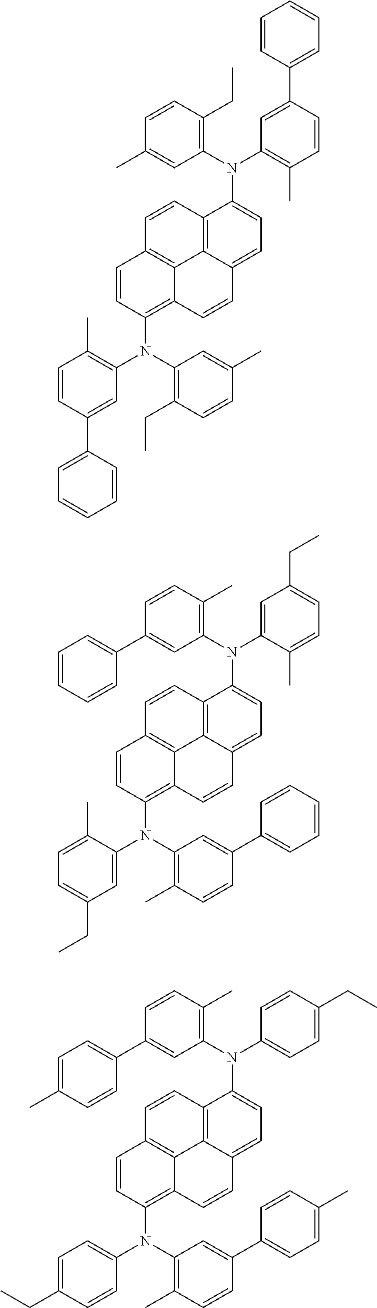 [SMILES: CCc1ccc(C)cc1N(c1cc(-c2ccccc2)ccc1C)c1ccc2ccc3c(N(c4cc(-c5ccccc5)ccc4C)c4cc(C)ccc4CC)ccc4ccc1c2c43 ; CCc1ccc(C)c(N(c2cc(-c3ccccc3)ccc2C)c2ccc3ccc4c(N(c5cc(CC)ccc5C)c5cc(-c6ccccc6)ccc5C)ccc5ccc2c3c54)c1 ; CCc1ccc(N(c2cc(-c3ccc(C)cc3)ccc2C)c2ccc3ccc4c(N(c5ccc(CC)cc5)c5cc(-c6ccc(C)cc6)ccc5C)ccc5ccc2c3c54)cc1]

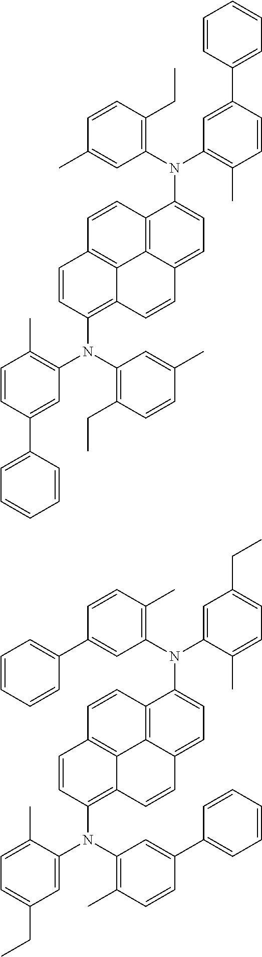 [SMILES: CCc1ccc(C)cc1N(c1cc(-c2ccccc2)ccc1C)c1ccc2ccc3c(N(c4cc(-c5ccccc5)ccc4C)c4cc(C)ccc4CC)ccc4ccc1c2c43 ; CCc1ccc(C)c(N(c2cc(-c3ccccc3)ccc2C)c2ccc3ccc4c(N(c5cc(CC)ccc5C)c5cc(-c6ccccc6)ccc5C)ccc5ccc2c3c54)c1]

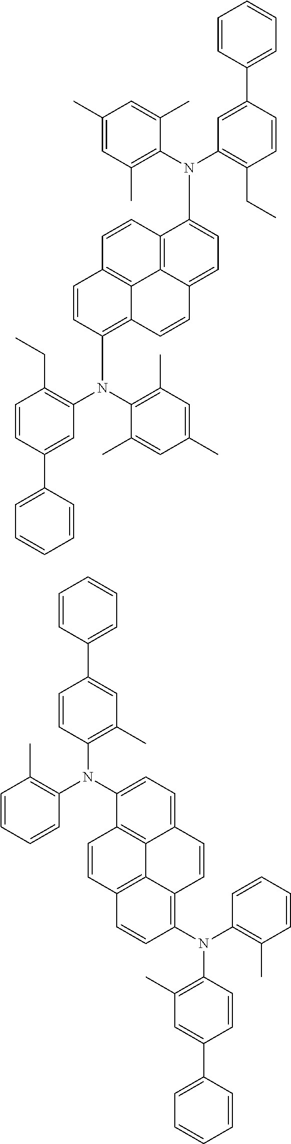

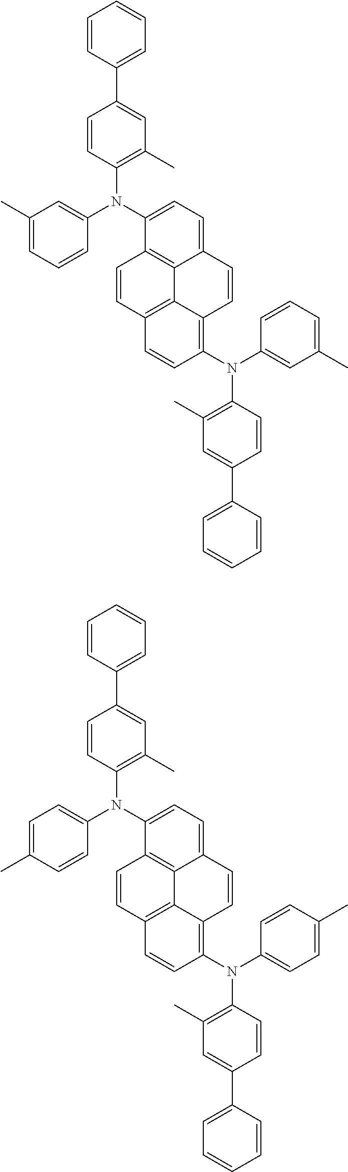

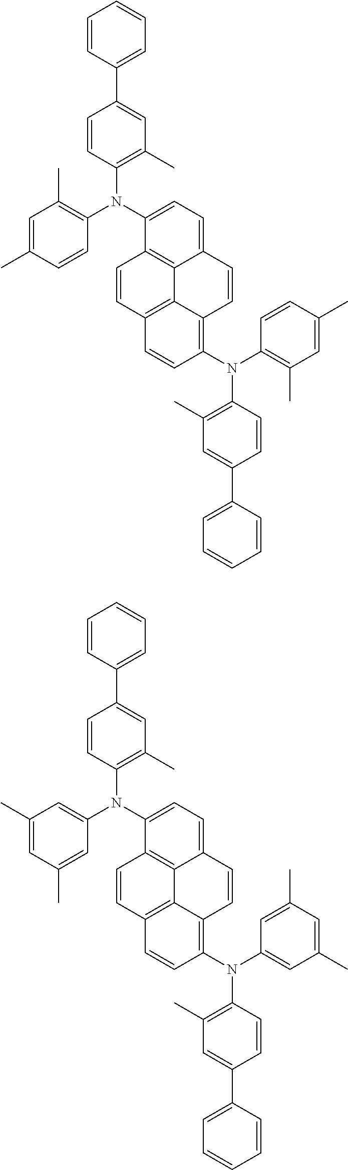

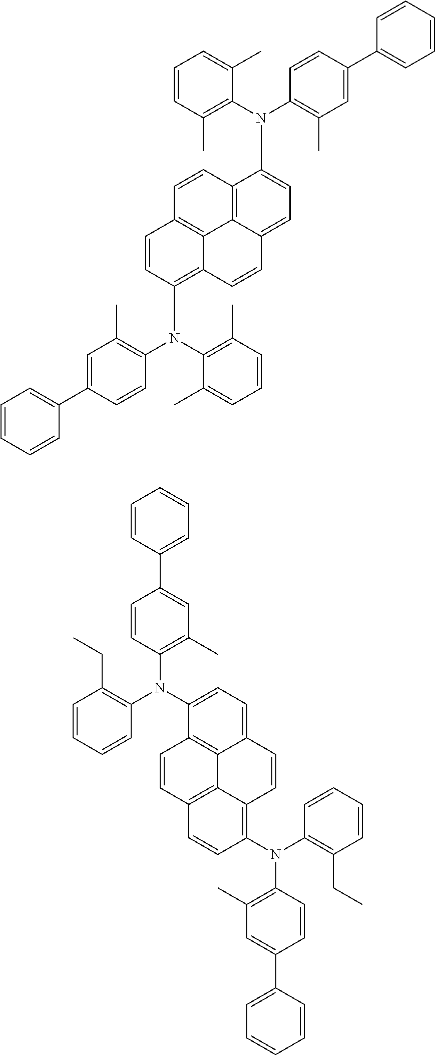 [SMILES: Cc1cc(-c2ccccc2)ccc1N(c1c(C)cccc1C)c1ccc2ccc3c(N(c4ccc(-c5ccccc5)cc4C)c4c(C)cccc4C)ccc4ccc1c2c43 ; CCc1ccccc1N(c1ccc(-c2ccccc2)cc1C)c1ccc2ccc3c(N(c4ccc(-c5ccccc5)cc4C)c4ccccc4CC)ccc4ccc1c2c43]

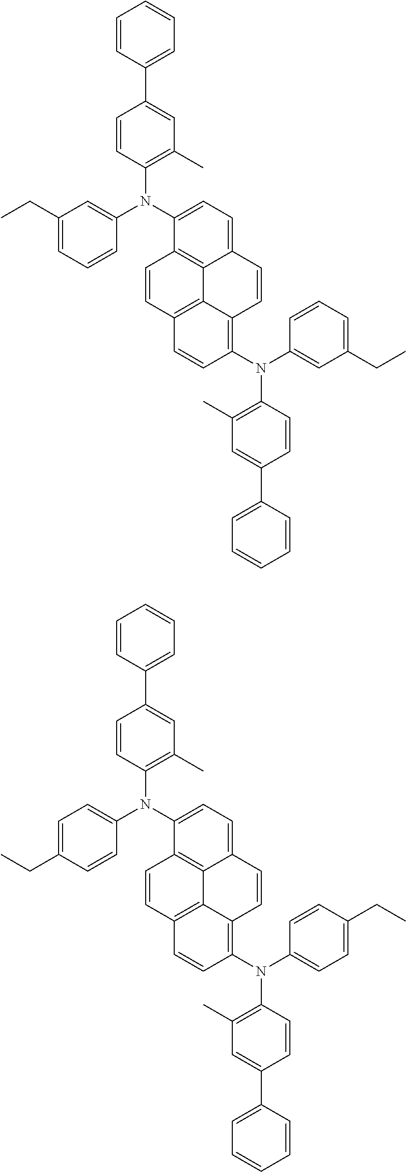

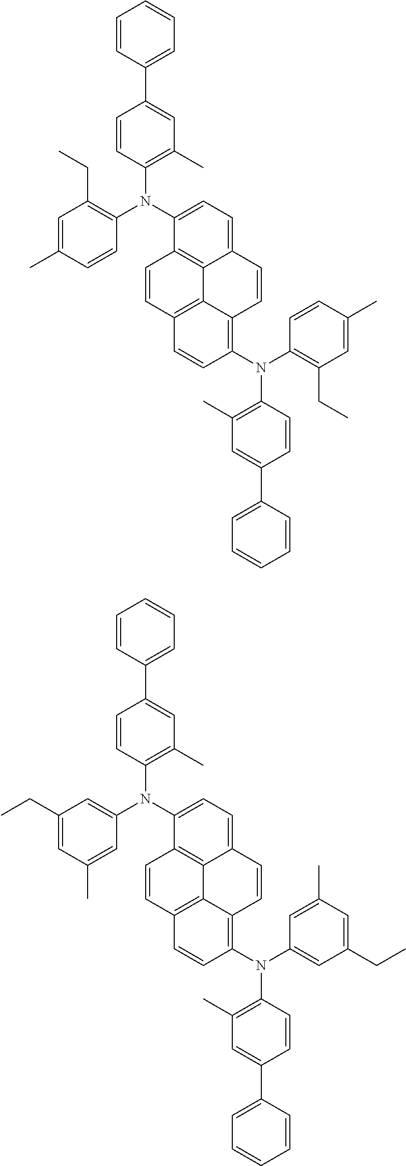

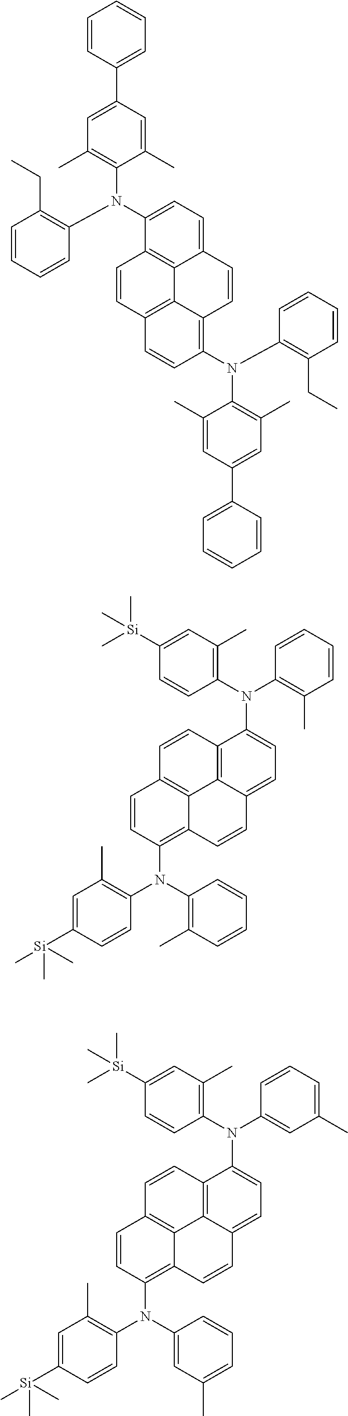

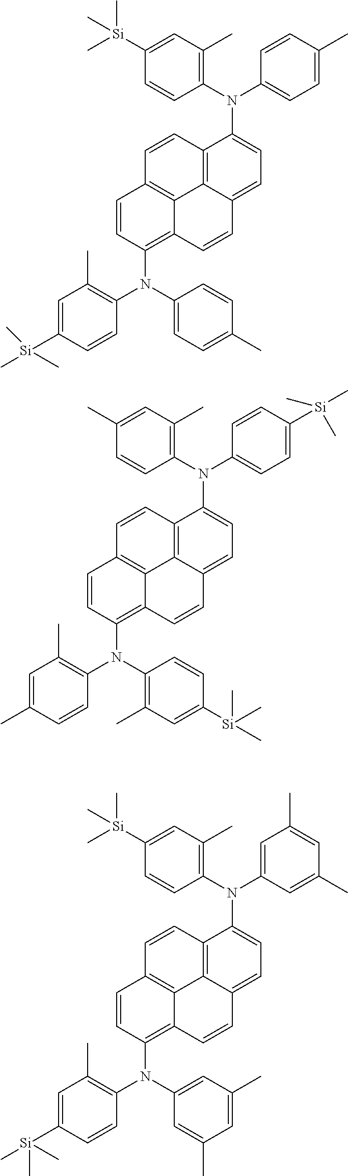

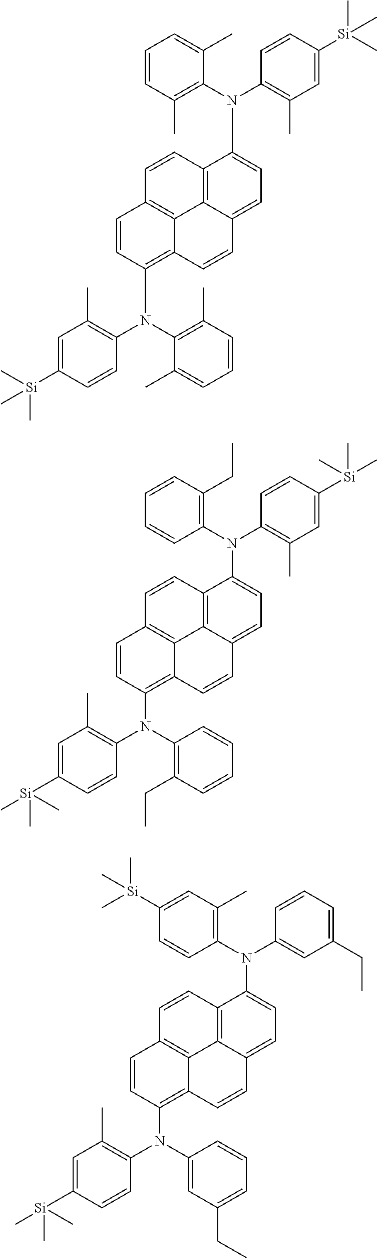

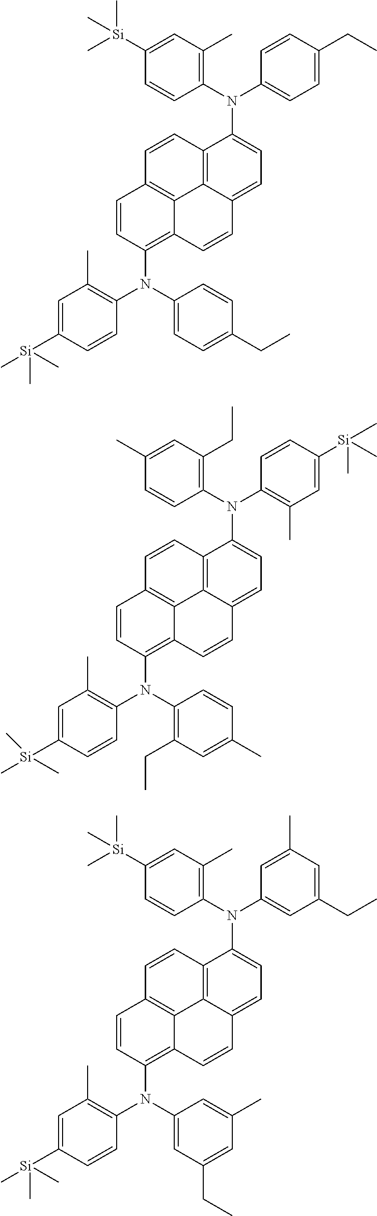

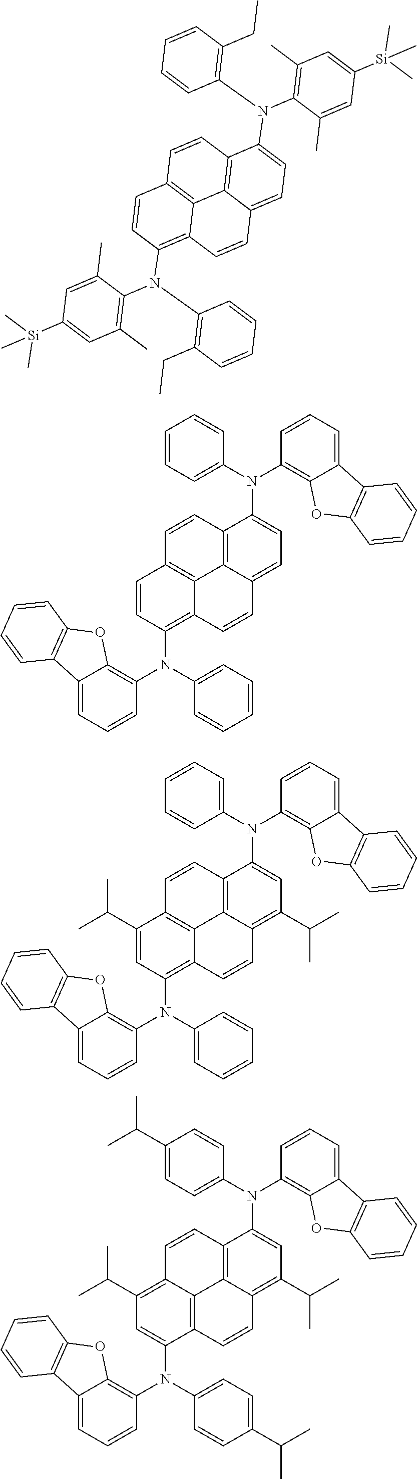

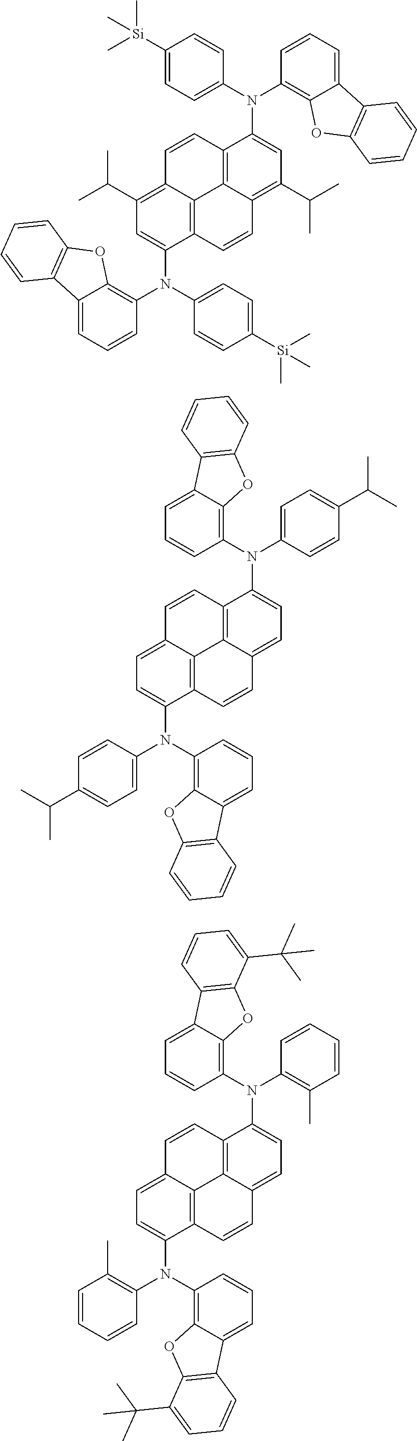

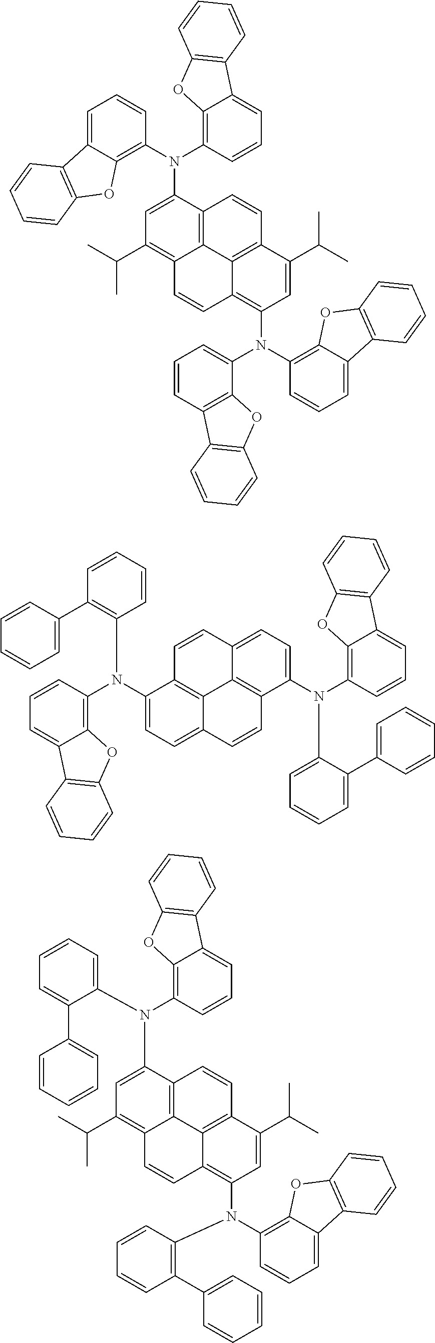 [SMILES: CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34 ; c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; CC(C)c1cc(N(c2ccccc2-c2ccccc2)c2cccc3c2oc2ccccc23)c2ccc3c(C(C)C)cc(N(c4ccccc4-c4ccccc4)c4cccc5c4oc4ccccc45)c4ccc1c2c34]

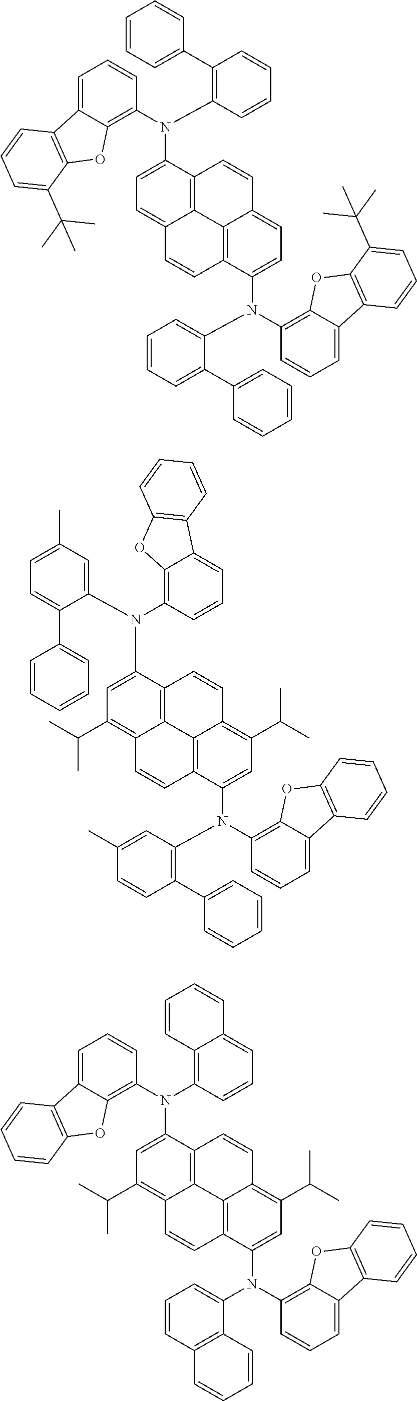 [SMILES: CC(C)(C)c1cccc2c1oc1c(N(c3ccccc3-c3ccccc3)c3ccc4ccc5c(N(c6ccccc6-c6ccccc6)c6cccc7c6oc6c(C(C)(C)C)cccc67)ccc6ccc3c4c65)cccc12 ; Cc1ccc(-c2ccccc2)c(N(c2cc(C(C)C)c3ccc4c(N(c5cc(C)ccc5-c5ccccc5)c5cccc6c5oc5ccccc56)cc(C(C)C)c5ccc2c3c54)c2cccc3c2oc2ccccc23)c1 ; CC(C)c1cc(N(c2cccc3ccccc23)c2cccc3c2oc2ccccc23)c2ccc3c(C(C)C)cc(N(c4cccc5ccccc45)c4cccc5c4oc4ccccc45)c4ccc1c2c34]

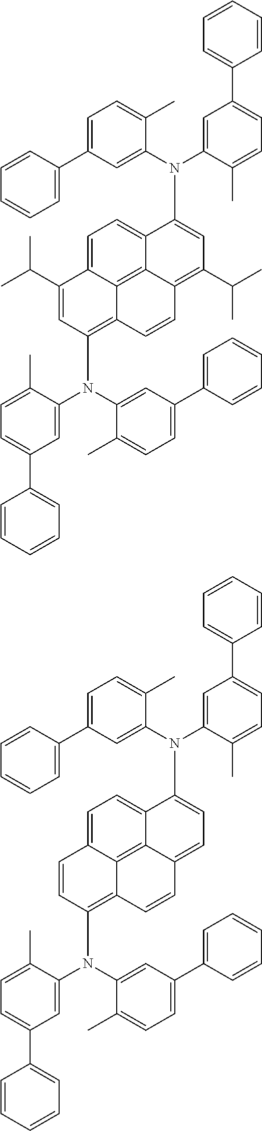 [SMILES: Cc1ccc(-c2ccccc2)cc1N(c1cc(-c2ccccc2)ccc1C)c1cc(C(C)C)c2ccc3c(N(c4cc(-c5ccccc5)ccc4C)c4cc(-c5ccccc5)ccc4C)cc(C(C)C)c4ccc1c2c43 ; Cc1ccc(-c2ccccc2)cc1N(c1cc(-c2ccccc2)ccc1C)c1ccc2ccc3c(N(c4cc(-c5ccccc5)ccc4C)c4cc(-c5ccccc5)ccc4C)ccc4ccc1c2c43]

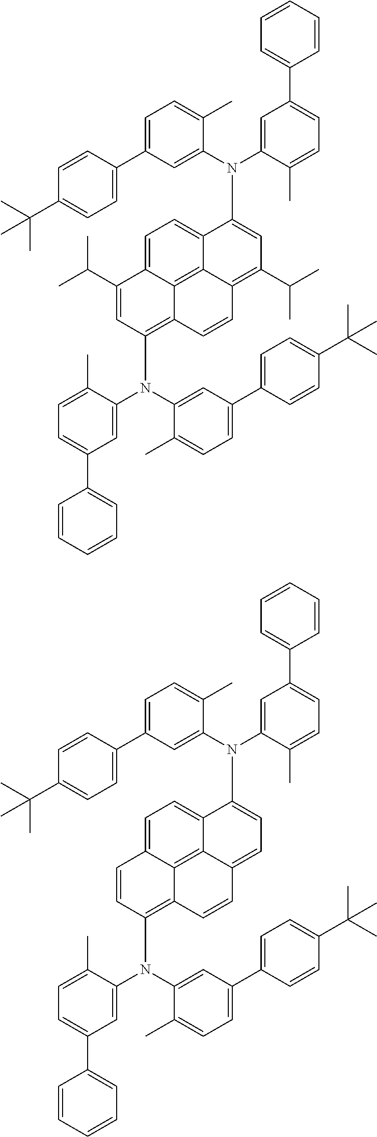

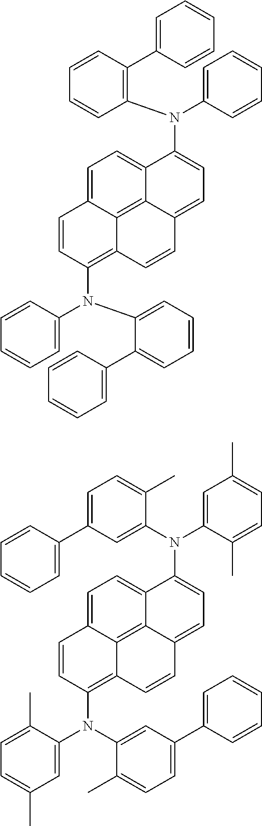 [SMILES: c1ccc(-c2ccccc2N(c2ccccc2)c2ccc3ccc4c(N(c5ccccc5)c5ccccc5-c5ccccc5)ccc5ccc2c3c54)cc1 ; Cc1ccc(C)c(N(c2cc(-c3ccccc3)ccc2C)c2ccc3ccc4c(N(c5cc(C)ccc5C)c5cc(-c6ccccc6)ccc5C)ccc5ccc2c3c54)c1]

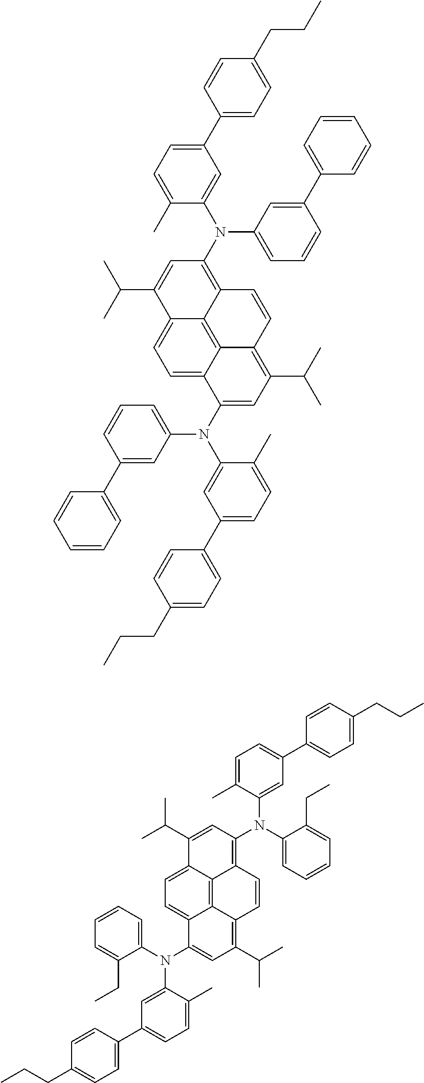 [SMILES: CCCc1ccc(-c2ccc(C)c(N(c3cccc(-c4ccccc4)c3)c3cc(C(C)C)c4ccc5c(N(c6cccc(-c7ccccc7)c6)c6cc(-c7ccc(CCC)cc7)ccc6C)cc(C(C)C)c6ccc3c4c65)c2)cc1 ; CCCc1ccc(-c2ccc(C)c(N(c3ccccc3CC)c3cc(C(C)C)c4ccc5c(N(c6cc(-c7ccc(CCC)cc7)ccc6C)c6ccccc6CC)cc(C(C)C)c6ccc3c4c65)c2)cc1]

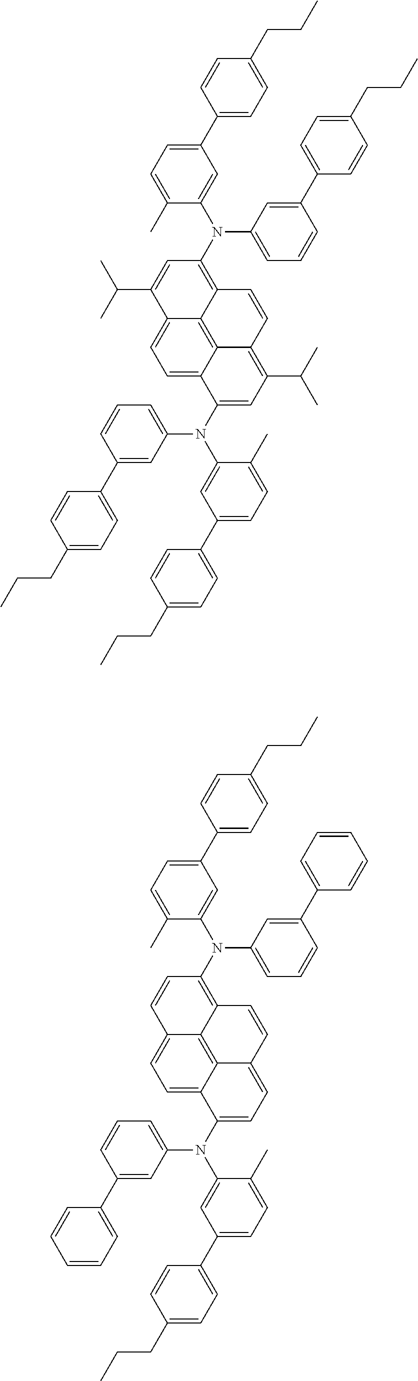 [SMILES: CCCc1ccc(-c2cccc(N(c3cc(-c4ccc(CCC)cc4)ccc3C)c3cc(C(C)C)c4ccc5c(N(c6cccc(-c7ccc(CCC)cc7)c6)c6cc(-c7ccc(CCC)cc7)ccc6C)cc(C(C)C)c6ccc3c4c65)c2)cc1 ; CCCc1ccc(-c2ccc(C)c(N(c3cccc(-c4ccccc4)c3)c3ccc4ccc5c(N(c6cccc(-c7ccccc7)c6)c6cc(-c7ccc(CCC)cc7)ccc6C)ccc6ccc3c4c65)c2)cc1]

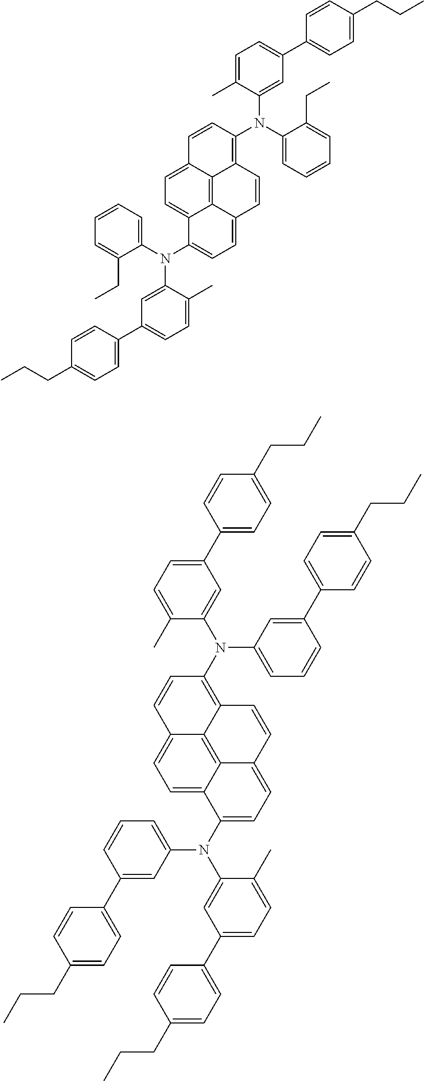

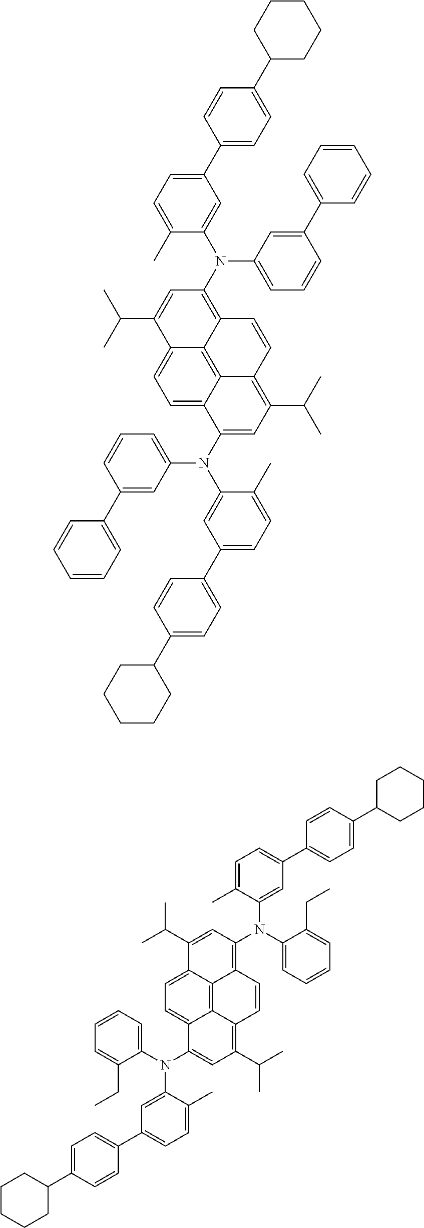 [SMILES: Cc1ccc(-c2ccc(C3CCCCC3)cc2)cc1N(c1cccc(-c2ccccc2)c1)c1cc(C(C)C)c2ccc3c(N(c4cccc(-c5ccccc5)c4)c4cc(-c5ccc(C6CCCCC6)cc5)ccc4C)cc(C(C)C)c4ccc1c2c43 ; CCc1ccccc1N(c1cc(-c2ccc(C3CCCCC3)cc2)ccc1C)c1cc(C(C)C)c2ccc3c(N(c4cc(-c5ccc(C6CCCCC6)cc5)ccc4C)c4ccccc4CC)cc(C(C)C)c4ccc1c2c43]

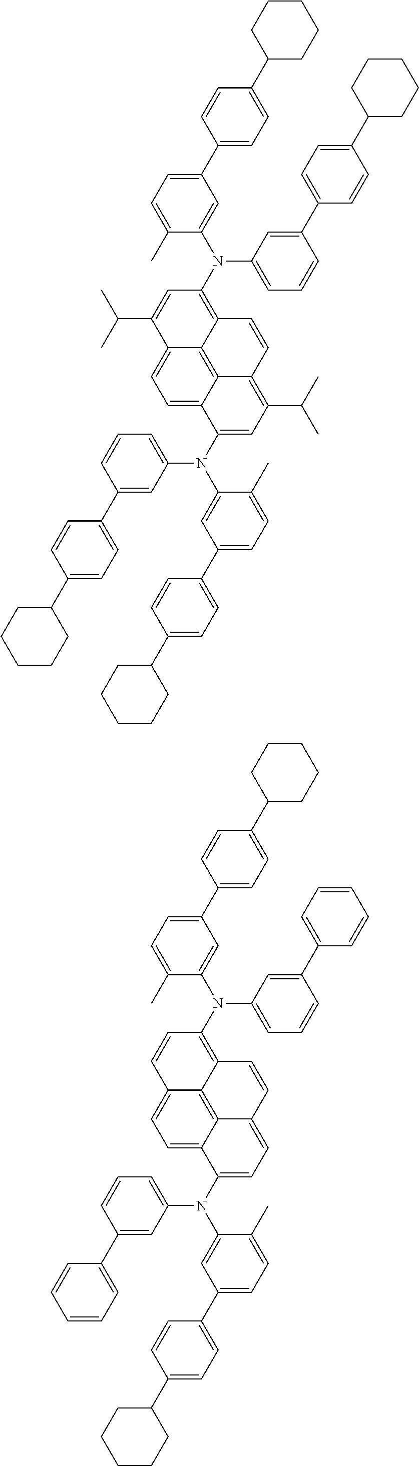

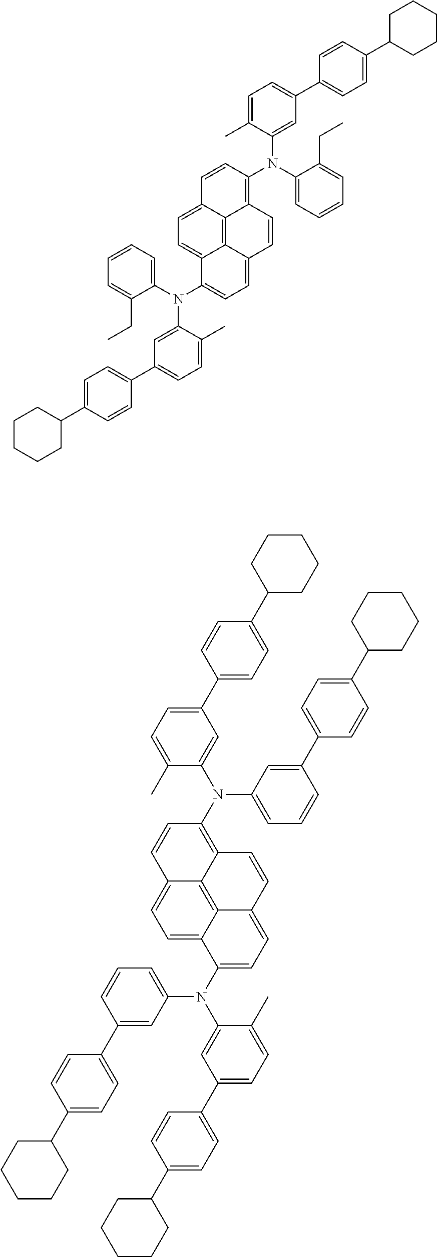 [SMILES: CCc1ccccc1N(c1cc(-c2ccc(C3CCCCC3)cc2)ccc1C)c1ccc2ccc3c(N(c4cc(-c5ccc(C6CCCCC6)cc5)ccc4C)c4ccccc4CC)ccc4ccc1c2c43 ; Cc1ccc(-c2ccc(C3CCCCC3)cc2)cc1N(c1cccc(-c2ccc(C3CCCCC3)cc2)c1)c1ccc2ccc3c(N(c4cccc(-c5ccc(C6CCCCC6)cc5)c4)c4cc(-c5ccc(C6CCCCC6)cc5)ccc4C)ccc4ccc1c2c43]

In the organic mixture as described herein, the absorption spectrum of the second emitter E2 and the emission spectrum of the first emitter E1 have a substantial overlap, so that efficient energy transfer can be realized therebetween.

In some embodiments, the absorption spectrum peak of the second emitter E2 (λ2) is on the short wavelength side of the emission spectrum peak of the first emitter E1 (M1), and there is significant overlap between them.

In some embodiments, the absorption spectrum peak of the second emitter E2 (λ2) is on the long wavelength side of the emission spectrum peak of the first emitter E1 (M1), and there is significant overlap between them.

Preferably, the difference between the emission spectrum peak of the first emitter E1 (λ1) and the absorption spectrum peak of the second emitter E2 (λ2)≤10 nm, preferably ≤8 nm, more preferably ≤5 nm, further preferably ≤3 nm, and most preferably ≤2 nm.

In some embodiments, the absorption spectrum peak of the second emitter E2 (λ2) is between the emission spectrum peak of the first emitter E1 (λ1) and the absorption spectrum peak of the first emitter E1 (λ3).

In some embodiments, the emission spectrum peak of the first emitter E1 (λ1) is between the absorption spectrum peak of the second emitter E2 (λ2) and the absorption spectrum peak of the first emitter E1 (λ3).

In some embodiments, the emission spectrum of the organic mixture is derived exclusively from the second emitter E2, i.e., a complete energy transfer is realized between the first emitter E1 and the second emitter E2.

In some embodiments, the emission spectrum peak of the first emitter E1 (λ1) is between 400 nm and 700 nm, preferably between 410 nm and 600 nm, more preferably between 420 nm and 500 nm, and most preferably between 430 nm and 460 nm.

In some embodiments, the emission spectrum peak of the first emitter E1 (λ1) is between 440 nm and 460 nm.

In some embodiments, the emission spectrum peak of the second emitter E2 (λ4) is between 400 nm and 800 nm, preferably between 450 nm and 750 nm, and most preferably between 450 nm and 700 nm.

In some embodiments, the emission spectrum peak of the second emitter E2 (λ4) is between 455 nm and 465 nm.

In some embodiments, the emission spectrum peak of the second emitter E2 is between 520 nm and 535 nm.

In some embodiments, the absorption spectrum peak of the first emitter E1 (λ3) is between 350 nm and 600 nm, preferably between 400 nm and 500 nm, and most preferably between 420 nm and 460 nm.

In some embodiments, the absorption spectrum peak of the first emitter E1 (λ3) is between 425 nm and 445 nm.

In some embodiments, the absorption spectrum peak of the second emitter E2 (22) is between 350 nm and 600 nm, preferably between 400 nm and 500 nm, and most preferably between 440 nm and 460 nm.

In some embodiments, the absorption spectrum peak of the second emitter E2 (22) is between 445 nm and 455 nm.

In some embodiments, in the organic mixture as described herein, the weight ratio of the first emitter E1 and the second emitter E2 ranges from 10:90 to 90:10, preferably from 20:80 to 80:20, more preferably from 70:30 to 30:70, further preferably from 60:40 to 40:60, and most preferably from 55:45 to 45:55.

In some embodiments, the organic mixture further comprises a host material H. A suitable host material H may be a singlet host material.

Examples of singlet host materials are not specially limited, any organic compound may be used as a host, as long as its singlet energy is higher than that of the first emitter E1/the second emitter E2.

Examples of the organic compound used as the singlet host material may be selected from cyclic aromatic hydrocarbon compound, such as benzene, biphenyl, triphenylbenzene, benzophenanthrene, triphenylene, naphthalene, anthracene, phenalene, phenanthrene, fluorene, pyrene, chrysene, perylene, azulene. The organic compound used as the singlet host material may be also selected from aromatic heterocyclic compound, such as dibenzothiophene, dibenzofuran, dibenzoselenophene, furan, thiophene, benzofuran, benzothiophene, benzoselenophene, carbazole, indocarbazole, pyridindole, pyrroledipyridine, pyrazole, imidazole, 1,2,4-triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, benzoisoxazole benzothiazole, quinoline, isoquinoline, cinnoline, quinazoline, quinoxaline, naphthalene, phthalein, pteridine, xanthene, acridine, phenazine, phenothiazine, phenoxazine, benzofuranopyridine, furandipyridine, benzothienopyridine, thiophenedipyridine, benzoselenophenopyridine, or selenophenodipyridine. The organic compound used as the singlet host material may be selected from groups containing 2 to 10 ring atoms, which may be the same or different types of cyclic aryl or heterocyclic aryl, and are linked to each other directly or by at least one of the following groups, such as oxygen atom, nitrogen atom, sulfur atom, silicon atom, phosphorus atom, boron atom, chain structural units, or aliphatic ring groups.

In some embodiments, the singlet host materials may be selected from the compounds comprising at least one of the following groups:

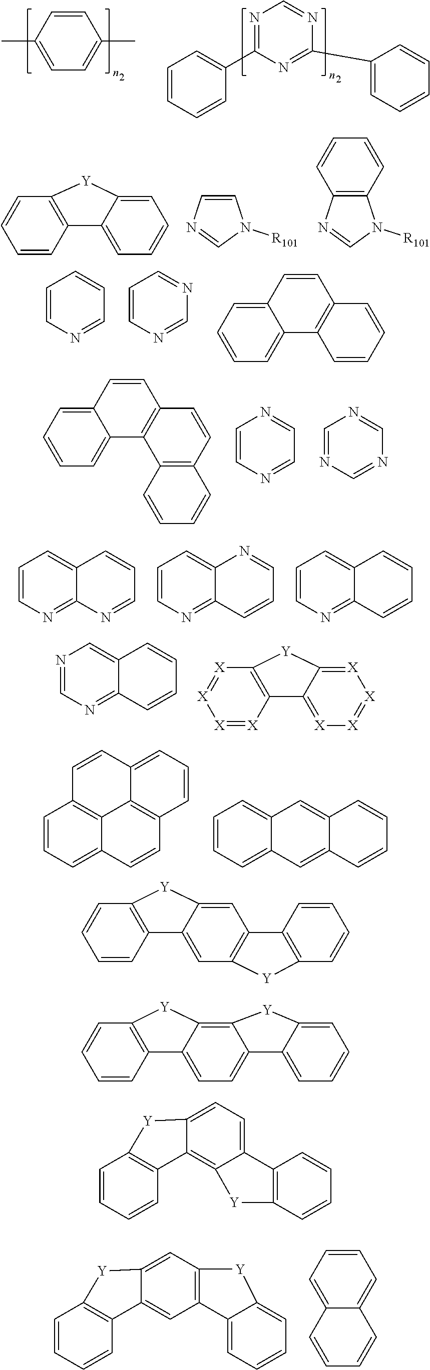

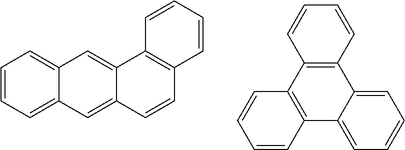

Each Y is independently selected from C(R₁₀₁)₂, NR₁₀₁, O, or S; each X is independently CR₁₀₁ or N; each R₁₀₁ is independently selected from: hydrogen, deuterium, halogen atoms (F, Cl, Br, I), cyano, alkyl, alkoxy, amino, alkenyl, alkynyl, aralkyl, heteroalkyl, aryl, or heteroaryl; n₂ is an integer from 1 to 20.

In some embodiments, the singlet hosts are selected from anthracene derivatives, such examples are disclosed in the patents such as CN102224614B, US2014246657A1, etc.

In some embodiments, the host material H is one of the compounds represented by formula (4-1) or formula (4-2):

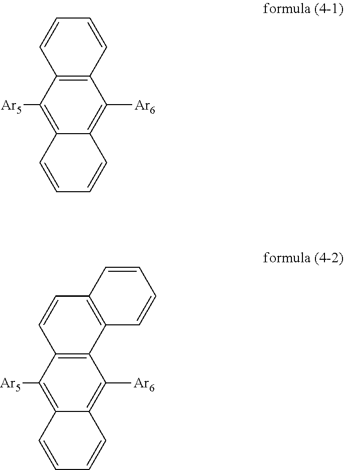

Where Ar₅ and Ar₆ are defined identically as the above-mentioned Ar₁.

In some embodiments, each of Ar₅ and Ar₆ is independently selected from benzene, naphthalene, dibenzofuran, naphthobenzofuran, carbazole, or any combination thereof.

Some examples of singlet host materials those may be used as the host material H are list below:

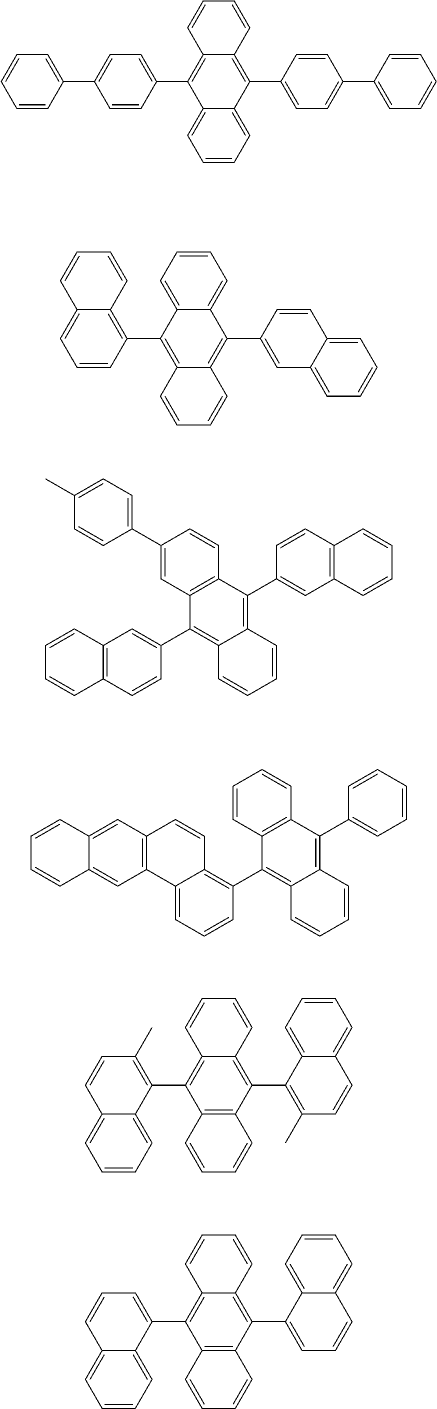

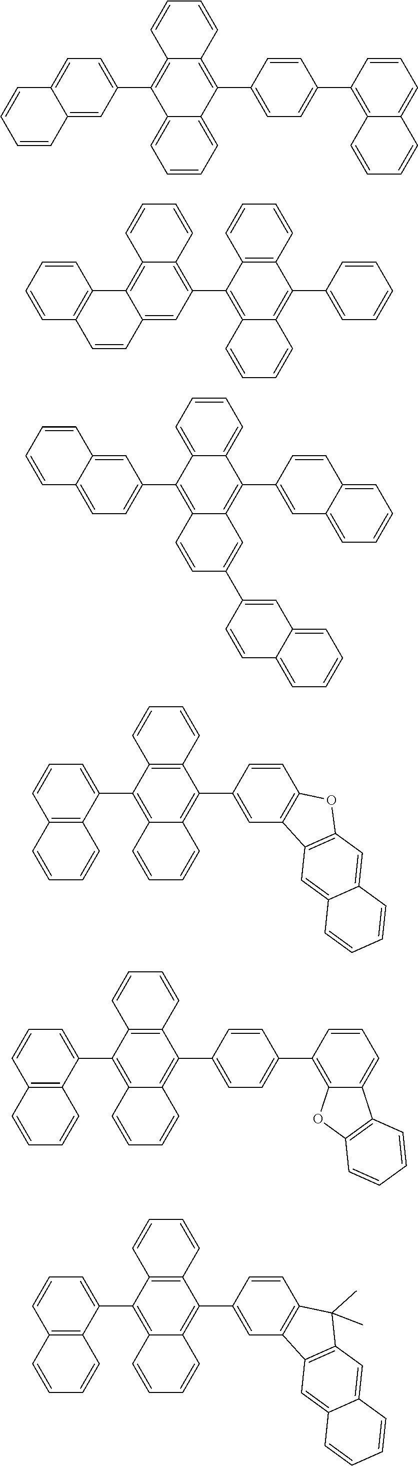

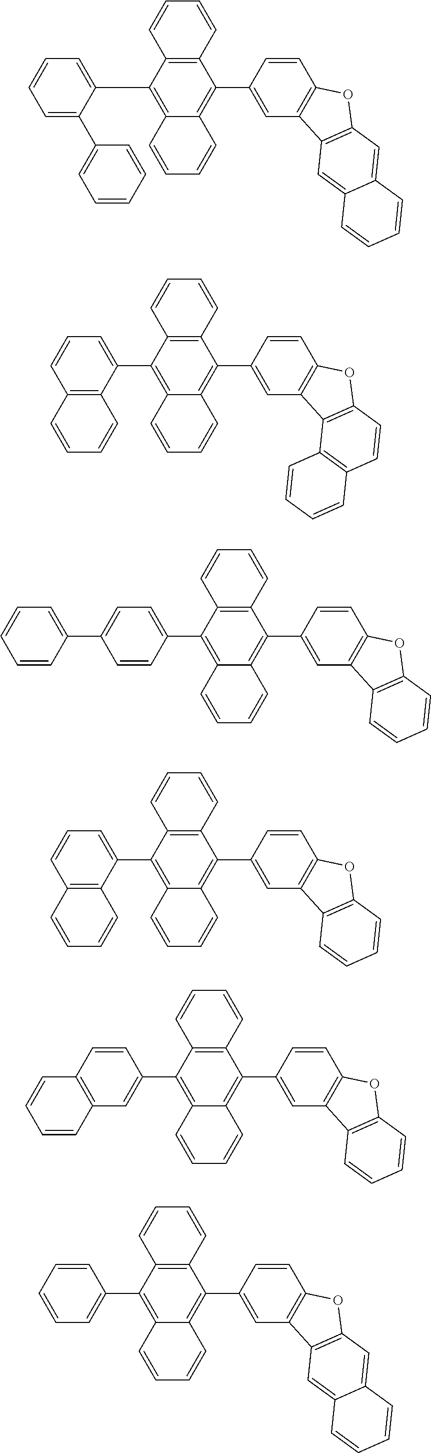

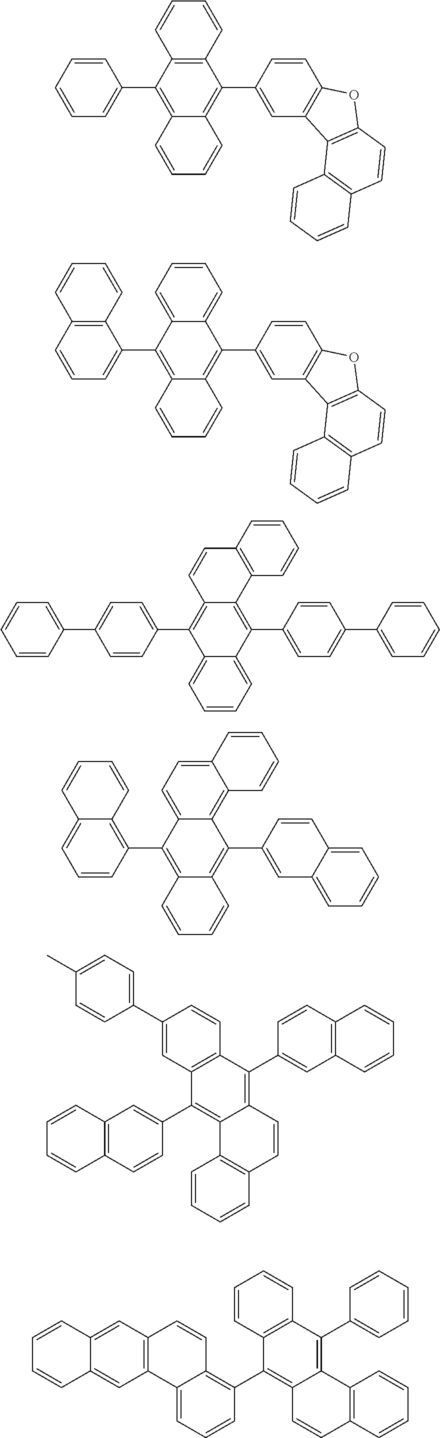

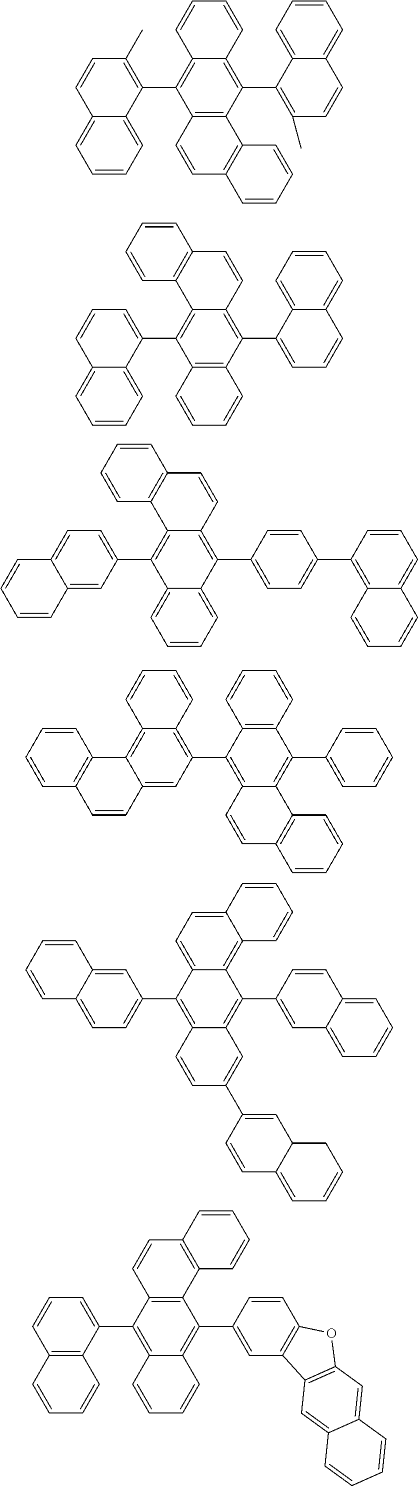

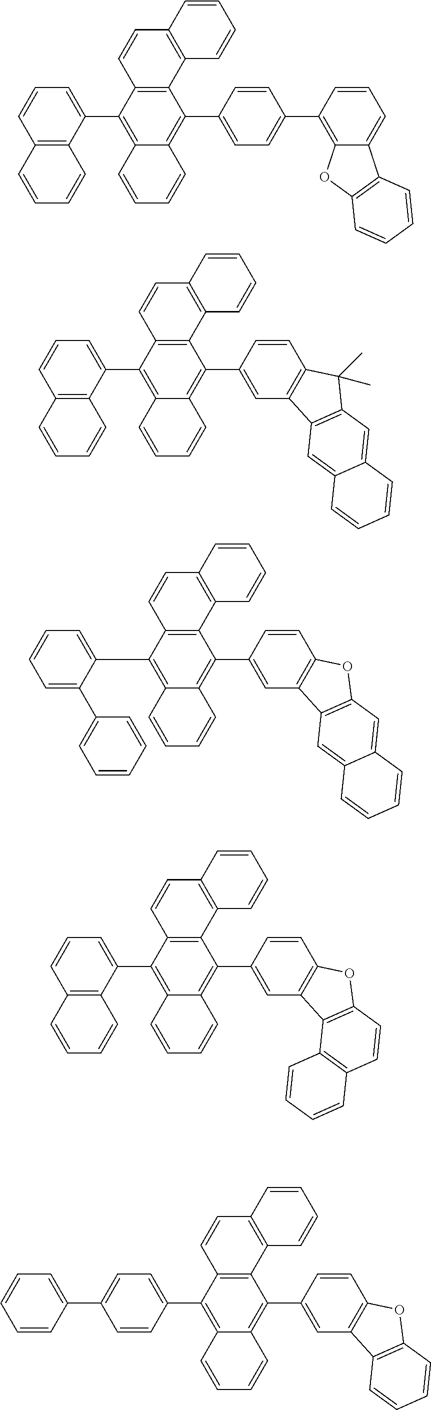

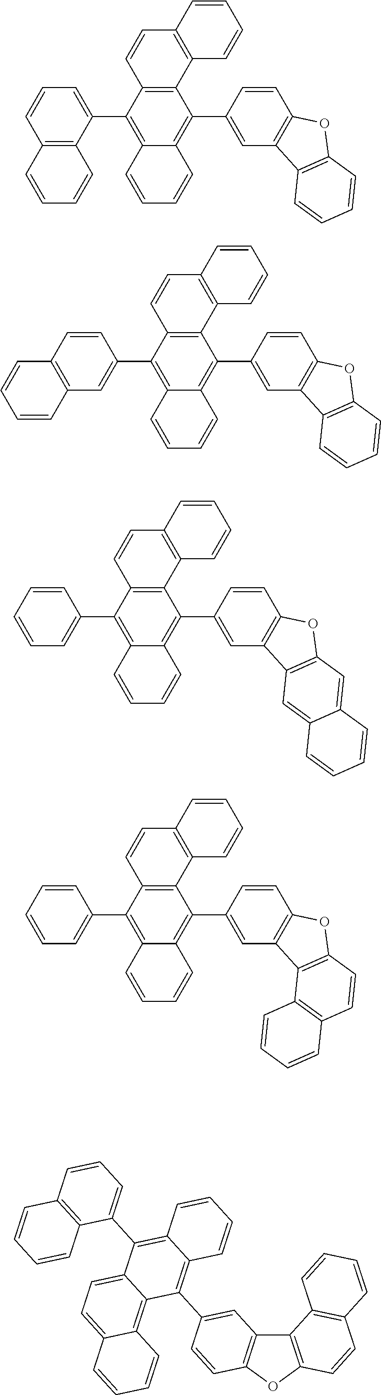 [SMILES: c1ccc2c(-c3c4ccccc4c(-c4ccc5oc6ccccc6c5c4)c4c3ccc3ccccc34)cccc2c1 ; c1ccc2cc(-c3c4ccccc4c(-c4ccc5oc6ccccc6c5c4)c4c3ccc3ccccc34)ccc2c1 ; c1ccc(-c2c3ccccc3c(-c3ccc4oc5cc6ccccc6cc5c4c3)c3c2ccc2ccccc23)cc1 ; c1ccc(-c2c3ccccc3c(-c3ccc4oc5ccc6ccccc6c5c4c3)c3c2ccc2ccccc23)cc1 ; c1ccc2c(-c3c4ccccc4c(-c4ccc5oc6ccc7ccccc7c6c5c4)c4c3ccc3ccccc34)cccc2c1]

In some embodiments, the anthracene-based singlet host materials as the host material H are deuterated, i.e., the host material molecule contains at least one deuterium atom, such examples are disclosed in the patents such as US2015021586A1, etc. The specific examples include:

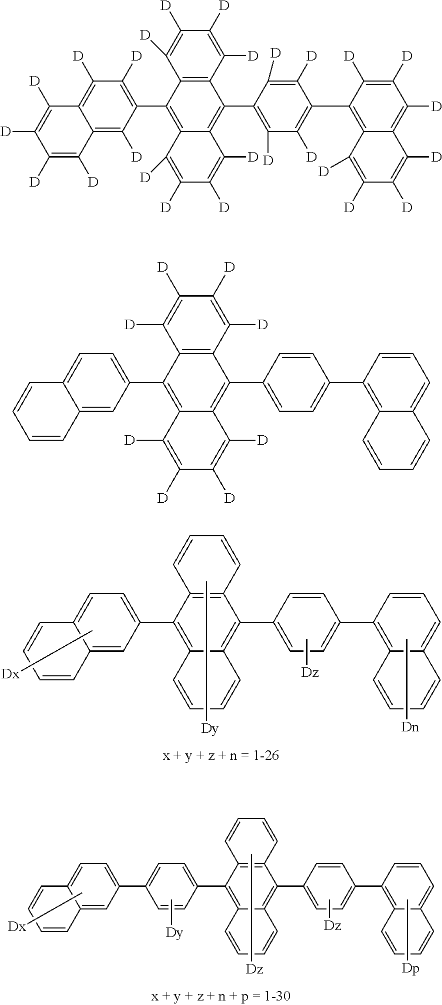

Another object of the present disclosure is to provide a material for the printed OLEDs.

For this purpose, in the organic mixture as described herein, at least one of the first emitter E1, the second emitter E2, and/or the host material H has a molecular weight 700 g/mol, preferably 800 g/mol, more preferably 900 g/mol, further preferably 1000 g/mol, and most preferably 1100 g/mol.

In some embodiments, the organic mixture as described herein has a solubility of ≥5 mg/mL, preferably ≥10 mg/mL, more preferably ≥15 mg/mL, further preferably ≥20 mg/mL, and most preferably ≥25 mg/mL, in any one solvent selected from toluene, xylene, mesitylene, cyclohexylbenzene, methyl benzoate, or a mixture of two or more of these solvents at 25° C.

In some embodiments, the second emitter E2 or the first emitter E1 of the organic mixture comprises at least one cross-linkable group, as disclosed in the Chinese patent application No. 202110370910.9, which is hereby incorporated by reference herein in its entirety.

In some embodiments, the second emitter E2 or the first emitter E1 comprises at least two cross-linkable groups.

In some embodiments, the second emitter E2 or the first emitter E1 comprises at least three cross-linkable groups.

In some embodiments, the host material H of the organic mixture comprises at least one cross-linkable group.

In some embodiments, the host material H comprises at least two cross-linkable groups.

In some embodiments, the host material H comprises at least three cross-linkable groups.

In another aspect, the present disclosure also provides a formulation comprising an organic mixture as described herein, and at least one organic solvent.

In some embodiments, the formulation as described herein is a solution.

In some embodiments, the formulation as described herein is a dispersion.

The formulation in the embodiments of the present disclosure may comprise the organic mixture of 0.01 wt % to 20 wt %, preferably 0.1 wt % to 20 wt %, more preferably 0.2 wt % to 20 wt %, and most preferably 2 wt % to 15 wt %.

In some embodiments, the organic solvent is selected from alcohols, esters, aromatic ketones, aromatic ethers, aliphatic ketones, aliphatic ethers, inorganic ester compounds such as boronic esters or phosphoric esters, or a combination of two or more of them.

In some embodiments, the suitable and preferred organic solvents include, but not limited to: aliphatics, alicyclics, aromatics, amines, thiols, amides, nitriles, esters, ethers, polyethers, alcohols, diols, or polyols.

In some embodiments, the alcohol refers to a suitable class of organic solvent. Preferred alcohols includes alkylcyclohexanols, particularly methylated aliphatic alcohols, naphthols, etc.

Examples of suitable alcohol organic solvents include, but not limited to, 1-dodecanol, phenyltridecanol, benzyl alcohol, ethylene glycol, 2-methoxyethanol, glycerol, propylene glycol, propyleneglycol monoethyl ether, etc.

The organic solvent can be used alone or as a combination of two or more organic solvents.

Further, examples of organic solvents, include (but not limited to): methanol, ethanol, 2-methoxyethanol, dichloromethane, trichloromethane, chlorobenzene, 1,2-dichlorobenzene, tetrahydrofuran, anisole, morpholine, toluene, o-xylene, m-xylene, p-xylene, 1,4-dioxane, acetone, 2-butanone, 1,2-dichloroethane, 3-phenoxytoluene, 1,1,1-trichloroethane, 1,1,2,2-tetrachloroethane, ethyl acetate, butyl acetate, N,N-dimethylformamide, N,N-dimethylacetamide, dimethyl sulfoxide, tetraline, decahydronaphthalene, indene, and/or any combination thereof.

In some embodiments, the organic solvent of the formulation is selected from aromatic, heteroaromatic, ester, aromatic ketone, aromatic ether, aliphatic ketone, aliphatic ether, cycloaliphatic, alicyclic or olefin compounds, borate, phosphorate, or a combination of two or more of them.

Examples of aromatic or heteroaromatic-based solvents of the present disclosure include, but not limited to: 1-tetralone, 3-phenoxytoluene, acetophenone, 1-methoxynaphthalene, diisopropylbenzene, n-phenylpentane, tetraline, cyclohexylbenzene, 1-chloronaphthalene, 1,4-dimethylnaphthalene, 3-isopropylbiphenyl, p-methyl cumene, dipentylbenzene, 1,2-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, 1-methylnaphthalene, 1,2,4-trichlorobenzene, 1,3-dipropoxybenzene, 4,4-difluorodiphenylmethane, diphenyl ether, 1,2-dimethoxy-4-(1-propenyl) benzene, diphenylmethane, 2-phenylpyridine, 3-phenylpyridine, 2-phenoxymethyl ether, 2-phenoxytetrahydrofuran, ethyl-2-naphthyl ether, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene, benzyl ether, etc.

In some embodiments, the suitable and preferred organic solvents are aliphatics, alicyclics, aromatics, amines, thiols, amides, nitriles, esters, ethers, polyethers.

The organic solvent may be a cycloalkane, such as decahydronaphthalene.

In some embodiments, the formulation of the present disclosure comprises at least 50 wt % of an alcohol solvent; preferably at least 80 wt %; particularly preferably at least 90 wt %.

In some embodiments, the particularly suitable organic solvent for the present disclosure is an organic solvent having Hansen solubility parameters in the following ranges:

δ_{d} (dispersion parameter) is in the range of 17.0 MPa^{1/2} to 23.2 MPa^{1/2}, especially in the range of 18.5 MPa^{1/2} to 21.0 MPa^{1/2}.

δₚ (polarity parameter) is in the range of 0.2 MPa^{1/2} to 12.5 MPa^{1/2}, especially in the range of 2.0 MPa^{1/2} to 6.0 MPa^{1/2}.

δₕ (hydrogen bonding parameter) is in the range of 0.9 MPa^{1/2} to 14.2 MPa^{1/2}, especially in the range of 2.0 MPa^{1/2} to 6.0 MPa^{1/2}.

In the formulation as described herein, the boiling point parameter should betaken into account when selecting the organic solvents. As used herein, the boiling points of the organic solvents≥150° C.; preferably ≥180° C.; more preferably ≥200° C.; further preferably ≥250° C.; and most preferably ≥275° C. or ≥300° C. The boiling points in these ranges are beneficial in terms for preventing nozzle clogging of the inkjet printhead. The organic solvent can be evaporated from solution system to form a functional film.

In some embodiments, in the formulation as described herein:
1) the viscosity is in the range of 1 cps to 100 cps at 25° C.; and/or
2) the surface tension is in the range of 19 dyne/cm to 50 dyne/cm at 25° C.

In the formulation as described herein, the surface tension parameter of the organic solvent should be taken into account when selecting the organic solvents. The suitable surface tension parameters of the inks are suitable for the particular substrate and particular printing method. For example, for the ink-jet printing, in some embodiments, the surface tension of the organic solvent at 25° C. is in the range of 19 dyne/cm to 50 dyne/cm, more preferably in the range of 22 dyne/cm to 35 dyne/cm, and most preferably in the range of 25 dyne/cm to 33 dyne/cm.

In some embodiments, the surface tension of the formulation as described herein at 25° C. is in the range of 19 dyne/cm to 50 dyne/cm; more preferably in the range of 22 dyne/cm to 35 dyne/cm; and most preferably in the range of 25 dyne/cm to 33 dyne/cm.

In the formulation as described herein, the viscosity parameters of the ink of the organic solvent should be taken into account when selecting the organic solvents. The viscosity can be adjusted by election different methods, such as by the suitable organic solvent and the concentration of functional materials in the ink. In some embodiments, the viscosity of the organic solvent is less than 100 cps, preferably less than 50 cps, and most preferably from 1.5 cps to 20 cps. The viscosity herein refers to the viscosity during printing at the ambient temperature that is generally at 15° C.-30° C., preferably 18° C.-28° C., more preferably 20° C.-25° C., and most preferably 23° C.-25° C. The resulting formulation will be particularly suitable for ink-jet printing.

In some embodiments, the viscosity of the formulation as described herein at 25° C. is in the range of from about 1 cps to 100 cps; preferably in the range of 1 cps to 50 cps; and most preferably in the range of 1.5 cps to 20 cps.

The ink obtained from the organic solvent satisfying the above-mentioned boiling point parameter, surface tension parameter and viscosity parameter can form a functional film with uniform thickness and composition property.

In yet another aspect, the present disclosure further provides an organic functional film, and the organic functional film is formed by using a formulation as described herein.

In yet another aspect, the present disclosure further provides a method for preparing the organic functional film, as shown in the following steps:
1) prepare a formulation as described herein;
2) the formulation is coated on a substrate by printing or coating to form a film, where the method of printing or coating is selected from the group consisting of ink-jet printing, nozzle printing, typographic printing, screen printing, dip coating, spin coating, blade coating, roller printing, torsional roll printing, planographic printing, flexographic printing, rotary printing, spray coating, brush or pad printing, and slit die coating;
3) the obtained film is heated at 50° C. and above to remove the organic solvent and cure the film.

The thickness of the organic functional film is generally 5 nm-20 μm, preferably 5 nm-10 μm, more preferably 10 nm-5 μm, and most preferably 10 nm-1 μm.

In yet another aspect, the present disclosure further provides the applications of the above-mentioned organic mixture and the organic functional film in optoelectronic devices.

In some embodiments, the optoelectronic device may be selected from an organic light-emitting diode (OLED), an organic photovoltaic cell (OPV), an organic light emitting electrochemical cell (OLEEC), an organic light emitting field effect transistor, or an organic laser.

In yet another aspect, the present disclosure further provides an optoelectronic device comprising an organic mixture, or an organic functional film as described herein.

Preferably, the optoelectronic device is an electroluminescent device, such as an organic light-emitting diode (OLED), an organic light emitting electrochemical cell (OLEEC), an organic light emitting field effect transistor, a perovskite light emitting diode (PeLED), and a quantum dot light emitting diode (QD-LED), where one of the functional layers comprises an organic mixture or an organic functional film as described herein. The functional layer may be selected from a hole-injection layer, a hole-transport layer, an electron-injection layer, an electron-transport layer, an emissive layer, or a cathode capping layer (CPL).

In some embodiments, the optoelectronic device is an organic electroluminescent device comprising a substrate, an anode, an emissive layer, and a cathode in sequence, the emissive layer comprises at least one organic mixture as described herein, or the emissive layer is formed by using a formulation as described herein.

In some embodiments, in the organic electroluminescent device as described herein, each of the second emitter E2 and the first emitter E1 is a small molecule or a polymer, preferably is a small molecule.

In some embodiments, the emissive layer of the organic electroluminescent device does not comprise any resin.

In some embodiments, the organic electroluminescent device emits blue light.

In some embodiments, the organic electroluminescent device is an OLED. Particularly preferably, the organic electroluminescent device is a top-emission OLED.

The substrate should be opaque or transparent. A transparent substrate could be used to produce a transparent light-emitting device (for example: Bulovic et al., Nature, 1996, 380, p29, and Gu et al., Appl. Phys. Lett., 1996, 68, p2606). The substrate can be rigid or flexible, e.g. it can be plastic, metal, semiconductor wafer, or glass. Preferably, the substrate has a smooth surface. Particularly ideal are substrates without surface defects. In some embodiments, the substrate is flexible and can be selected from a polymer film or plastic with a glass transition temperature (Tg)>150° C., preferably >200° C., more preferably >250° C., and most preferably >300° C. Examples of the suitable flexible substrates include poly ethylene terephthalate (PET) and polyethylene glycol (2,6-naphthalene) (PEN).

The anode may be a conductive metal, or a metal oxide, or a conductive polymer. The anode should be able to easily inject holes into a hole-injection layer (HIL), a hole-transport layer (HTL), or an emissive layer. In some embodiments, the absolute value of the difference between the work function of the anode and the HOMO energy level/valence band energy level of the emitter of the emissive layer or the p-type semiconductor materials of the hole-injection layer (HIL)/hole-transport layer (HTL)/electron-blocking layer (EBL)<0.5 eV, preferably <0.3 eV, and most preferably <0.2 eV. Examples of anode materials may include, but not limited to: Al, Cu, Au, Ag, Mg, Fe, Co, Ni, Mn, Pd, Pt, ITO, aluminum-doped zinc oxide (AZO), etc. Other suitable anode materials are known and can be readily selected for use by the general technicians in this field. The anode materials can be deposited using any suitable technique, such as a suitable physical vapor deposition method including RF magnetron sputtering, vacuum thermal evaporation, e-beam, etc. In some embodiments, the anode is patterned. Patterned conductive ITO substrates are commercially available and can be used to produce the devices as described herein.

The cathode may be a conductive metal or a metal oxide. The cathode should be able to easily inject electrons into the electron-injection layer (EIL), the electron-transport layer (ETL), or the directly into the emissive layer. In some embodiments, the absolute value of the difference between the work function of the cathode and the LUMO energy level/conduction band energy level of the emitter of the emissive layer, or the n-type semiconductor materials of the electron-injection layer (EIL)/electron-transport layer (ETL)/hole-blocking layer (HBL)<0.5 eV, preferably <0.3 eV, and most preferably <0.2 eV. In principle, all materials those can be used as cathodes for OLEDs may be applied as cathode materials for the devices as described herein. Examples of cathode materials include, but not limited to: Al, Au, Ag, Ca, Ba, Mg, LiF/Al, MgAg alloy, BaF₂/Al, Cu, Fe, Co, Ni, Mn, Pd, Pt, ITO, etc. The cathode materials can be deposited using any suitable technique, such as the suitable physical vapor deposition method including RF magnetron sputtering, vacuum thermal evaporation, e-beam, etc. In some embodiments, the transmittance of the cathode in the range of 400-680 nm ≥40%, preferably ≥45%, more preferably ≥50%, and most preferably ≥60%. Typically, 10-20 nm of Mg:Ag alloys can be used as transparent cathodes, and the ratio of the Mg:Ag can range from 2:8 to 0.5:9.5.

The OLED may also comprise other functional layers, such as a hole-injection layer (HIL), a hole-transport layer (HTL), an electron-blocking layer (EBL), an electron-injection layer (EIL), an electron-transport layer (ETL), and a hole-blocking layer (HBL). Materials suitable for use in these functional layers are described in details above and in WO2010135519A1, US20090134784A1 and WO2011110277A1. The entire contents of these three documents are hereby incorporated herein for reference.

Further, the organic electroluminescent device further comprises a cathode capping layer (CPL).

The CPL material generally requires a high refractive index (n), such as n≥1.95@460 nm, n≥1.90@520 nm, n≥1.85@620 nm. Examples of the CPL materials include:

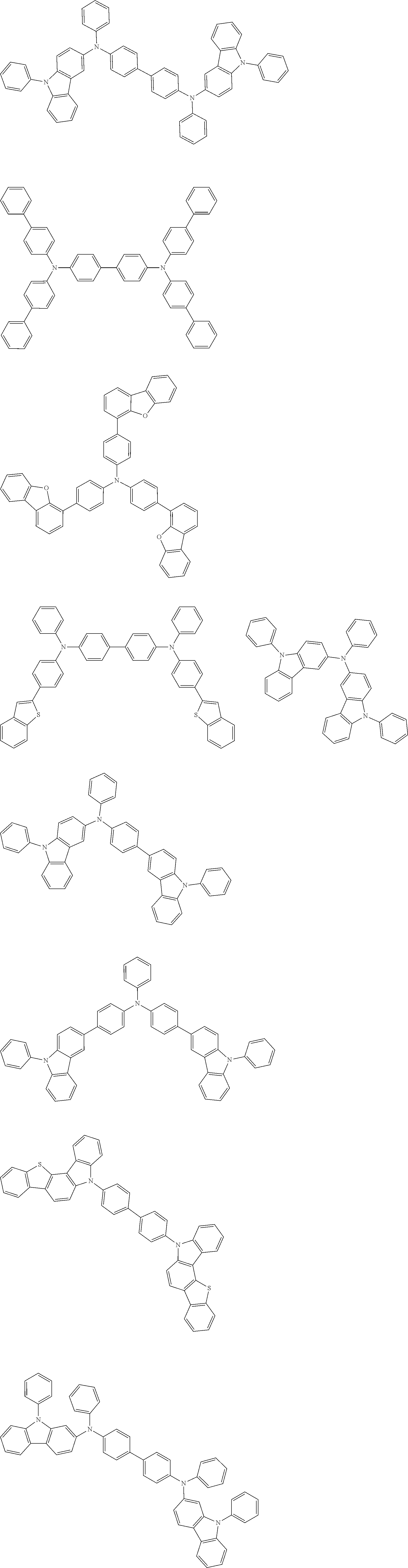

More further examples of the CPL materials can be found in the following patents: KR20140128653A, CN104380842B, US2016308162A1. The above patents are incorporated herein by reference in their entirety.

Preferably, the encapsulation layer of the organic electroluminescent device is thin-film encapsulated (TFE).

In yet another aspect, the present disclosure further provides a display panel comprising at least one pixel, the at least one pixel comprises an organic electroluminescent device as described herein.

### Specific Embodiment

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### 1. Synthesis of Compounds

### Compound E1-1:

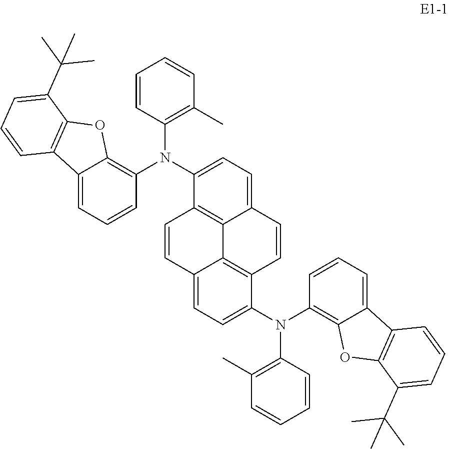 [SMILES: Cc1ccccc1N(c1ccc2ccc3c(N(c4ccccc4C)c4cccc5c4oc4c(C(C)(C)C)cccc45)ccc4ccc1c2c43)c1cccc2c1oc1c(C(C)(C)C)cccc12]

The compound E1-1 was synthesized with reference to the method described in patent WO2013077405A1.

### Compound E1-2:

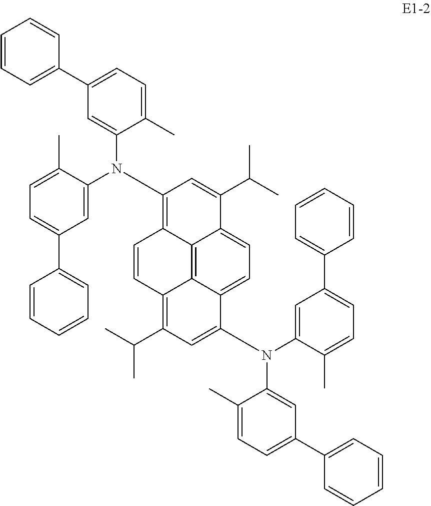 [SMILES: Cc1ccc(-c2ccccc2)cc1N(c1cc(-c2ccccc2)ccc1C)c1cc(C(C)C)c2ccc3c(N(c4cc(-c5ccccc5)ccc4C)c4cc(-c5ccccc5)ccc4C)cc(C(C)C)c4ccc1c2c43]

The compound E1-2 was synthesized with reference to the method described in patent WO2016042781A1.

### Compound E1-3:

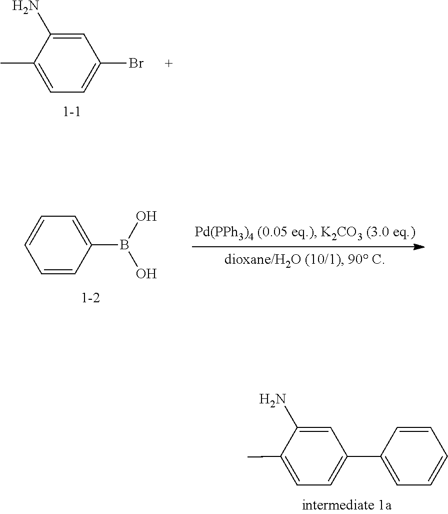

### Synthesis of Intermediate 1a:

Compound 1-1 (20 g, 109.9 mmol), compound 1-2 (13.41 g, 109.9 mmol), potassium carbonate (45.50 g, 329.7 mmol), and tetrakis(triphenylphosphine)palladium (6.35 g, 5.5 mmol) were added to a dry flask, then 400 mL of 1,4-dioxane and 40 mL of water were added to the above mixture under a nitrogen atmosphere. After stirring at 90° C. for 16 h, the reaction solution was cooled to room temperature, then concentrated. After 1,4-dioxane was removed, the result was added to 600 mL of water and extracted with dichloromethane three times, then the result was concentrated and further purified by column chromatography using dichloromethane:n-hexane (3:10) as the eluent. The eluent containing the product was concentrated to obtain intermediate 1a (17.5 g, 88% yield) with a purity of 98%.

The synthetic method of the intermediate 3a was similar to that of the intermediate 1a, with the only difference being the use of the compound 2-2 instead of the compound 1-2.

The raw materials used for synthesizing intermediate 3a and the yield of intermediate 3a are as follows:

| Reactant 1 | Reactant 2 | Product | Yield |
|---|---|---|---|
| 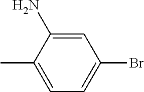 1-1 | 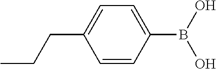 2-2 | 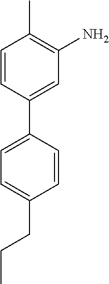 [SMILES: CCCc1ccc(-c2ccc(C)c(N)c2)cc1] | 93% |
| | | intermediate 3a | |

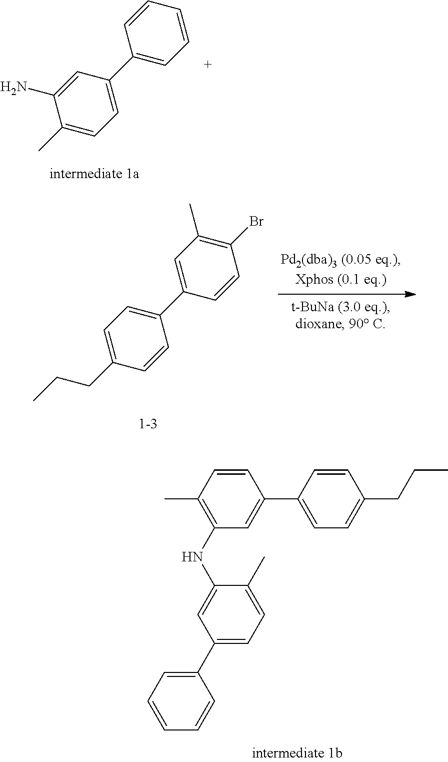 [SMILES: Cc1ccc(-c2ccccc2)cc1N ; CCCc1ccc(-c2ccc(Br)c(C)c2)cc1 ; CCCc1ccc(-c2ccc(C)c(Nc3cc(-c4ccccc4)ccc3C)c2)cc1]

### Synthesis of Intermediate 1b:

Intermediate 1a (7.56 g, 41.3 mmol), compound 1-3 (11.89 g, 41.3 mmol), sodium tert-butoxide (11.89 g, 123.9 mmol), Pd₂(dba)₃ (1.89 g, 2.1 mmol), and XPhos (1.96 g, 4.1 mmol) were added to a dry flask, then 100 mL of 1,4-dioxane was added to the above mixture under a nitrogen atmosphere. After stirring at 100° C. for 16 h, the reaction solution was cooled to room temperature, then concentrated. After 1,4-dioxane was removed, the result was added to 150 mL of water and extracted with dichloromethane three times, then the result was concentrated and further purified by column chromatography using dichloromethane:n-hexane (1:10) as the eluent. The eluent containing the product was concentrated to obtain intermediate 1b (13.24 g, 82% yield) with a purity of 98%.

The synthetic method of the intermediate 2b was similar to that of the intermediate 1b, with the only difference being the use of the compound 2-1 instead of the intermediate 1a.

The synthetic method of the intermediate 3b was similar to that of the intermediate 1b, with the only difference being the use of the intermediate 3a instead of the intermediate 1a.

The raw materials used for synthesizing intermediate 2b and intermediate 3b, as well as the yields of intermediate 2b and intermediate 3b, are as follows:

| Reactant 1 | Reactant 2 | Product | Yield |
|---|---|---|---|
| 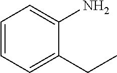 2-1 | 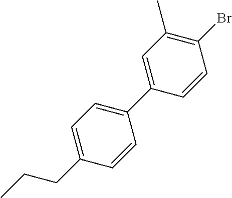 [SMILES: CCCc1ccc(-c2ccc(Br)c(C)c2)cc1] 1-3 | 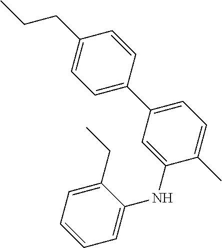 [SMILES: CCCc1ccc(-c2ccc(C)c(Nc3ccccc3CC)c2)cc1] | 76% |
| | | intermediate 2b | |
| 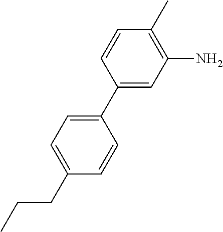 [SMILES: CCCc1ccc(-c2ccc(C)c(N)c2)cc1] Intermedlate 3a | 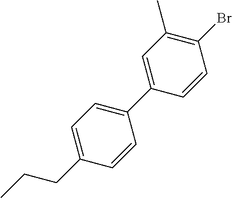 [SMILES: CCCc1ccc(-c2ccc(Br)c(C)c2)cc1] 1-3 | 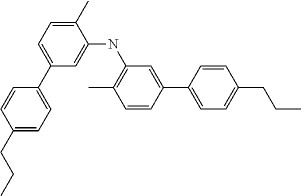 [SMILES: CCCc1ccc(-c2ccc(C)c(Nc3cc(-c4ccc(CCC)cc4)ccc3C)c2)cc1] intermediate 3b | 85% |

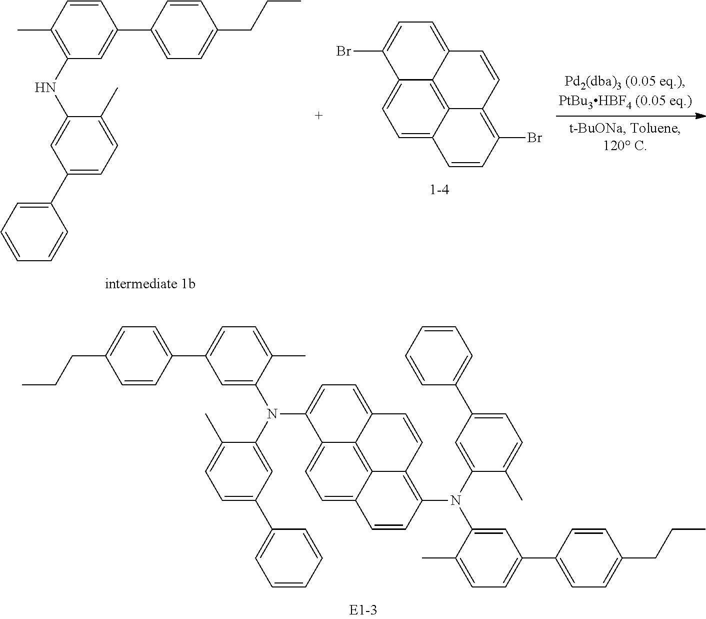 [SMILES: CCCc1ccc(-c2ccc(C)c(Nc3cc(-c4ccccc4)ccc3C)c2)cc1 ; Brc1ccc2ccc3c(Br)ccc4ccc1c2c43 ; CCCc1ccc(-c2ccc(C)c(N(c3cc(-c4ccccc4)ccc3C)c3ccc4ccc5c(N(c6cc(-c7ccccc7)ccc6C)c6cc(-c7ccc(CCC)cc7)ccc6C)ccc6ccc3c4c65)c2)cc1]

### Synthesis of Compound E1-3:

Compound 1-4 (3.00 g, 8.3 mmol), intermediate 1b (9.74 g, 24.9 mmol), sodium tert-butoxide (3.19 g, 33.2 mmol), Pd₂(dba)₃ (380 mg, 0.4 mmol), and PtBu₃·HBF₄ (230 mg, 0.8 mmol) were added to a dry flask, then 60 mL of toluene was added to the above mixture under a nitrogen atmosphere. After stirring at 120° C. for 16 h, the reaction solution was cooled to room temperature. After concentration, the result was added to 100 mL of water and extracted with dichloromethane three times, then the result was concentrated and further purified by column chromatography using dichloromethane:n-hexane (1:8) as the eluent. The eluent containing the product was concentrated to obtain compound E1-3 (6.35 g, 78% yield) with a purity of 99%.

### Compound E1-4~Compound E1-6:

The synthetic method of the compound E1-4 was similar to that of the compound E1-3, with the only difference being the use of the intermediate 2b instead of the intermediate 1b, and the compound 2-4 instead of the compound 1-4.

The synthetic method of the compound E1-5 was similar to that of the compound E1-3, with the only difference being the use of the intermediate 3b instead of the intermediate 1b, and the compound 2-4 instead of the compound 1-4.

The synthetic method of the compound E1-6 was similar to that of the compound E1-3, with the only difference being the use of the intermediate 2b instead of the intermediate 1b.

Yields and raw materials for compound E1-4 to compound E1-6 are as follows:

| Reactant 1 | Reactant 2 | Product | Yield |
|---|---|---|---|
| 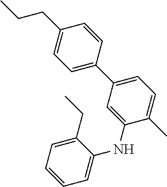 [SMILES: CCCc1ccc(-c2ccc(C)c(Nc3ccccc3CC)c2)cc1] intermediate 2b | 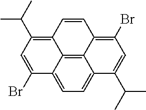 [SMILES: CC(C)c1cc(Br)c2ccc3c(C(C)C)cc(Br)c4ccc1c2c43] compound 2-4 | 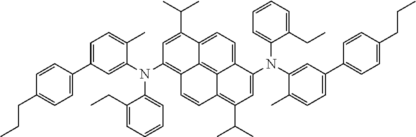 [SMILES: CCCc1ccc(-c2ccc(C)c(N(c3ccccc3CC)c3cc(C(C)C)c4ccc5c(N(c6cc(-c7ccc(CCC)cc7)ccc6C)c6ccccc6CC)cc(C(C)C)c6ccc3c4c65)c2)cc1] E1-4 | 85% |
| 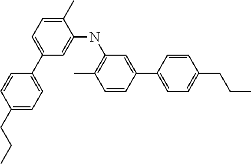 [SMILES: CCCc1ccc(-c2ccc(C)c(Nc3cc(-c4ccc(CCC)cc4)ccc3C)c2)cc1] intermediate 3b | 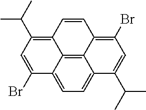 [SMILES: CC(C)c1cc(Br)c2ccc3c(C(C)C)cc(Br)c4ccc1c2c43] compound 2-4 | 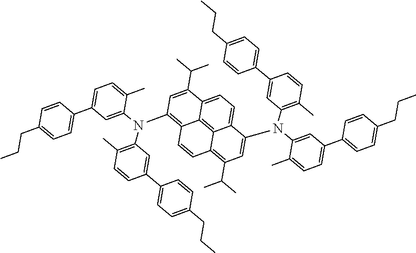 [SMILES: CCCc1ccc(-c2ccc(C)c(N(c3cc(-c4ccc(CCC)cc4)ccc3C)c3cc(C(C)C)c4ccc5c(N(c6cc(-c7ccc(CCC)cc7)ccc6C)c6cc(-c7ccc(CCC)cc7)ccc6C)cc(C(C)C)c6ccc3c4c65)c2)cc1] | 54% |
| | | E1-5 | |
| 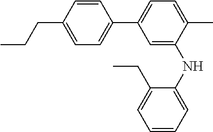 [SMILES: CCCc1ccc(-c2ccc(C)c(Nc3ccccc3CC)c2)cc1] | 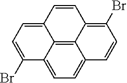 [SMILES: Brc1ccc2ccc3c(Br)ccc4ccc1c2c43] compound 1-4 | 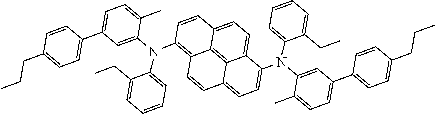 [SMILES: CCCc1ccc(-c2ccc(C)c(N(c3ccccc3CC)c3ccc4ccc5c(N(c6cc(-c7ccc(CCC)cc7)ccc6C)c6ccccc6CC)ccc6ccc3c4c65)c2)cc1] | 89% |
| intermediate 2b | | E1-6 | |

### Compound E2-1:

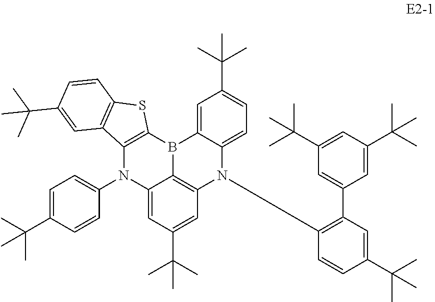 [SMILES: CC(C)(C)c1ccc(N2c3cc(C(C)(C)C)cc4c3B(c3cc(C(C)(C)C)ccc3N4c3ccc(C(C)(C)C)cc3-c3cc(C(C)(C)C)cc(C(C)(C)C)c3)c3sc4ccc(C(C)(C)C)cc4c32)cc1]

The compound E2-1 was synthesized with reference to the method described in patent CN117567491A.

### Compound E2-2:

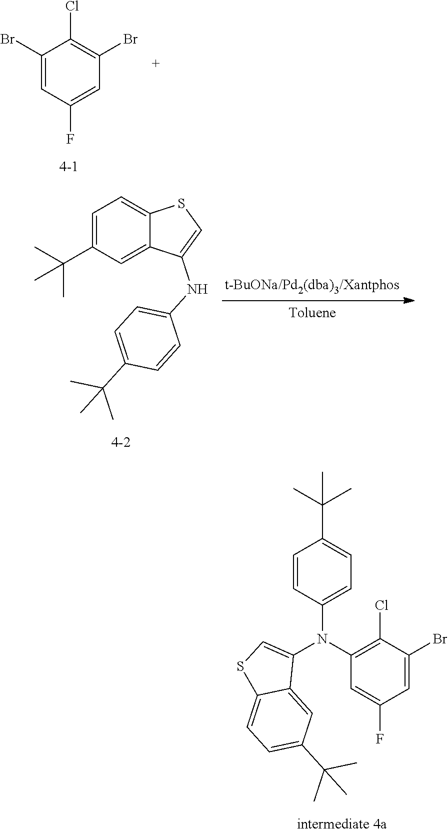 [SMILES: Fc1cc(Br)c(Cl)c(Br)c1 ; CC(C)(C)c1ccc(Nc2csc3ccc(C(C)(C)C)cc23)cc1 ; CC(C)(C)c1ccc(N(c2cc(F)cc(Br)c2Cl)c2csc3ccc(C(C)(C)C)cc23)cc1]

### Synthesis of Intermediate 4a:

Compound 4-1 (28.8 g, 100.0 mmol), compound 4-2 (37.1 g, 110.0 mmol), toluene (300 mL), sodium tert-butoxide (14.4 g, 150.0 mmol), Pd₂(dba)₃ (916 mg, 1.0 mmol), and Xantphos (1.1 g, 2.0 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=15:1, v:v) to obtain intermediate 4a. The resulting sample was dried to yield about 33.5 g (yield: 61.5%) of intermediate 4a.

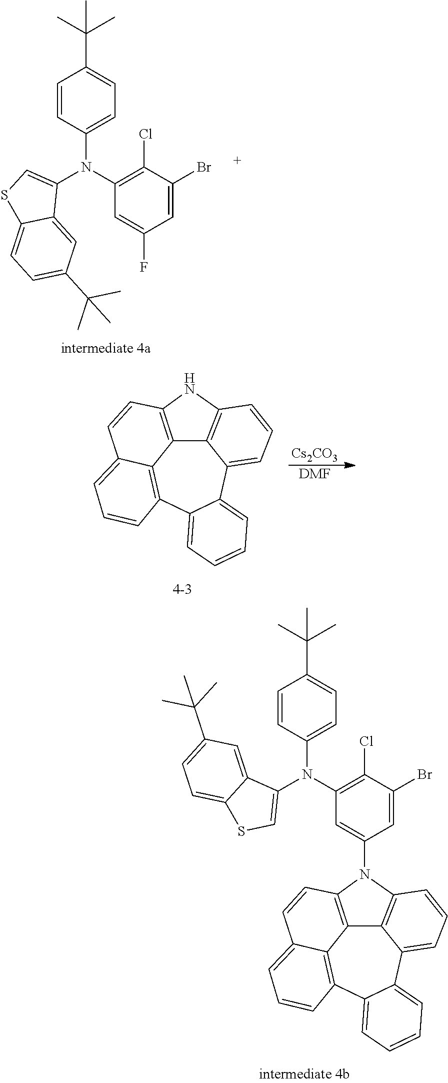

### Synthesis of Intermediate 4b:

Intermediate 4a (30.0 g, 55.0 mmol), compound 4-3 (17.6 g, 60.5 mmol), cesium carbonate (26.5 g, 82.5 mmol), and 300 mL of DMF were added in turn to a 500 mL three-necked flask, the reaction was heated to reflux. Monitored by TLC, the reaction was halted when the raw material had been substantially consumed, then the result was washed with 300 mL of methanol and 100 mL of water at room temperature for 2 h to obtain intermediate 4b. The resulting sample was dried to yield about 29.2 g (yield: about 65.1%) of intermediate 4b.

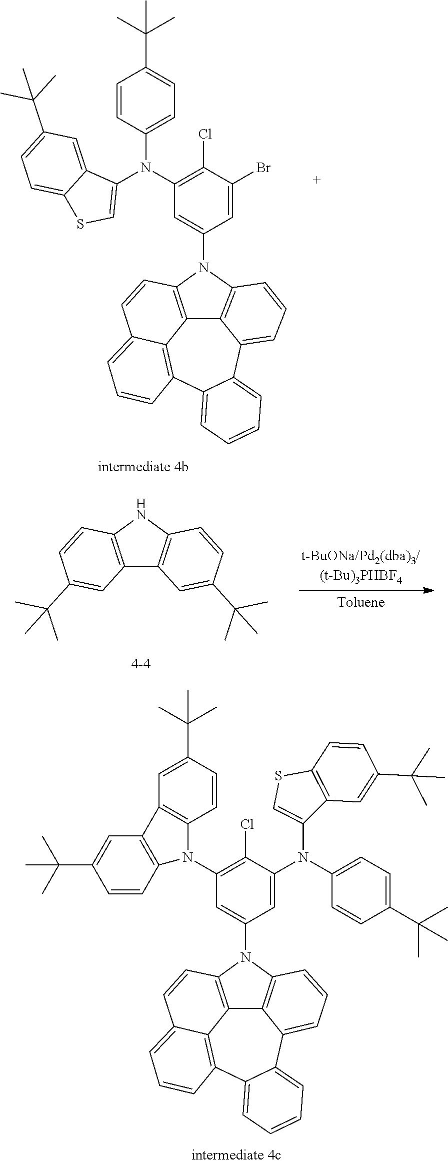 [SMILES: CC(C)(C)c1ccc(N(c2cc(-n3c4cccc5c4c4c6c(cccc6ccc43)-c3ccccc3-5)cc(Br)c2Cl)c2csc3ccc(C(C)(C)C)cc23)cc1 ; CC(C)(C)c1ccc2[nH]c3ccc(C(C)(C)C)cc3c2c1 ; CC(C)(C)c1ccc(N(c2cc(-n3c4cccc5c4c4c6c(cccc6ccc43)-c3ccccc3-5)cc(-n3c4ccc(C(C)(C)C)cc4c4cc(C(C)(C)C)ccc43)c2Cl)c2csc3ccc(C(C)(C)C)cc23)cc1]

### Synthesis of Intermediate 4c:

Intermediate 4b (25.0 g, 30.6 mmol), compound 4-4 (9.4 g, 33.6 mmol), toluene (200 mL), sodium tert-butoxide (4.4 g, 45.9 mmol), Pd₂(dba)₃ (280 mg, 0.3 mmol), and TTBPH BF₄ (174.0 mg, 0.6 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=12:1, v:v) to obtain intermediate 4c. The resulting sample was dried to yield about 21.7 g (yield: about 69.8%) of intermediate 4c.

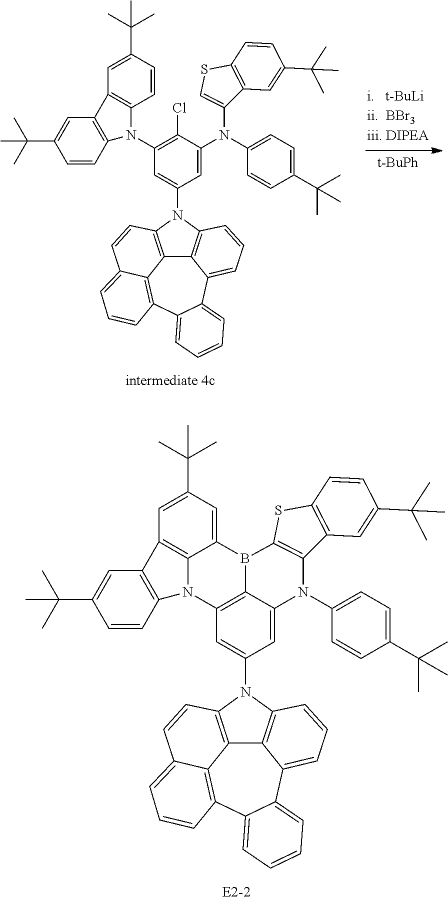

### Synthesis of Compound E2-2:

Intermediate 4c (20.0 g, 19.7 mmol) and tert-butylbenzene (200 mL) were added to a 500 mL three-necked flask under a nitrogen atmosphere, then 1.6 M tert-butyllithium (25.8 mL, 43.34 mmol) was added dropwise to the above mixture at 0° C. After heating up to 60° C., the resulting solution was reacted for 1 h, boron tribromide (5.6 mL, 59.1 mmol) was added dropwise to the above mixture at 0° C. and the resulting mixture was then reacted at room temperature for 2 h. After the dropwise addition of N,N-diisopropylethylamine (25.8 mL, 147.7 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-2. The resulting sample was further dried to yield about 2.9 g (yield: about 14.9%) of compound E2-2.

### Compound E2-3:

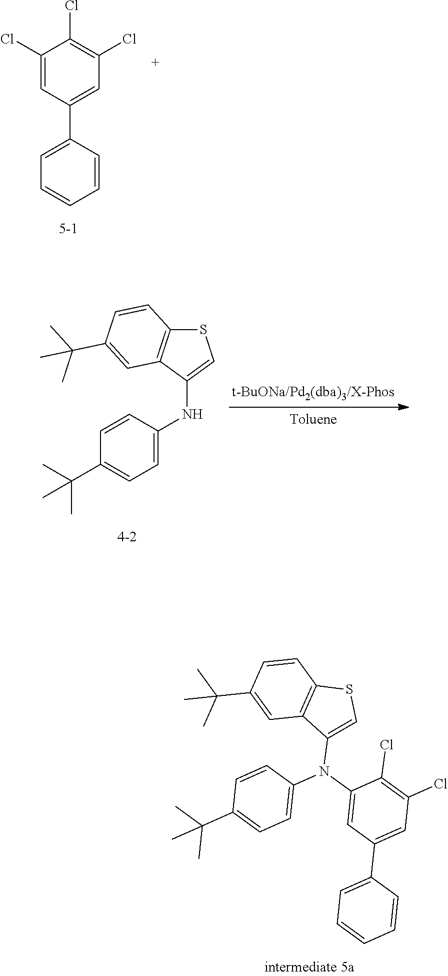 [SMILES: Clc1cc(-c2ccccc2)cc(Cl)c1Cl ; CC(C)(C)c1ccc(Nc2csc3ccc(C(C)(C)C)cc23)cc1 ; CC(C)(C)c1ccc(N(c2cc(-c3ccccc3)cc(Cl)c2Cl)c2csc3ccc(C(C)(C)C)cc23)cc1]

### Synthesis of Intermediate 5a:

Compound 5-1 (25.7 g, 100.0 mmol), compound 4-2 (37.1 g, 110.0 mmol), toluene (300 mL), sodium tert-butoxide (14.4 g, 150.0 mmol), Pd₂(dba)₃ (916 mg, 1.0 mmol), and X-Phos (953 mg, 2.0 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=12:1, v:v) to obtain intermediate 5a. The resulting sample was dried to yield about 32.5 g (yield: about 58.3%) of intermediate 5a.

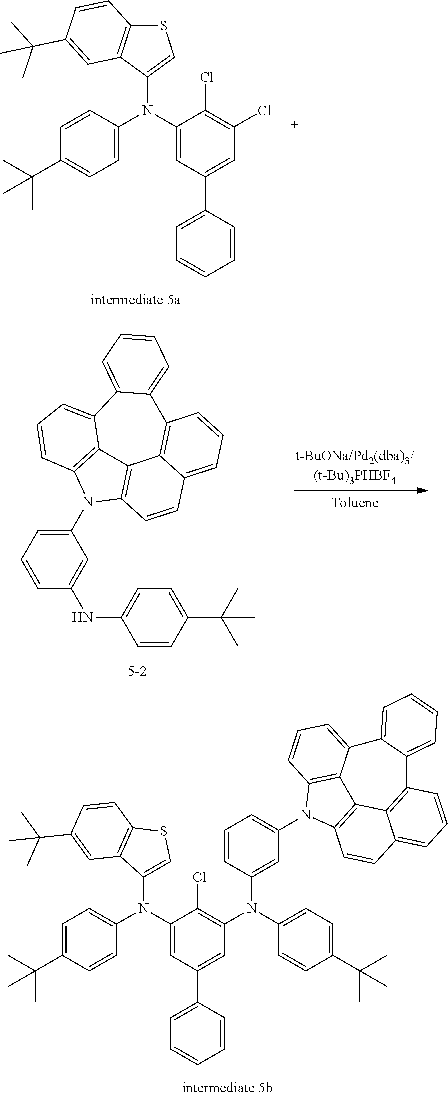 [SMILES: CC(C)(C)c1ccc(N(c2cc(-c3ccccc3)cc(Cl)c2Cl)c2csc3ccc(C(C)(C)C)cc23)cc1 ; CC(C)(C)c1ccc(Nc2cccc(-n3c4cccc5c4c4c6c(cccc6ccc43)-c3ccccc3-5)c2)cc1 ; CC(C)(C)c1ccc(N(c2cccc(-n3c4cccc5c4c4c6c(cccc6ccc43)-c3ccccc3-5)c2)c2cc(-c3ccccc3)cc(N(c3ccc(C(C)(C)C)cc3)c3csc4ccc(C(C)(C)C)cc34)c2Cl)cc1]

### Synthesis of Intermediate 5b:

Intermediate 5a (17.1 g, 30.6 mmol), compound 5-2 (17.3 g, 33.6 mmol), toluene (200 mL), sodium tert-butoxide (4.4 g, 45.9 mmol), Pd₂(dba)₃ (280 mg, 0.3 mmol), and TTBPH BF₄ (174.0 mg, 0.6 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=8:1, v:v) to obtain intermediate 5b. The resulting sample was dried to yield about 19.6 g (yield: about 61.9%) of intermediate 5b.

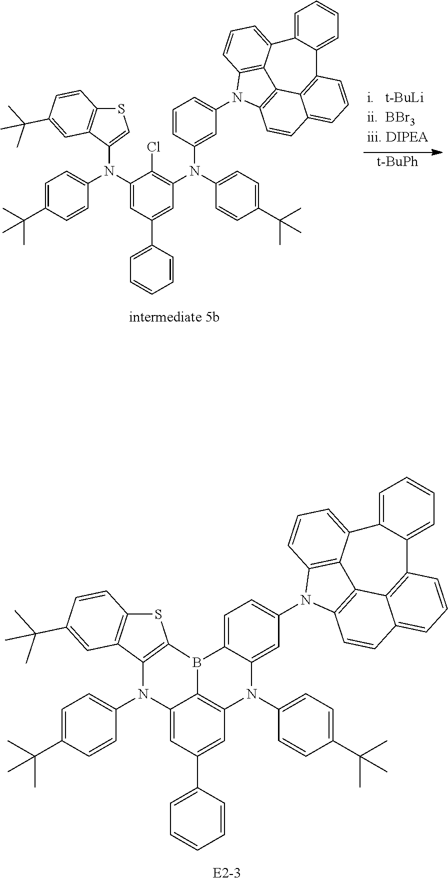

### Synthesis of Compound E2-3:

Intermediate 5b (20.4 g, 19.7 mmol) and tert-butylbenzene (200 mL) were added to a 500 mL three-necked flask under a nitrogen atmosphere, then 1.6 M tert-butyllithium (25.8 mL, 43.34 mmol) was added dropwise to the above mixture at 0° C. After heating up to 60° C., the resulting solution was reacted for 1 h, boron tribromide (5.6 mL, 59.1 mmol) was added dropwise to the above mixture at 0° C. and the resulting mixture was then reacted at room temperature for 2 h. After the dropwise addition of N,N-diisopropylethylamine (25.8 mL, 147.7 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-3. The resulting sample was further dried to yield about 3.5 g (yield: about 17.5%) of compound E2-3.

### Compound E2-4:

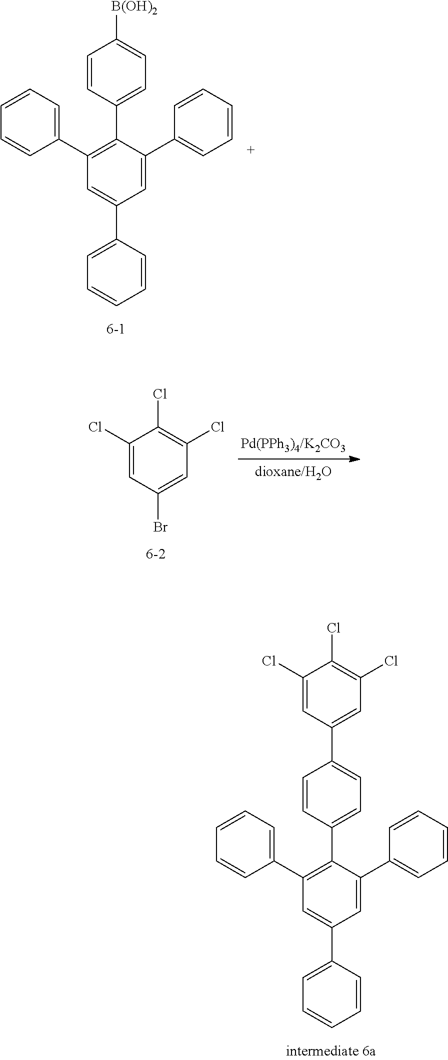 [SMILES: OB(O)c1ccc(-c2c(-c3ccccc3)cc(-c3ccccc3)cc2-c2ccccc2)cc1 ; Clc1cc(Br)cc(Cl)c1Cl ; Clc1cc(-c2ccc(-c3c(-c4ccccc4)cc(-c4ccccc4)cc3-c3ccccc3)cc2)cc(Cl)c1Cl]

### Synthesis of Intermediate 6a:

Compound 6-2 (7.9 g, 30.6 mmol), compound 6-1 (14.3 g, 33.6 mmol), 1,4-dioxane (150 mL), water (30 mL), potassium carbonate (8.4 g, 61.2 mmol), and Pd(PPh₃)₄ (346 mg, 0.3 mmol) were added in turn to a 250 mL three-necked flask under a nitrogen atmosphere, then heated to 100° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane) to obtain intermediate 6a. The resulting sample was dried to yield about 15.3 g (yield: about 89.8%) of intermediate 6a.

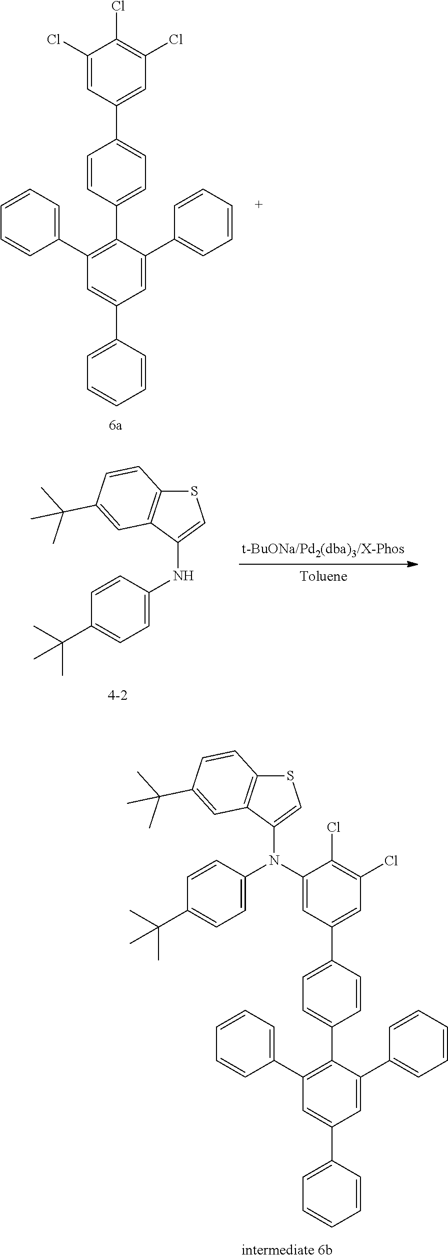 [SMILES: Clc1cc(-c2ccc(-c3c(-c4ccccc4)cc(-c4ccccc4)cc3-c3ccccc3)cc2)cc(Cl)c1Cl ; CC(C)(C)c1ccc(Nc2csc3ccc(C(C)(C)C)cc23)cc1 ; CC(C)(C)c1ccc(N(c2cc(-c3ccc(-c4c(-c5ccccc5)cc(-c5ccccc5)cc4-c4ccccc4)cc3)cc(Cl)c2Cl)c2csc3ccc(C(C)(C)C)cc23)cc1]

### Synthesis of Intermediate 6b:

Intermediate 6a (14.2 g, 25.4 mmol), compound 4-2 (9.4 g, 27.9 mmol), toluene (150 mL), sodium tert-butoxide (3.7 g, 38.1 mmol), Pd₂(dba)₃ (183 mg, 0.2 mmol), and X-Phos (190.6 mg, 0.4 mmol) were added in turn to a 250 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=10:1, v:v) to obtain intermediate 6b. The resulting sample was dried to yield about 14.6 g (yield: about 66.6%) of intermediate 6b.

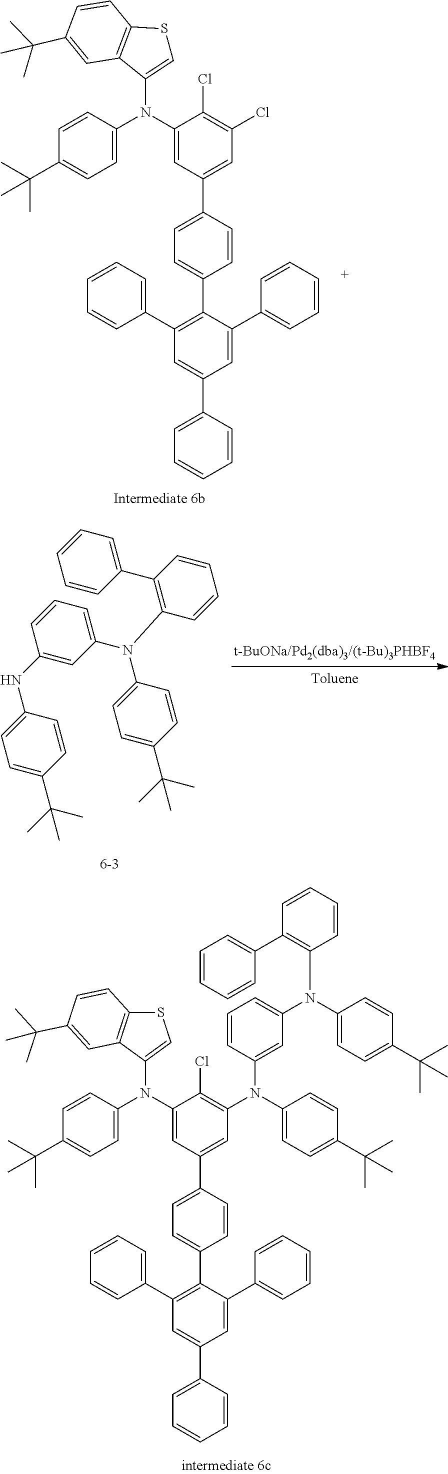 [SMILES: CC(C)(C)c1ccc(N(c2cc(-c3ccc(-c4c(-c5ccccc5)cc(-c5ccccc5)cc4-c4ccccc4)cc3)cc(Cl)c2Cl)c2csc3ccc(C(C)(C)C)cc23)cc1 ; CC(C)(C)c1ccc(Nc2cccc(N(c3ccc(C(C)(C)C)cc3)c3ccccc3-c3ccccc3)c2)cc1 ; CC(C)(C)c1ccc(N(c2cccc(N(c3ccc(C(C)(C)C)cc3)c3cc(-c4ccc(-c5c(-c6ccccc6)cc(-c6ccccc6)cc5-c5ccccc5)cc4)cc(N(c4ccc(C(C)(C)C)cc4)c4csc5ccc(C(C)(C)C)cc45)c3Cl)c2)c2ccccc2-c2ccccc2)cc1]

### Synthesis of Intermediate 6c:

Intermediate 6b (14.0 g, 16.2 mmol), compound 6-3 (9.4 g, 17.8 mmol), toluene (150 mL), sodium tert-butoxide (2.3 g, 24.3 mmol), Pd₂(dba)₃ (183 mg, 0.2 mmol), and TTBPH BF₄ (116.0 mg, 0.4 mmol) were added in turn to a 250 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=7:1, v:v) to obtain intermediate 6c. The resulting sample was dried to yield about 16.0 g (yield: about 73.3%) of intermediate 6c.

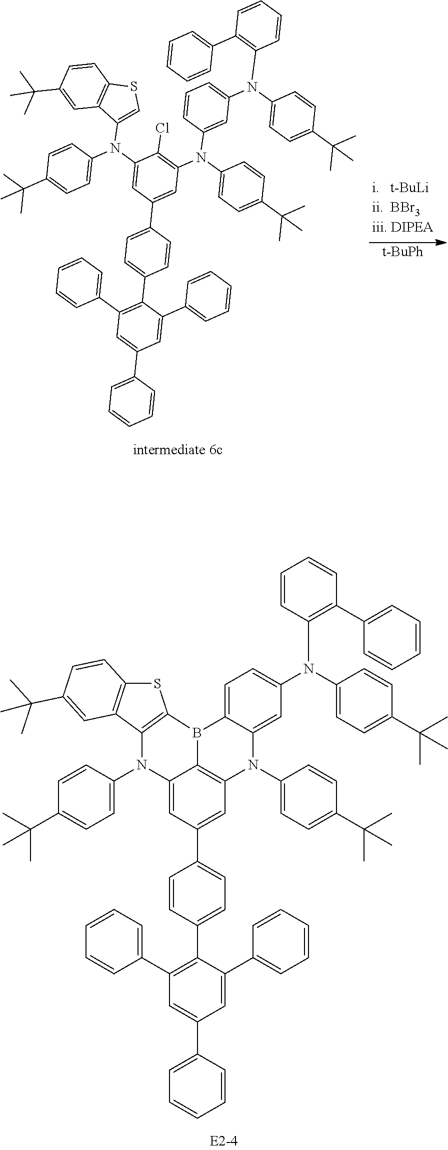

### Synthesis of Compound E2-4:

Intermediate 6c (15.1 g, 11.2 mmol) and tert-butylbenzene (200 mL) were added to a 500 mL three-necked flask under a nitrogen atmosphere, then 1.6 M tert-butyllithium (14.7 mL, 24.7 mmol) was added dropwise to the above mixture at 0° C. After heating up to 60° C., the resulting solution was reacted for 1 h, boron tribromide (3.2 mL, 33.6 mmol) was added dropwise to the above mixture at 0° C. and the resulting mixture was then reacted at room temperature for 2 h. After the dropwise addition of N,N-diisopropylethylamine (14.7 mL, 84.1 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-4. The resulting sample was further dried to yield about 3.6 g (yield: about 24.2%) of compound E2-4.

### Compound E2-5:

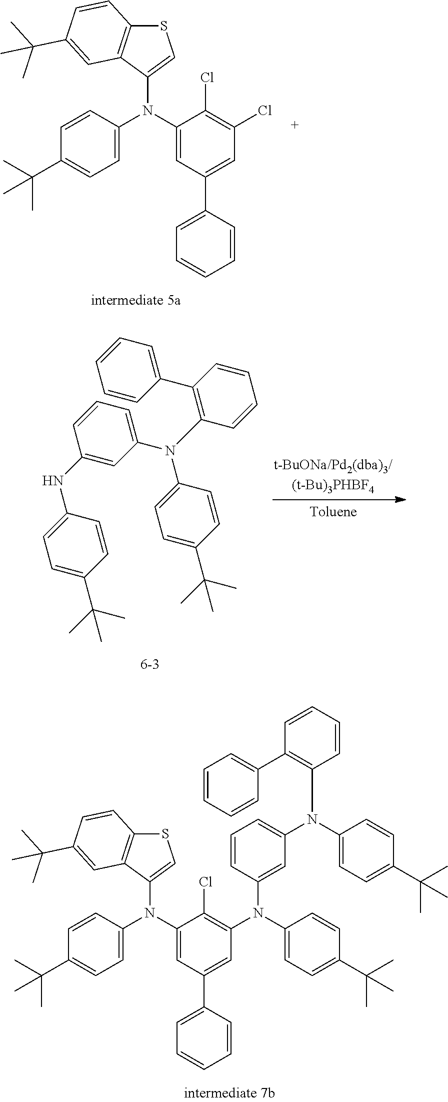 [SMILES: CC(C)(C)c1ccc(N(c2cc(-c3ccccc3)cc(Cl)c2Cl)c2csc3ccc(C(C)(C)C)cc23)cc1 ; CC(C)(C)c1ccc(Nc2cccc(N(c3ccc(C(C)(C)C)cc3)c3ccccc3-c3ccccc3)c2)cc1 ; CC(C)(C)c1ccc(N(c2cccc(N(c3ccc(C(C)(C)C)cc3)c3cc(-c4ccccc4)cc(N(c4ccc(C(C)(C)C)cc4)c4csc5ccc(C(C)(C)C)cc45)c3Cl)c2)c2ccccc2-c2ccccc2)cc1]

### Synthesis of Intermediate 7b:

Intermediate 5a (17.1 g, 30.6 mmol), compound 6-3 (17.6 g, 33.6 mmol), toluene (200 mL), sodium tert-butoxide (4.4 g, 45.9 mmol), Pd₂(dba)₃ (280 mg, 0.3 mmol), and TTBPH BF₄ (174.0 mg, 0.6 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=8:1, v:v) to obtain intermediate 7b. The resulting sample was dried to yield about 23.2 g (yield: about 72.6%) of intermediate 7b.

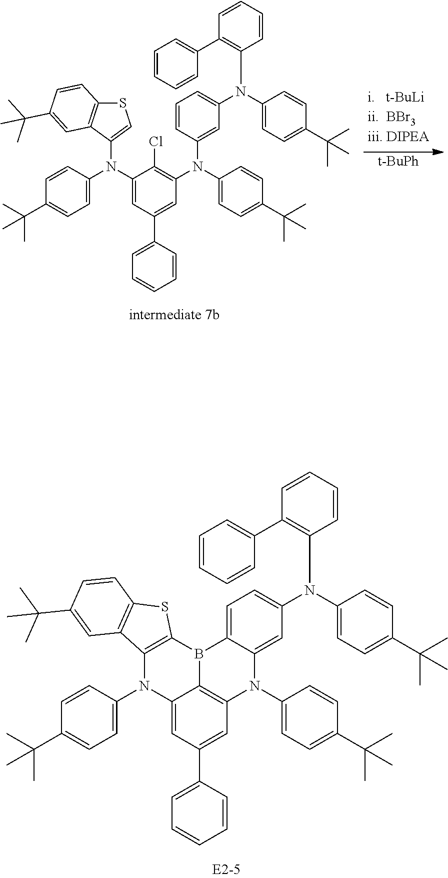

### Synthesis of Compound E2-5:

Intermediate 7b (20.0 g, 19.7 mmol) and tert-butylbenzene (200 mL) were added to a 500 mL three-necked flask under a nitrogen atmosphere, then 1.6 M tert-butyllithium (25.8 mL, 43.34 mmol) was added dropwise to the above mixture at 0° C. After heating up to 60° C., the resulting solution was reacted for 1 h, boron tribromide (5.6 mL, 59.1 mmol) was added dropwise to the above mixture at 0° C. and the resulting mixture was then reacted at room temperature for 2 h. After the dropwise addition of N,N-diisopropylethylamine (25.8 mL, 147.7 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-5. The resulting sample was further dried to yield about 4.3 g (yield: about 21.1%) of compound E2-5.

### Compound E2-6:

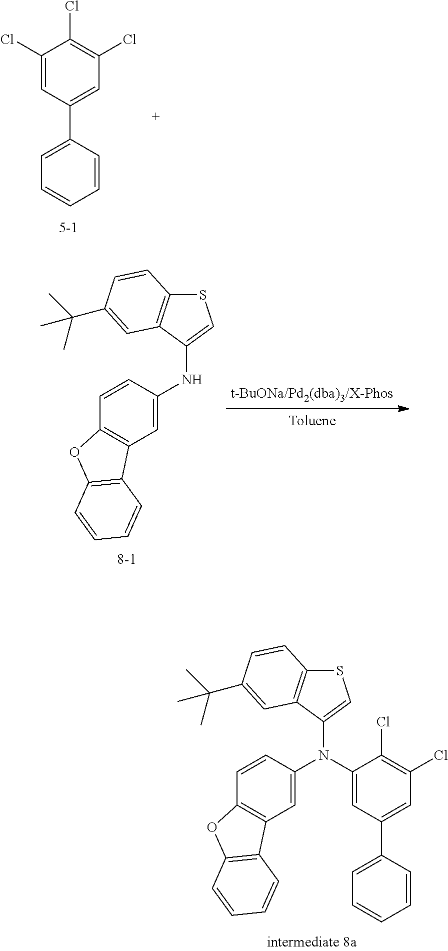 [SMILES: Clc1cc(-c2ccccc2)cc(Cl)c1Cl ; CC(C)(C)c1ccc2scc(Nc3ccc4oc5ccccc5c4c3)c2c1 ; CC(C)(C)c1ccc2scc(N(c3ccc4oc5ccccc5c4c3)c3cc(-c4ccccc4)cc(Cl)c3Cl)c2c1]

### Synthesis of Intermediate 8a:

Compound 5-1 (25.6 g, 100.0 mmol), compound 8-1 (40.8 g, 110.0 mmol), toluene (300 mL), sodium tert-butoxide (14.4 g, 150.0 mmol), Pd₂(dba)₃ (916 mg, 1.0 mmol), and X-Phos (953 mg, 2.0 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=10:1, v:v) to obtain intermediate 8a. The resulting sample was dried to yield about 40.1 g (yield: about 67.7%) of intermediate 8a.

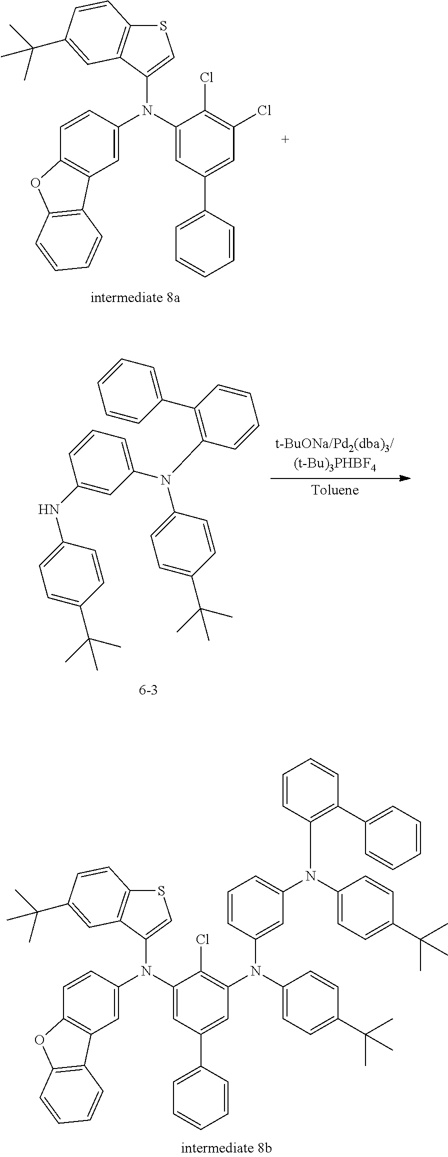 [SMILES: CC(C)(C)c1ccc2scc(N(c3ccc4oc5ccccc5c4c3)c3cc(-c4ccccc4)cc(Cl)c3Cl)c2c1 ; CC(C)(C)c1ccc(Nc2cccc(N(c3ccc(C(C)(C)C)cc3)c3ccccc3-c3ccccc3)c2)cc1 ; CC(C)(C)c1ccc(N(c2cccc(N(c3ccc(C(C)(C)C)cc3)c3cc(-c4ccccc4)cc(N(c4ccc5oc6ccccc6c5c4)c4csc5ccc(C(C)(C)C)cc45)c3Cl)c2)c2ccccc2-c2ccccc2)cc1]

### Synthesis of Intermediate 8b:

Intermediate 8a (18.14 g, 30.6 mmol), compound 6-3 (17.6 g, 33.6 mmol), toluene (200 mL), sodium tert-butoxide (4.4 g, 45.9 mmol), Pd₂(dba)₃ (280 mg, 0.3 mmol), and TTBPH BF₄ (174.0 mg, 0.6 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=6:1, v:v) to obtain intermediate 8b. The resulting sample was dried to yield about 24.5 g (yield: about 73.9%) of intermediate 8b.

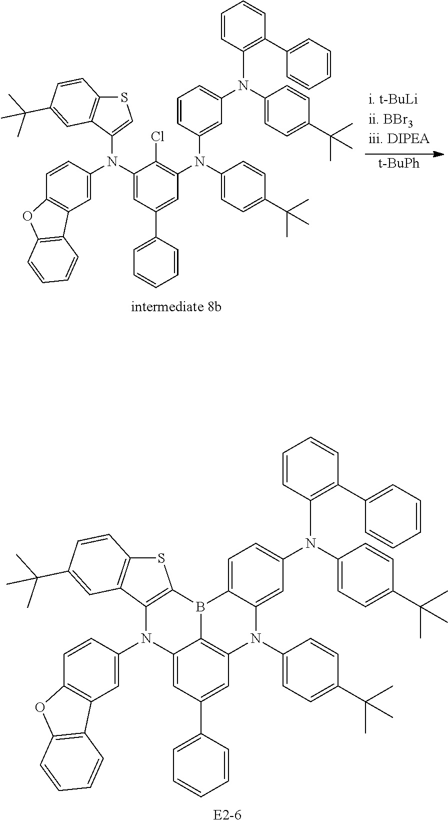

### Synthesis of Compound E2-6:

Intermediate 8b (21.3 g, 19.7 mmol) and tert-butylbenzene (200 mL) were added to a 500 mL three-necked flask under a nitrogen atmosphere, then 1.6 M tert-butyllithium (25.8 mL, 43.34 mmol) was added dropwise to the above mixture at 0° C. After heating up to 60° C., the resulting solution was reacted for 1 h, boron tribromide (5.6 mL, 59.1 mmol) was added dropwise to the above mixture at 0° C. and the resulting mixture was then reacted at room temperature for 2 h. After the dropwise addition of N,N-diisopropylethylamine (25.8 mL, 147.7 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-6. The resulting sample was further dried to yield about 2.4 g (yield: about 11.7%) of compound E2-6.

### Compound E2-7:

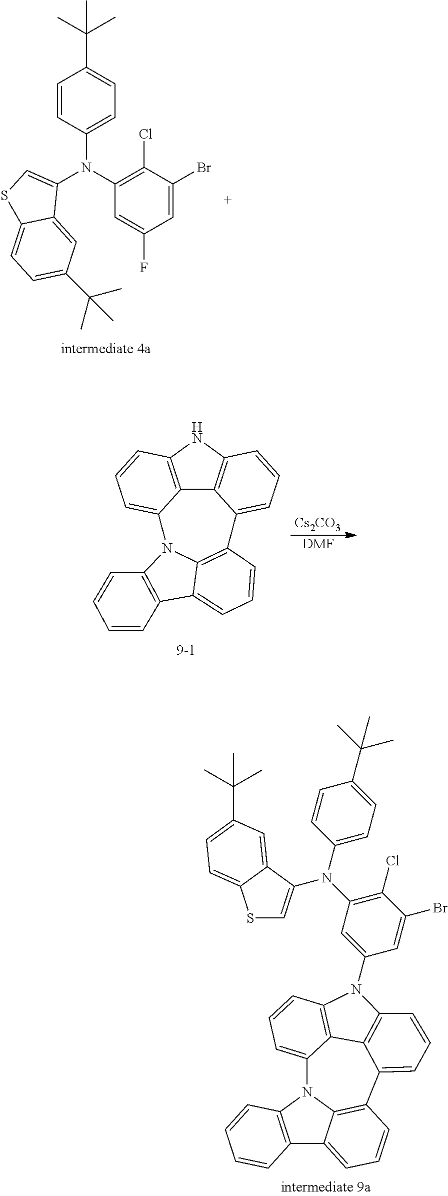

Synthesis of intermediate 9a:

Intermediate 4a (30.0 g, 55.0 mmol), compound 9-1 (19.9 g, 60.5 mmol), cesium carbonate (26.5 g, 82.5 mmol), and 300 mL of DMF were added in turn to a 500 mL three-necked flask, the reaction was heated to reflux. Monitored by TLC, the reaction was halted when the raw material had been substantially consumed, then the result was washed with 300 mL of methanol and 100 mL of water at room temperature for 2 h to obtain intermediate 9a. The resulting sample was dried to yield about 30.3 g (yield: about 64.4%) of intermediate 9a.

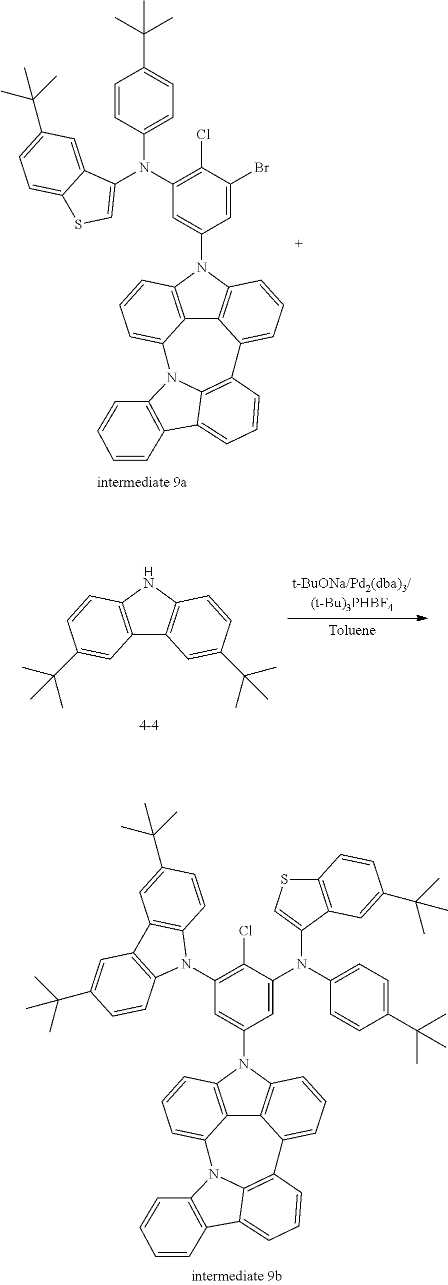 [SMILES: CC(C)(C)c1ccc(N(c2cc(-n3c4cccc5c6cccc7c8ccccc8n(c8cccc3c8c54)c67)cc(Br)c2Cl)c2csc3ccc(C(C)(C)C)cc23)cc1 ; CC(C)(C)c1ccc2[nH]c3ccc(C(C)(C)C)cc3c2c1 ; CC(C)(C)c1ccc(N(c2cc(-n3c4cccc5c6cccc7c8ccccc8n(c8cccc3c8c54)c67)cc(-n3c4ccc(C(C)(C)C)cc4c4cc(C(C)(C)C)ccc43)c2Cl)c2csc3ccc(C(C)(C)C)cc23)cc1]

### Synthesis of Intermediate 9b:

Intermediate 9a (26.1 g, 30.6 mmol), compound 4-4 (9.4 g, 33.6 mmol), toluene (200 mL), sodium tert-butoxide (4.4 g, 45.9 mmol), Pd₂(dba)₃ (280 mg, 0.3 mmol), and TTBPH BF₄ (174.0 mg, 0.6 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=12:1, v:v) to obtain intermediate 9b. The resulting sample was dried to yield about 21.3 g (yield: about 66.1%) of intermediate 9b.

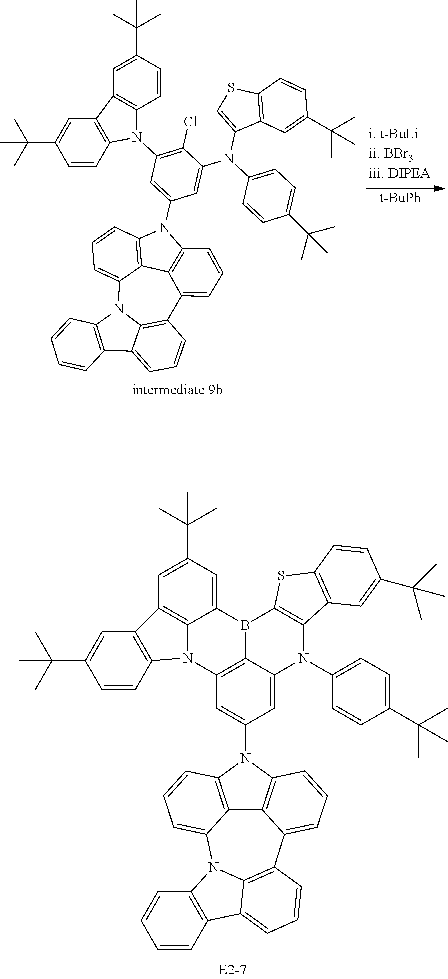

### Synthesis of Compound E2-7:

Intermediate 9b (20.7 g, 19.7 mmol) and tert-butylbenzene (200 mL) were added to a 500 mL three-necked flask under a nitrogen atmosphere, then 1.6 M tert-butyllithium (25.8 mL, 43.34 mmol) was added dropwise to the above mixture at 0° C. After heating up to 60° C., the resulting solution was reacted for 1 h, boron tribromide (5.6 mL, 59.1 mmol) was added dropwise to the above mixture at 0° C. and the resulting mixture was then reacted at room temperature for 2 h. After the dropwise addition of N,N-diisopropylethylamine (25.8 mL, 147.7 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-7. The resulting sample was further dried to yield about 3.3 g (yield: about 16.6%) of compound E2-7.

### Compound E2-8:

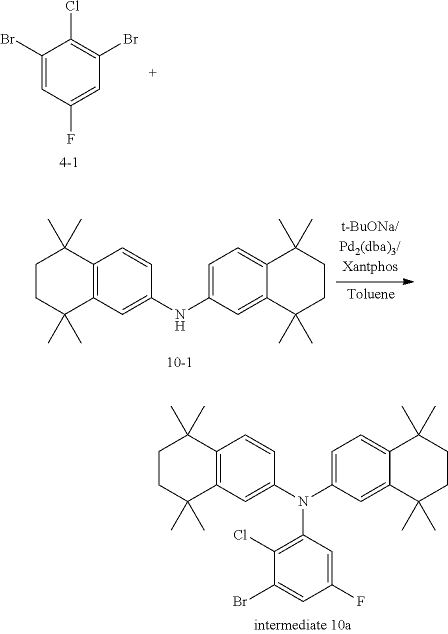 [SMILES: Fc1cc(Br)c(Cl)c(Br)c1 ; CC1(C)CCC(C)(C)c2cc(Nc3ccc4c(c3)C(C)(C)CCC4(C)C)ccc21 ; CC1(C)CCC(C)(C)c2cc(N(c3ccc4c(c3)C(C)(C)CCC4(C)C)c3cc(F)cc(Br)c3Cl)ccc21]

### Synthesis of Intermediate 10a:

Compound 4-1 (28.8 g, 100.0 mmol), compound 10-1 (42.8 g, 110.0 mmol), toluene (300 mL), sodium tert-butoxide (14.4 g, 150.0 mmol), Pd₂(dba)₃ (916 mg, 1.0 mmol), and Xantphos (1.1 g, 2.0 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=15:1, v:v) to obtain intermediate 10a. The resulting sample was dried to yield about 38.5 g (yield: about 64.6%) of intermediate 10a.

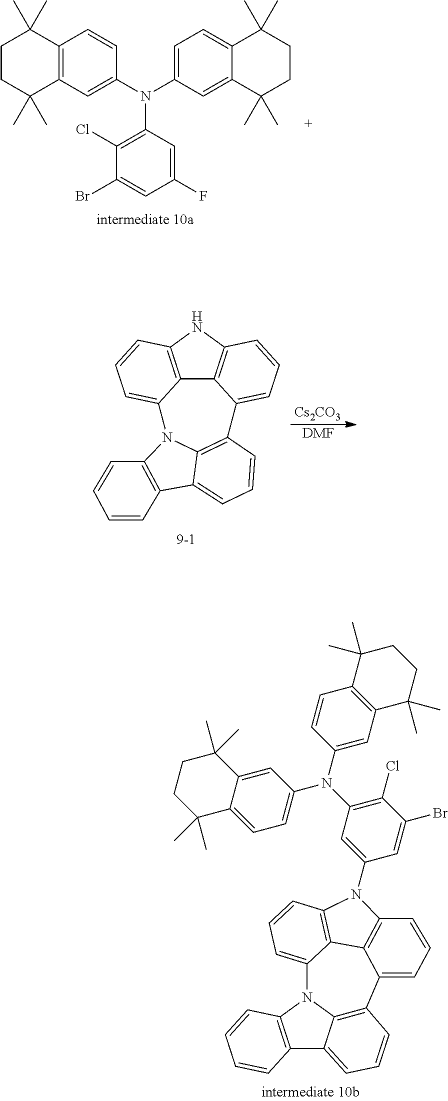

### Synthesis of Intermediate 10b:

Intermediate 10a (32.8 g, 55.0 mmol), compound 9-1 (19.9 g, 60.5 mmol), cesium carbonate (26.5 g, 82.5 mmol), and 300 mL of DMF were added in turn to a 500 mL three-necked flask, the reaction was heated to reflux. Monitored by TLC, the reaction was halted when the raw material had been substantially consumed, then the result was washed with 300 mL of methanol and 100 mL of water at room temperature for 2 h to obtain intermediate 10b. The resulting sample was dried to yield about 35.2 g (yield: about 70.7%) of intermediate 10b.

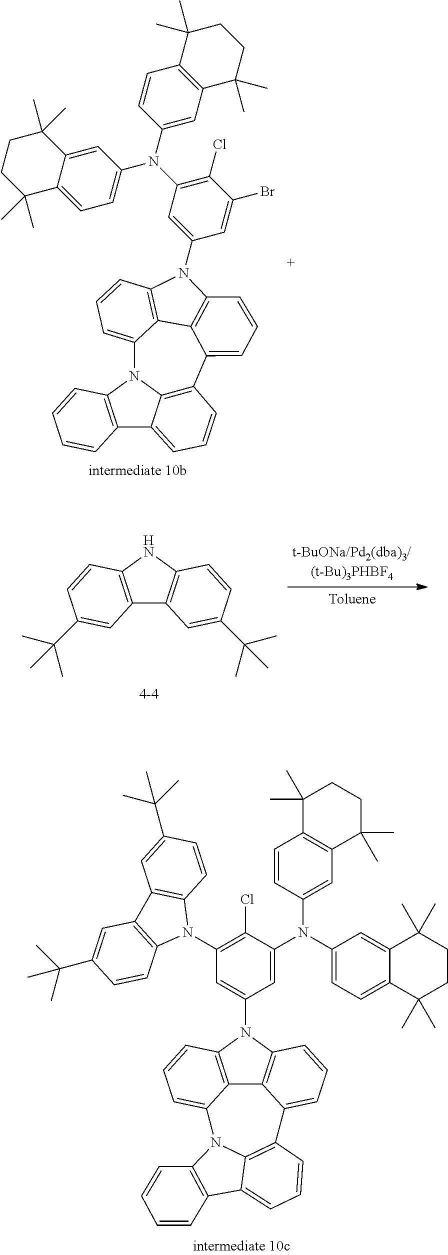 [SMILES: CC1(C)CCC(C)(C)c2cc(N(c3ccc4c(c3)C(C)(C)CCC4(C)C)c3cc(-n4c5cccc6c7cccc8c9ccccc9n(c9cccc4c9c65)c78)cc(Br)c3Cl)ccc21 ; CC(C)(C)c1ccc2[nH]c3ccc(C(C)(C)C)cc3c2c1 ; CC(C)(C)c1ccc2c(c1)c1cc(C(C)(C)C)ccc1n2-c1cc(-n2c3cccc4c5cccc6c7ccccc7n(c7cccc2c7c43)c56)cc(N(c2ccc3c(c2)C(C)(C)CCC3(C)C)c2ccc3c(c2)C(C)(C)CCC3(C)C)c1Cl]

### Synthesis of Intermediate 10c:

Intermediate 10b (27.7 g, 30.6 mmol), compound 4-4 (9.4 g, 33.6 mmol), toluene (200 mL), sodium tert-butoxide (4.4 g, 45.9 mmol), Pd₂(dba)₃ (280 mg, 0.3 mmol), and TTBPH BF₄ (174.0 mg, 0.6 mmol) were added in turn to a 500 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=12:1, v:v) to obtain intermediate 10c. The resulting sample was dried to yield about 23.0 g (yield: about 68.1%) of intermediate 10c.

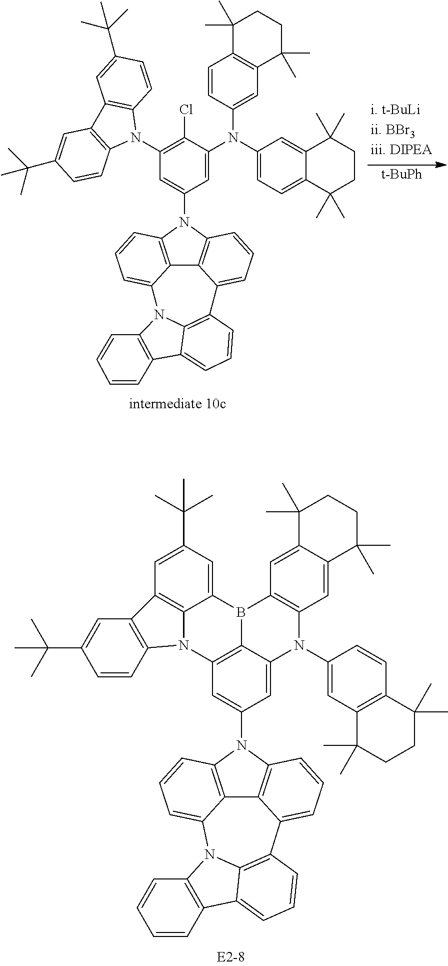

### Synthesis of Compound E2-8:

Intermediate 10c (21.7 g, 19.7 mmol) and tert-butylbenzene (200 mL) were added to a 500 mL three-necked flask under a nitrogen atmosphere, then 1.6 M tert-butyllithium (25.8 mL, 43.34 mmol) was added dropwise to the above mixture at 0° C. After heating up to 60° C., the resulting solution was reacted for 1 h, boron tribromide (5.6 mL, 59.1 mmol) was added dropwise to the above mixture at 0° C. and the resulting mixture was then reacted at room temperature for 2 h. After the dropwise addition of N,N-diisopropylethylamine (25.8 mL, 147.7 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-8. The resulting sample was further dried to yield about 2.1 g (yield: about 10.6%) of compound E2-8.

### Compound E2-9:

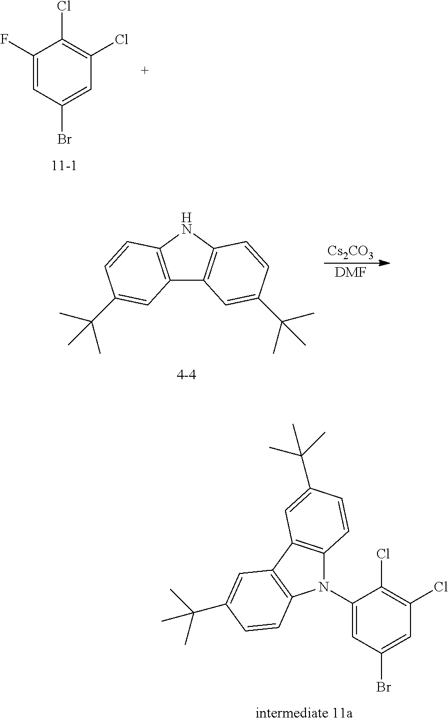

### Synthesis of Intermediate 11a:

Compound 11-1 (13.4 g, 55.0 mmol), compound 4-4 (19.9 g, 60.5 mmol), cesium carbonate (26.5 g, 82.5 mmol), and 300 mL of DMF were added in turn to a 500 mL three-necked flask, then heated to 100° C. Monitored by TLC, the reaction was halted when the raw material had been substantially consumed, then the result was washed with 300 mL of methanol and 100 mL of water at room temperature for 2 h to obtain intermediate 11a. The resulting sample was dried to yield about 25.5 g (yield: about 92.2%) of intermediate 11a.

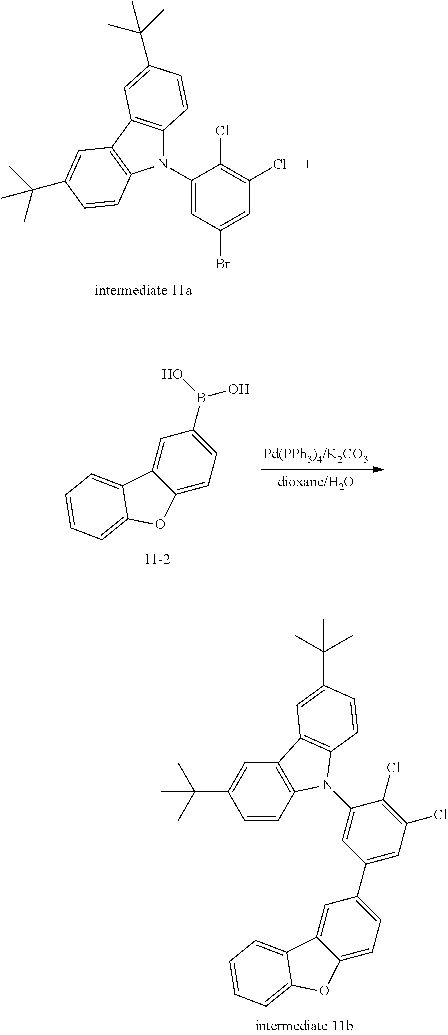 [SMILES: CC(C)(C)c1ccc2c(c1)c1cc(C(C)(C)C)ccc1n2-c1cc(Br)cc(Cl)c1Cl ; OB(O)c1ccc2oc3ccccc3c2c1 ; CC(C)(C)c1ccc2c(c1)c1cc(C(C)(C)C)ccc1n2-c1cc(-c2ccc3oc4ccccc4c3c2)cc(Cl)c1Cl]

### Synthesis of Intermediate 11b:

Intermediate 11a (14.4 g, 30.6 mmol), compound 11-2 (7.1 g, 33.6 mmol), 1,4-dioxane (150 mL), water (30 mL), potassium carbonate (8.4 g, 61.2 mmol), and Pd(PPh₃)₄ (346 mg, 0.3 mmol) were added in turn to a 250 mL three-necked flask under a nitrogen atmosphere, then heated to 100° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=10:1, v:v) to obtain intermediate 11b. The resulting sample was dried to yield about 15.1 g (yield: about 83.7%) of intermediate 11b.

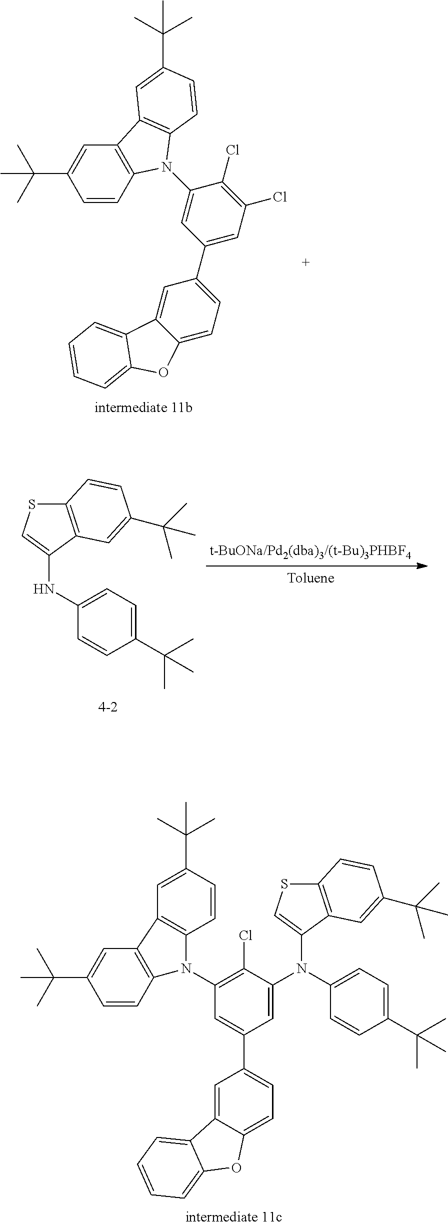 [SMILES: CC(C)(C)c1ccc2c(c1)c1cc(C(C)(C)C)ccc1n2-c1cc(-c2ccc3oc4ccccc4c3c2)cc(Cl)c1Cl ; CC(C)(C)c1ccc(Nc2csc3ccc(C(C)(C)C)cc23)cc1 ; CC(C)(C)c1ccc(N(c2cc(-c3ccc4oc5ccccc5c4c3)cc(-n3c4ccc(C(C)(C)C)cc4c4cc(C(C)(C)C)ccc43)c2Cl)c2csc3ccc(C(C)(C)C)cc23)cc1]

### Synthesis of Intermediate 11c:

Intermediate 11b (15.0 g, 25.4 mmol), compound 4-2 (9.4 g, 27.9 mmol), toluene (150 mL), sodium tert-butoxide (3.7 g, 38.1 mmol), Pd₂(dba)₃ (183 mg, 0.2 mmol), and TTBPH BF₄ (116.0 mg, 0.4 mmol) were added in turn to a 250 mL three-necked flask under a nitrogen atmosphere, then heated to 110° C. Monitored by TLC, after the reaction was completed, the reaction solution was cooled to room temperature and the solvent was removed by rotary evaporation, then the result was extracted with ethyl acetate and saturated sodium chloride solution. After that, the combined organic phases were dried, filtered, and concentrated, then the result was separated by silica gel column chromatography (eluent: n-hexane:dichloromethane=8:1, v:v) to obtain intermediate 11c. The resulting sample was dried to yield about 14.3 g (yield: about 63.5%) of intermediate 11c.

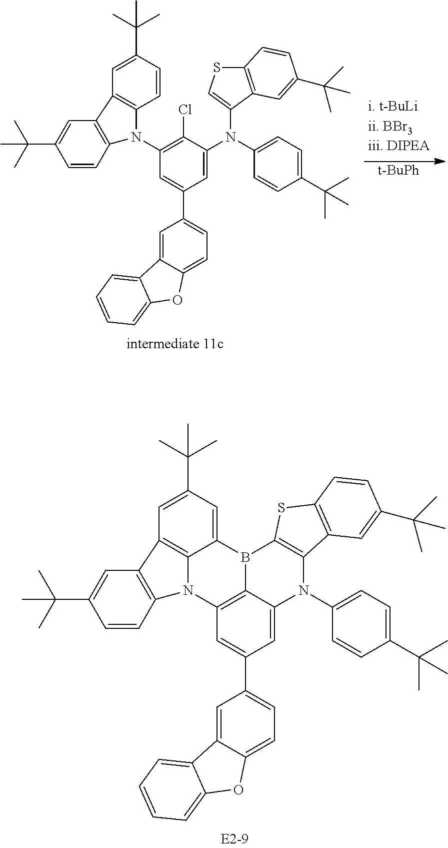

### Synthesis of Compound E2-9:

Intermediate 11c (10.0 g, 11.2 mmol) and tert-butylbenzene (200 mL) were added to a 500 mL three-necked flask under a nitrogen atmosphere, then 1.6 M tert-butyllithium (14.7 mL, 24.7 mmol) was added dropwise to the above mixture at 0° C. After heating up to 60° C., the resulting solution was reacted for 1 h, boron tribromide (3.2 mL, 33.6 mmol) was added dropwise to the above mixture at 0° C. and the resulting mixture was then reacted at room temperature for 2 h. After the dropwise addition of N,N-diisopropylethylamine (14.7 mL, 84.1 mmol) at 0° C., the mixture was heated to 120° C. and reacted for 3 h, then cooled down to room temperature. After removing the solvent via rotary evaporation, the result was extracted with ethyl acetate and saturated sodium chloride solution, the combined organic phases were dried, filtered, and concentrated, then the sample was recrystallized with toluene to obtain compound E2-9. The resulting sample was further dried to yield about 2.1 g (yield: about 21.8%) of compound E2-9.

### 2. Energy Level Structure of Compound E1

The energy level of the organic material can be calculated by quantum computation, for example, using TD-DFT (time-dependent density functional theory) by Gaussian 09W (Gaussian Inc.), the specific simulation methods of which can be found in CN110892543B. Firstly, the molecular geometry is optimized by semi-empirical method “Ground State/DFT/Default Spin/B3LYP” and the basis set “6-31G (d)” (Charge 0/Spin Singlet), and then the energy structure of organic molecules is calculated by TD-DFT (time-dependent density functional theory) “TD-SCF/DFT/Default Spin/B3PW91” and the basis set “6-31G (d)” (Charge 0/Spin Singlet). The HOMO and LUMO energy levels are calculated using the following calibration formula, where E_{S1} and E_{T1} are used directly.

$$HOMO ( eV ) = ( ( HOMO ( G ) \times 27.212 ) - 0.98 \; 99 ) / 1.1206$$

$$LUMO ( eV ) = ( ( LUMO ( G ) \times 27.212 ) - 2.00 \; 41 ) / 1.385$$

Where HOMO(G) and LUMO(G) are the direct calculation results of Gaussian 09W, in units of Hartree.

The results are shown in Table 1:

TABLE 1

| Compound | HOMO | LUMO | ΔHOMO | E_{S1} | E_{T1} | ΔE_{ST} |
|---|---|---|---|---|---|---|
| Number | (eV) | (eV) | (eV) | (eV) | (eV) | (eV) |
| E1-1 | −5.16 | −2.65 | 0.47 | 2.76 | 1.81 | 0.95 |
| E1-2 | −5.08 | −2.60 | 0.53 | 2.75 | 1.75 | 1.00 |
| E1-3 | −5.19 | −2.65 | 0.47 | 2.79 | 1.81 | 0.98 |
| E1-4 | −4.96 | −2.54 | 0.56 | 2.73 | 1.72 | 1.01 |
| E1-5 | −5.14 | −2.62 | 0.52 | 2.80 | 1.76 | 1.05 |
| E1-6 | −5.11 | −2.60 | 0.48 | 2.77 | 1.79 | 0.98 |

Where the HOMO energy level is defined as the energy of the highest occupied molecular orbital of the organic molecule; the LUMO energy level is defined as the energy of the lowest unoccupied molecular orbital of the organic molecule; the ΔHOMO is defined as the energy difference between the highest occupied molecular orbital and the next highest occupied molecular orbital of the organic molecule (i.e., ΔHOMO=HOMO−(HOMO−1)); the E_{S1} energy level is defined as the lowest singlet excited state energy level of the organic molecule; the E_{T1} energy level is defined as the lowest triplet excited state energy level of the organic molecule; the ΔE_{ST} is defined as the energy level difference between the lowest singlet excited state and the lowest triplet excited state of the organic molecule (i.e., ΔE_{ST}=E_{S1}−E_{T1}).

### 3. Optical Properties of the Mixtures

The organic mixture is prepared as follows.

E1 and E2 were together dissolved in toluene at a specific mass ratio to obtain a homogeneous solution, the solvent was then removed by vacuum drying to yield a solid mixture. The obtained solid was further mechanically ground and uniformly mixed in a quartz mortar to obtain the organic mixture.

The mixture formulations and their photoluminescence properties in polystyrene (PS) films are shown in Table 2. The preparation and characterization methods of the polystyrene-doped films are as follows:

Polystyrene (CAS: 9003-53-6, average Mw~280,000 by GPC, purchased from Sigma-Aldrich) was dissolved in toluene to form a 100 mg/mL solution. Under oscillating conditions, the comparative compound or the organic mixture as described herein was dissolved therein at a concentration of 3 mg/mL to form a homogeneous solution. The resulting solution was spin-coated on glass at 1000 rpm for 30 s and then heated on a hot plate at 80° C. for 5 min to completely solidify into a transparent film with a thickness of 2 μm. After that, the emission spectrum of the obtained film was acquired in the wavelength range of 400 nm-800 nm under 360 nm excitation to obtain the emission peak wavelength and FWHM values, and the absorption peak was determined by measuring the ultraviolet-visible (UV-Vis) absorption spectrum of the compound in a toluene solution.

TABLE 2

| | | | | E1-Emission | E2-Absorption | Emission | |
|---|---|---|---|---|---|---|---|
| | E1 | E2 | E1:E2 | Peak | Peak | Peak | FWHM |
| Comparative | E1-1 | — | — | 455 | — | 455 | 46 |
| Example 1 | | | | | | | |
| Comparative | E1-2 | — | — | 459 | — | 459 | 47 |
| Example 2 | | | | | | | |
| Comparative | E1-3 | — | — | 454 | — | 454 | 44 |
| Example 3 | | | | | | | |
| Comparative | E1-4 | — | — | 454 | — | 454 | 48 |
| Example 4 | | | | | | | |
| Comparative | — | E2-1 | — | — | 445 | 458 | 25 |
| Example 5 | | | | | | | |
| Comparative | — | E2-2 | — | — | 449 | 459 | 21 |
| Example 6 | | | | | | | |
| Comparative | — | E2-3 | — | — | 450 | 464 | 21 |
| Example 7 | | | | | | | |
| Comparative | — | E2-4 | — | — | 449 | 463 | 23 |
| Example 8 | | | | | | | |
| Comparative | — | E2-5 | — | — | 445 | 460 | 20 |
| Example 9 | | | | | | | |
| Comparative | — | E2-9 | — | — | 456 | 468 | 23 |
| Example 10 | | | | | | | |
| Example 1 | E1-1 | E2-1 | 3:1 | 455 | 445 | 459 | 30 |
| Example 2 | E1-1 | E2-1 | 2:1 | 455 | 445 | 459 | 28 |
| Example 3 | E1-1 | E2-1 | 1:1 | 455 | 445 | 460 | 28 |
| Example 4 | E1-1 | E2-1 | 1:2 | 455 | 445 | 460 | 26 |
| Example 5 | E1-2 | E2-1 | 3:1 | 459 | 445 | 460 | 33 |
| Example 6 | E1-2 | E2-1 | 2:1 | 459 | 445 | 460 | 31 |
| Example 7 | E1-2 | E2-1 | 1:1 | 459 | 445 | 460 | 28 |
| Example 8 | E1-2 | E2-2 | 3:1 | 459 | 449 | 459 | 24 |
| Example 9 | E1-2 | E2-2 | 2:1 | 459 | 449 | 459 | 22 |
| Example 10 | E1-2 | E2-2 | 1:1 | 459 | 449 | 458 | 21 |
| Example 11 | E1-2 | E2-3 | 3:1 | 459 | 450 | 465 | 24 |
| Example 12 | E1-2 | E2-3 | 2:1 | 459 | 450 | 465 | 23 |
| Example 13 | E1-2 | E2-3 | 1:1 | 459 | 450 | 465 | 22 |
| Example 14 | E1-2 | E2-4 | 3:1 | 459 | 449 | 463 | 25 |
| Example 15 | E1-2 | E2-4 | 2:1 | 459 | 449 | 463 | 25 |
| Example 16 | E1-2 | E2-4 | 1:1 | 459 | 449 | 463 | 24 |
| Example 17 | E1-3 | E2-5 | 3:1 | 454 | 447 | 460 | 23 |
| Example 18 | E1-3 | E2-5 | 2:1 | 454 | 447 | 460 | 21 |
| Example 19 | E1-3 | E2-5 | 1:1 | 454 | 447 | 460 | 20 |
| Example 20 | E1-4 | E2-2 | 1:1 | 454 | 449 | 460 | 20 |
| Example 21 | E1-5 | E2-2 | 1:1 | 462 | 449 | 461 | 25 |
| Example 22 | E1-6 | E2-2 | 1:1 | 454 | 449 | 460 | 21 |
| Example 23 | E1-4 | E2-3 | 1:1 | 454 | 450 | 465 | 21 |
| Example 24 | E1-5 | E2-3 | 1:1 | 462 | 450 | 465 | 24 |
| Example 25 | E1-6 | E2-3 | 1:1 | 454 | 450 | 465 | 21 |
| Example 26 | E1-4 | E2-4 | 1:1 | 454 | 449 | 463 | 24 |
| Example 27 | E1-5 | E2-4 | 1:1 | 462 | 449 | 464 | 27 |
| Example 28 | E1-6 | E2-4 | 1:1 | 454 | 449 | 463 | 24 |
| Example 29 | E1-4 | E2-5 | 1:1 | 454 | 445 | 460 | 21 |
| Example 30 | E1-5 | E2-5 | 1:1 | 462 | 445 | 461 | 23 |
| Example 31 | E1-6 | E2-5 | 1:1 | 454 | 445 | 460 | 21 |
| Example 32 | E1-4 | E2-6 | 1:1 | 454 | 445 | 459 | 20 |
| Example 33 | E1-5 | E2-6 | 1:1 | 462 | 445 | 461 | 25 |
| Example 34 | E1-6 | E2-6 | 1:1 | 454 | 445 | 460 | 21 |
| Example 35 | E1-4 | E2-7 | 1:1 | 454 | 448 | 460 | 24 |
| Example 36 | E1-5 | E2-7 | 1:1 | 462 | 448 | 460 | 28 |
| Example 37 | E1-6 | E2-7 | 1:1 | 454 | 448 | 460 | 24 |
| Example 38 | E1-4 | E2-8 | 1:1 | 454 | 454 | 467 | 23 |
| Example 39 | E1-5 | E2-8 | 1:1 | 462 | 454 | 467 | 23 |
| Example 40 | E1-6 | E2-8 | 1:1 | 454 | 454 | 467 | 23 |
| Example 41 | E1-3 | E2-9 | 1:1 | 454 | 456 | 468 | 23 |
| Example 42 | E1-4 | E2-9 | 1:1 | 454 | 456 | 468 | 23 |
| Example 43 | E1-5 | E2-9 | 1:1 | 462 | 456 | 468 | 24 |
| Example 44 | E1-6 | E2-9 | 1:1 | 454 | 456 | 468 | 23 |

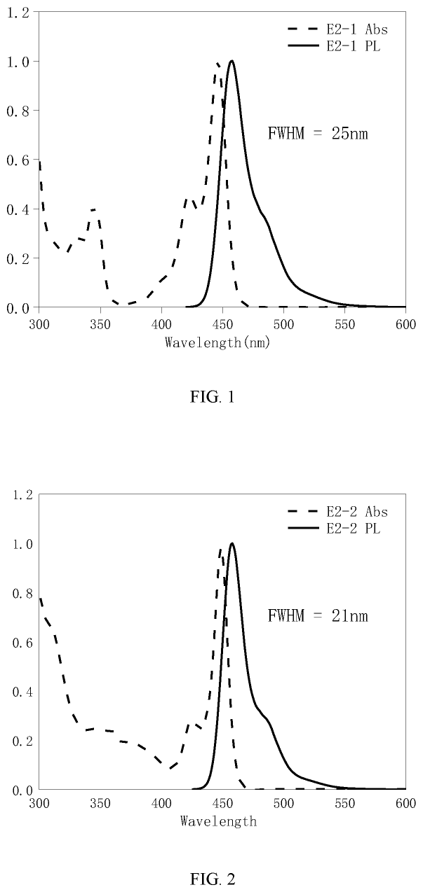

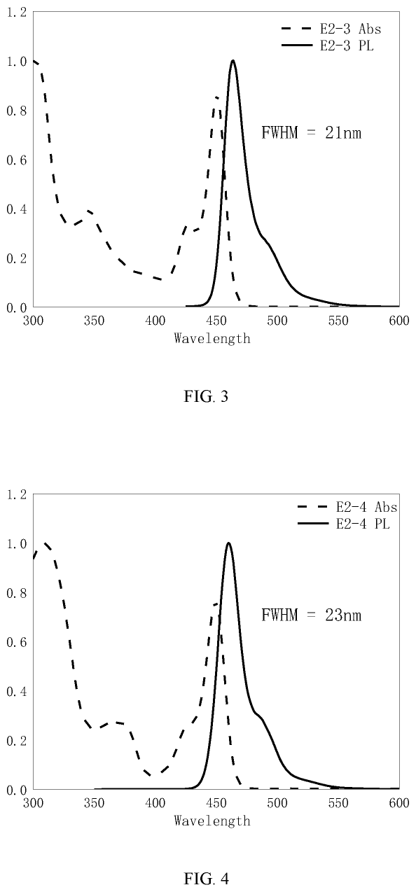

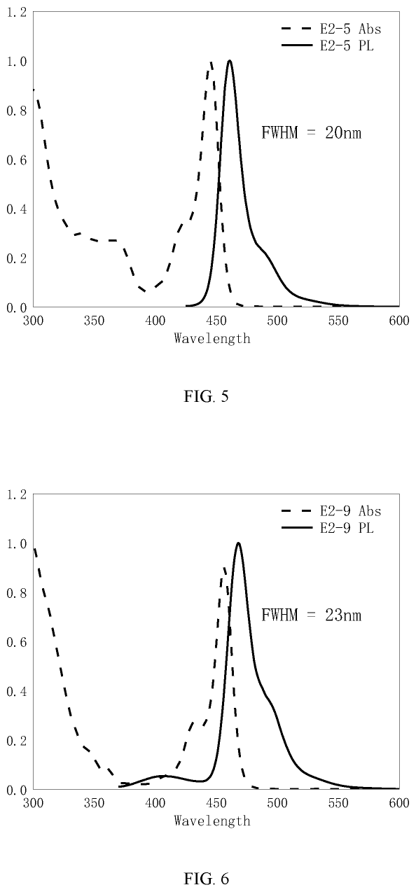

FIG. 1-FIG. 6 sequentially show the absorption (Abs) and emission (PL) spectrums of E2-1, E2-2, E2-3, E2-4, E2-5, and E2-9. It can be seen that the FWHMs of the emission spectrums for E2-1, E2-2, E2-3, E2-4, E2-5, and E2-9 are 25 nm, 21 nm, 21 nm, 23 nm, 20 nm, and 23 nm, respectively.

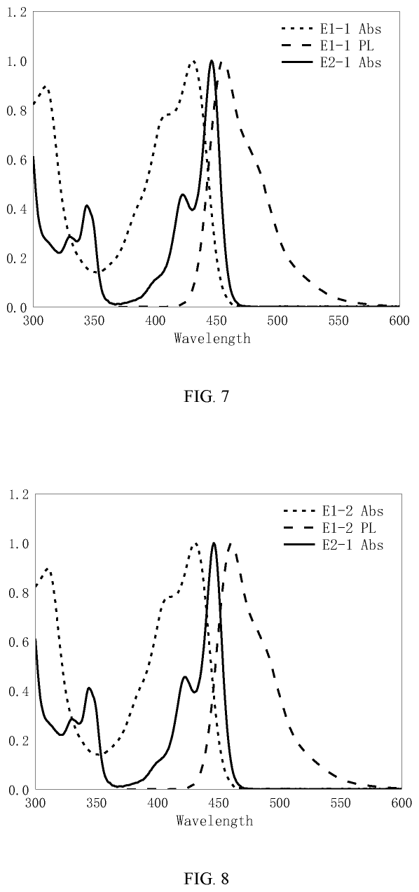

FIG. 7 shows the absorption (Abs) and emission (PL) spectrums of the compound E1-1, and the absorption (Abs) spectrum of the compound E2-1. There is a significant overlap between the absorption spectrum of the compound E2-1 and the emission spectrum of the compound E1-1.

FIG. 8 shows the absorption (Abs) and emission (PL) spectrums of the compound E1-2, and the absorption (Abs) spectrum of the compound E2-1. There is a certain degree of overlap between the absorption spectrum of compound E2-1 and the emission spectrum of the compound E1-2.

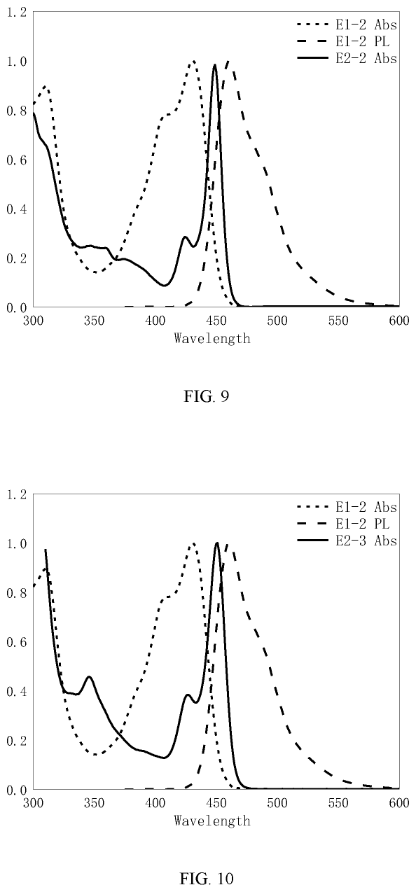

FIG. 9 shows the absorption (Abs) and emission (PL) spectrums of the compound E1-2, and the absorption (Abs) spectrum of the compound E2-2. There is a significant overlap between the absorption spectrum of the compound E2-2 and the emission spectrum of the compound E1-2.

FIG. 10 shows the absorption (Abs) and emission (PL) spectrums of the compound E1-2, and the absorption (Abs) spectrum of the compound E2-3. There is a significant overlap between the absorption spectrum of the compound E2-3 and the emission spectrum of the compound E1-2.

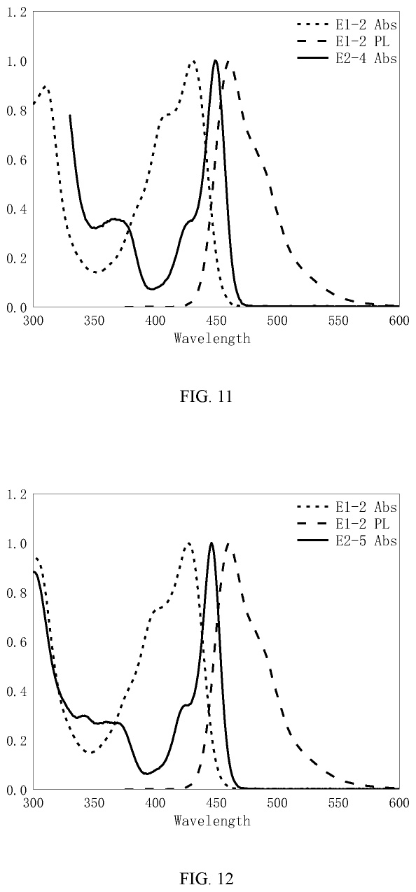

FIG. 11 shows the absorption (Abs) and emission (PL) spectrums of the compound E1-2, and the absorption (Abs) spectrum of the compound E2-4. There is a significant overlap between the absorption spectrum of the compound E2-4 and the emission spectrum of the compound E1-2.

FIG. 12 shows the absorption (Abs) and emission (PL) spectrums of the compound E1-2, and the absorption (Abs) spectrum of the compound E2-5. There is a significant overlap between the absorption spectrum of the compound E2-5 and the emission spectrum of the compound E1-2.

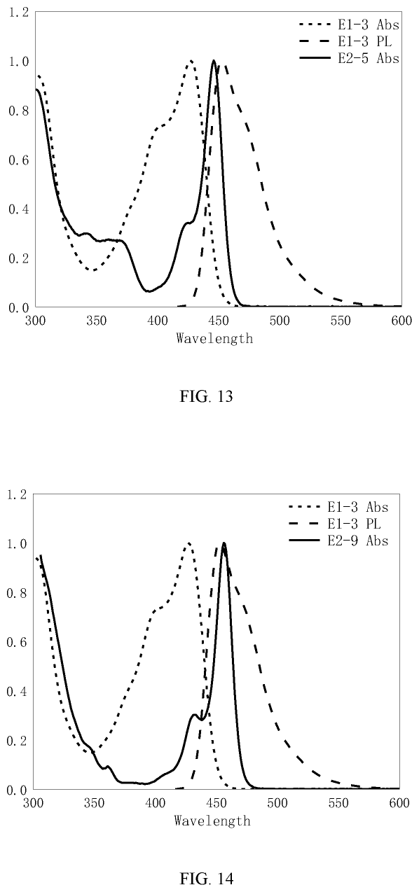

FIG. 13 shows the absorption (Abs) and emission (PL) spectrums of the compound E1-3, and the absorption (Abs) spectrum of the compound E2-5. There is a significant overlap between the absorption spectrum of the compound E2-5 and the emission spectrum of the compound E1-3.

FIG. 14 shows the absorption (Abs) and emission (PL) spectrums of the compound E1-3, and the absorption (Abs) spectrum of the compound E2-9. There is a significant overlap between the absorption spectrum of the compound E2-9 and the emission spectrum of the compound E1-3.

The materials used in the light-emitting device embodiments of the present disclosure are as follows:

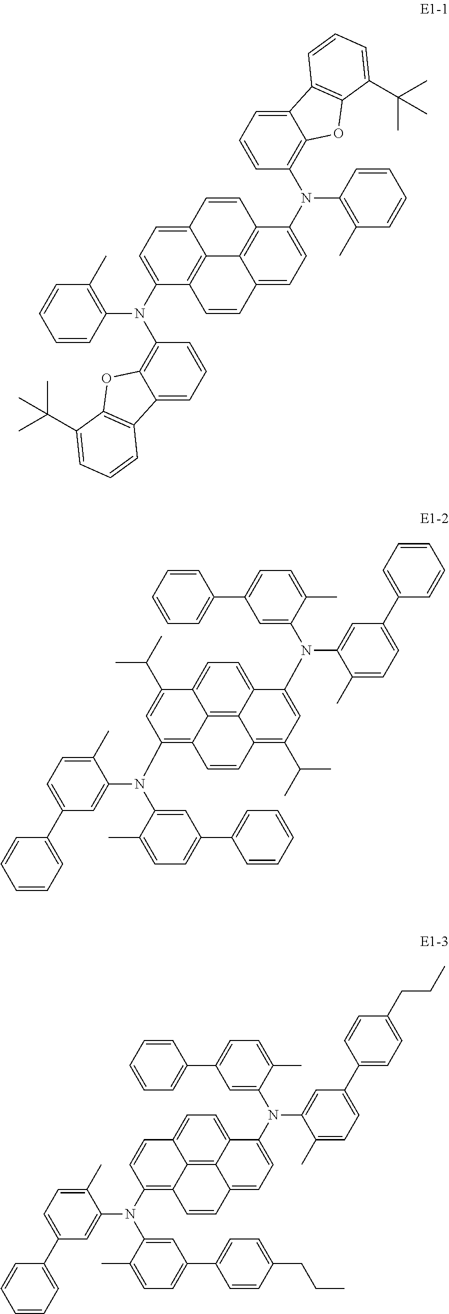 [SMILES: Cc1ccccc1N(c1ccc2ccc3c(N(c4ccccc4C)c4cccc5c4oc4c(C(C)(C)C)cccc45)ccc4ccc1c2c43)c1cccc2c1oc1c(C(C)(C)C)cccc12 ; Cc1ccc(-c2ccccc2)cc1N(c1cc(-c2ccccc2)ccc1C)c1cc(C(C)C)c2ccc3c(N(c4cc(-c5ccccc5)ccc4C)c4cc(-c5ccccc5)ccc4C)cc(C(C)C)c4ccc1c2c43 ; CCCc1ccc(-c2ccc(C)c(N(c3cc(-c4ccccc4)ccc3C)c3ccc4ccc5c(N(c6cc(-c7ccccc7)ccc6C)c6cc(-c7ccc(CCC)cc7)ccc6C)ccc6ccc3c4c65)c2)cc1]

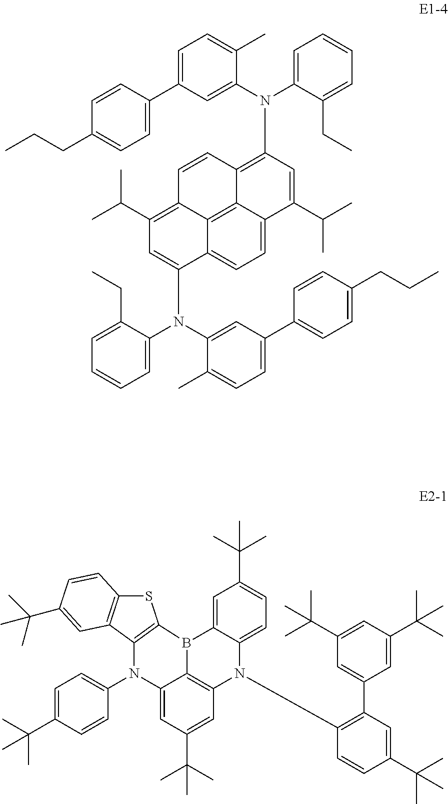

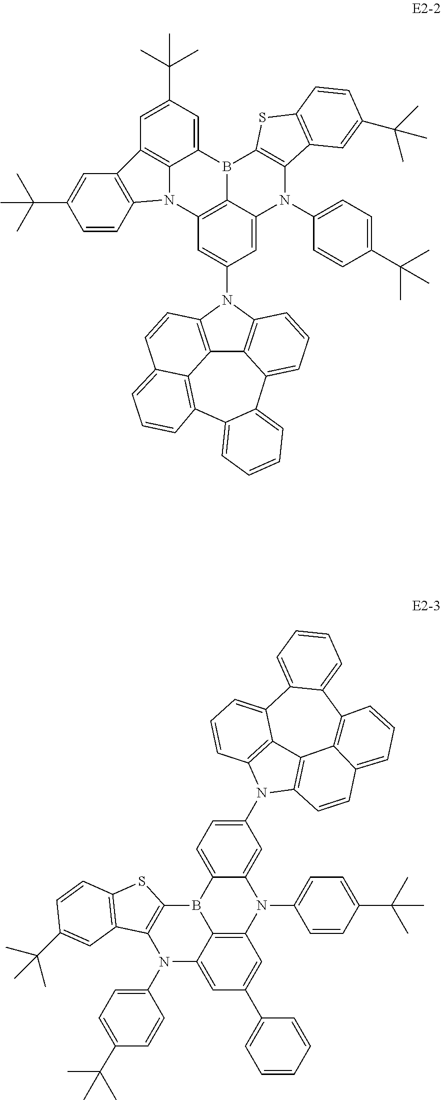

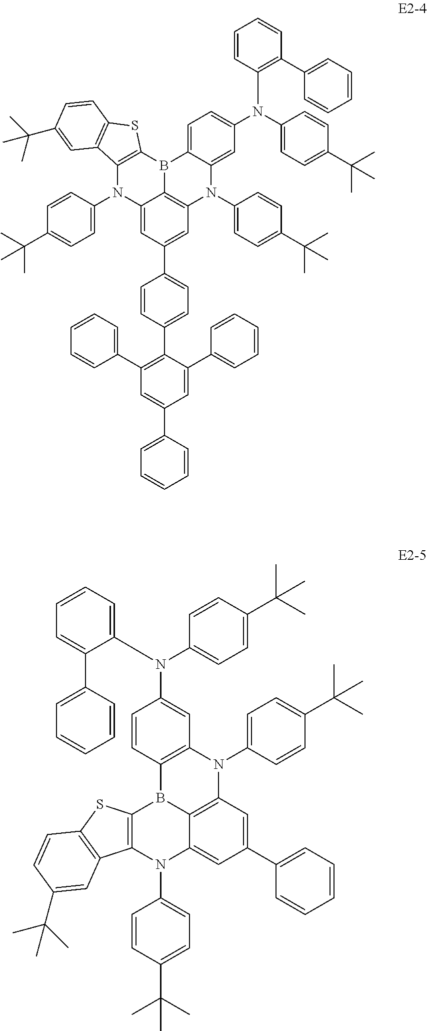

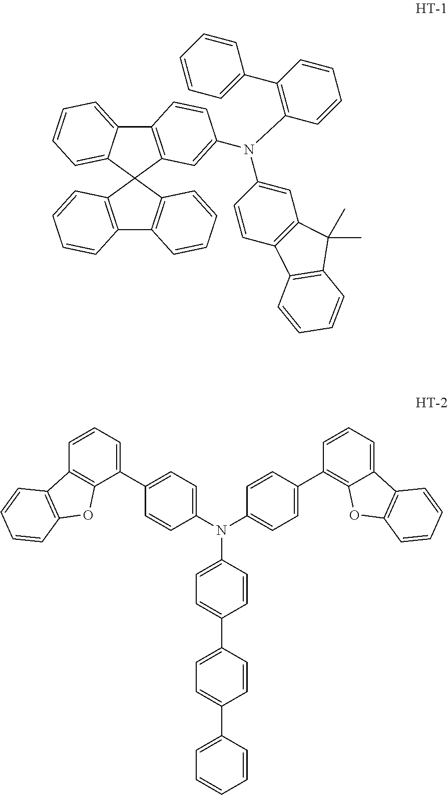 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

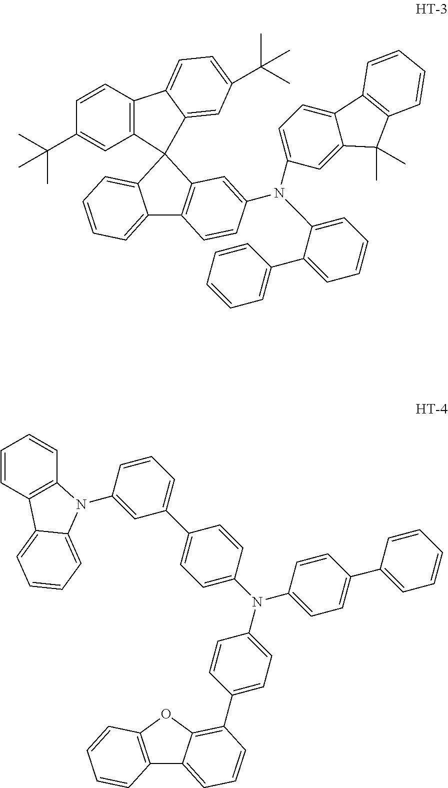 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

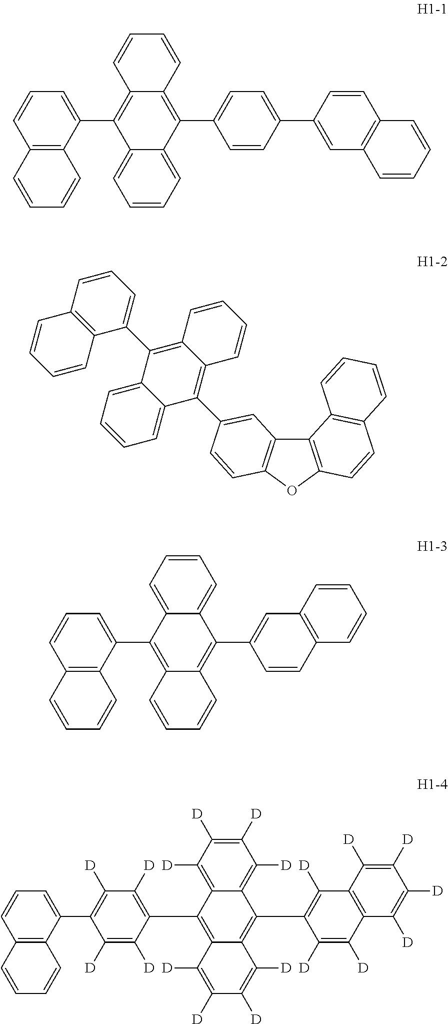

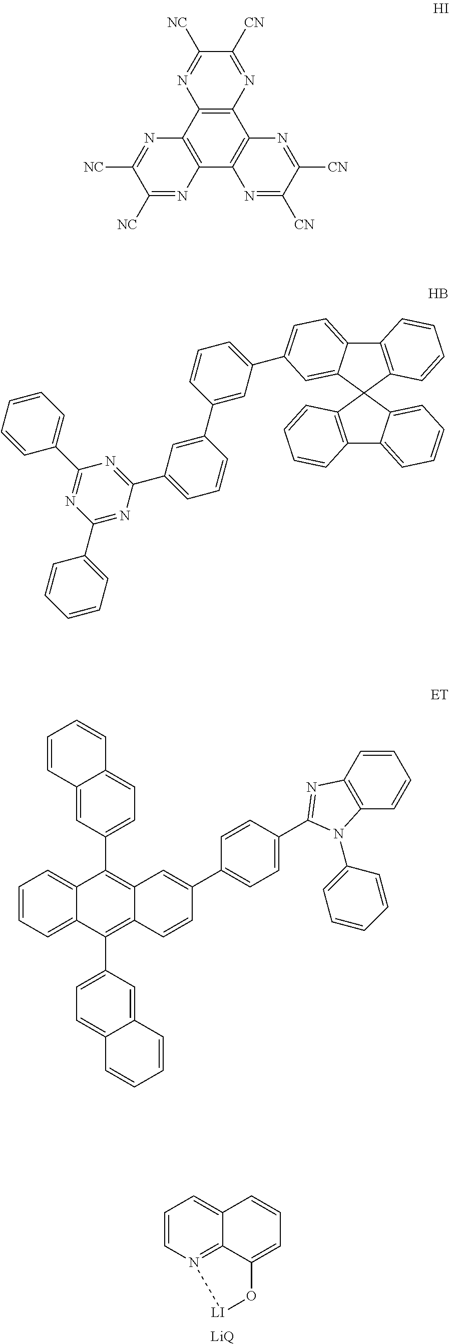

Among them, the compound HT-1 was synthesized according to the method described in application No. CN110416418A; the compound HT-2 was synthesized according to the method described in International Publication No. WO2016060332A1; the compound HT-3 was synthesized according to the method described in International Publication No.

WO2012034627A1; the compound HT-4 was synthesized according to the method described in U.S. Pat. No. 20200144506A1; the compound H1-2 was synthesized according to the method described in International Publication No. WO2010137285A1; the compound H1-3 was synthesized according to the method described in U.S. Pat. No. 2022216410A1; the compound H1-4 was synthesized according to the method described in International Publication No.

WO2021107742A1; the compound HB was synthesized according to the method described in International Publication No. WO2018074845A1; HAT-CN (HI), H1-1, ET, and LiQ were purchased from Jilin OLED Material Tech Co., Ltd.; other materials were synthesized according to the above-mentioned methods.

### 4. Preparation and Characterization of Evaporation-Based OLEDs

In one embodiment, the evaporation-based OLEDs were fabricated based on the device structure of HI (30 nm)/HT-1 (50 nm)/HT-2 (10 nm)/BH:BD=97:3 (25 nm)/ET:LiQ=50:50 (30 nm)/LiQ (1 nm)/Al (100 nm).

The preparation process for device example OLEDA1-device example OLEDA3 (comparative examples) is as follows:

a. Cleaning of the ITO (Indium Tin Oxide) conductive glass substrate: the substrates are washed with various solvents (such as one or more of chloroform, ketone, or isopropyl alcohol), and then treated with UV and ozone.

b. Evaporation: the resultant ITO substrate was mounted on a vacuum deposition apparatus in high vacuum (1×10⁻⁶ mbar), and HAT-CN was then vacuum-deposited on the anode to form a hole-injection layer having a thickness of 30 nm, then two hole-transport layers, HT-1 (50 nm) and HT-2 (10 nm) were deposited on the HIL in vacuum deposition sequentially. Then BH and BD (where BH is H1-1 and BD is listed in Table 3) in two different evaporation sources were deposited at a weight ratio of 97:3 to form an emissive layer having a thickness of 25 nm. Subsequently, compound ET and LiQ were placed in two different evaporation units, and co-deposited at a weight ratio of 50:50 to form an electron-transport layer having a thickness of 30 nm. LiQ was then deposited on the electron-transport layer to form an electron-injection layer having a thickness of 1 nm, and Al was deposited on the electron-injection layer to form a cathode having a thickness of 100 nm.

c. Encapsulation: encapsulating the device in a nitrogen-regulated glove box with an UV curable resin and a glass cover plate.

The preparation process for OLEDA4 and OLEDA5 is as follows: steps a and c are the same as described in the procedures for preparing the above-mentioned OLEDA1-OLEDA3.

b. Evaporation: the resultant ITO substrate was mounted on a vacuum deposition apparatus in high vacuum (1×10⁻⁶ mbar), and HAT-CN was then vacuum-deposited on the anode to form a hole-injection layer having a thickness of 30 nm, then two hole-transport layers, HT-1 (50 nm) and HT-2 (10 nm) were deposited on the HIL in vacuum deposition sequentially. Then BH, BD1, and BD2 (where BH is H1-1, BD1, and BD2 are listed in Table 3) in three different evaporation sources were deposited at a weight ratio of 97:1.5:1.5 to form an emissive layer having a thickness of 25 nm. Subsequently, compound ET and LiQ were placed in two different evaporation units, and co-deposited at a weight ratio of 50:50 to form an electron-transport layer having a thickness of 30 nm. LiQ was then deposited on the electron-transport layer to form an electron-injection layer having a thickness of 1 nm, and Al was deposited on the electron-injection layer to form a cathode having a thickness of 100 nm.

As shown in Table 3, the device performance of the device examples and the comparative example were tested; where the driving voltage was measured at a current density of 10 mA/cm²; T95 refers to the relative value of the time at which the luminance of the device examples decreases to 95% of the initial luminance at a constant current density of 50 mA/cm² compared with that of OLEDA1.

TABLE 3

| | BD | Driving Voltage (V) | T95@J50 |
|---|---|---|---|
| OLEDA1 | E1-1 | 3.75 | 100% |
| OLEDA2 | E2-1 | 3.70 | 80% |
| OLEDA3 | E2-2 | 3.73 | 75% |

| | | | | |
|---|---|---|---|---|
| OLEDA4 | E1-1 | E2-1 | 3.71 | 343% |
| OLEDA5 | E1-1 | E2-2 | 3.72 | 257% |

OLEDA4 and OLEDA5 show a significant improvement in lifetime, with no significant difference in driving voltage compared to the Comparative Examples (i.e, OLEDA1, OLEDA2, and OLEDA3). This result indicates that the OLED device containing two types of emitters can extend its lifetime.

In another embodiment, the evaporation-based OLEDs were fabricated based on the device structure of HI(10 nm)/HT-3 (50 nm)/HT-4 (5 nm)/BH:BD=97:3 (20 nm)/HB (5 nm)/ET:LiQ=50:50 (25 nm)/LiQ(2 nm)/Al(100 nm).

The preparation process for device example OLEDB1-device example OLEDB9 (comparative examples) is as follows:

a. Cleaning of the ITO (Indium Tin Oxide) conductive glass substrate: the substrates are washed with various solvents (such as one or more of chloroform, ketone, or isopropyl alcohol), and then treated with UV and ozone.

b. Evaporation: the resultant ITO substrate was mounted on a vacuum deposition apparatus in high vacuum (1×10⁻⁶ mbar), and HAT-CN was then vacuum-deposited on the anode to form a hole-injection layer having a thickness of 10 nm, then two hole-transport layers, HT-3 (50 nm) and HT-4 (5 nm) were deposited on the HIL in vacuum deposition sequentially. Then BH and BD (where BH is H1-2 and BD is listed in Table 4) in two different evaporation sources were deposited at a weight ratio of 97:3 to form an emissive layer having a thickness of 20 nm. Subsequently, HB was deposited on the emissive layer to form a hole-blocking layer having a thickness of 5 nm, then compound ET and LiQ were placed in two different evaporation units, and co-deposited at a weight ratio of 50:50 to form an electron-transport layer having a thickness of 25 nm. LiQ was then deposited on the electron-transport layer to form an electron-injection layer having a thickness of 2 nm, and Al was deposited on the electron-injection layer to form a cathode having a thickness of 100 nm.

c. Encapsulation: encapsulating the device in a nitrogen-regulated glove box with an UV curable resin and a glass cover plate.

The preparation process for OLEDB10-OLEDB23 is as follows:

Steps a and c are the same as described in the procedures for preparing the above-mentioned OLEDB1-OLEDB9.

b. Evaporation: the resultant ITO substrate was mounted on a vacuum deposition apparatus in high vacuum (1×10⁻⁶ mbar), and HAT-CN was then vacuum-deposited on the anode to form a hole-injection layer having a thickness of 10 nm, then two hole-transport layers, HT-3 (50 nm) and HT-4 (5 nm) were deposited on the HIL in vacuum deposition sequentially. Then BH, BD1, and BD2 (where BH is H1-2, and BD1 and BD2 are listed in Table 4) in three different evaporation sources were deposited at a weight ratio of 97:x:3-x to form an emissive layer having a thickness of 20 nm. Subsequently, HB was deposited on the emissive layer to form a hole-blocking layer having a thickness of 5 nm, compound ET and LiQ were placed in two different evaporation units, and co-deposited at a weight ratio of 50:50 to form an electron-transport layer having a thickness of 25 nm. LiQ was then deposited on the electron-transport layer to form an electron-injection layer having a thickness of 2 nm, and Al was deposited on the electron-injection layer to form a cathode having a thickness of 100 nm.

As shown in Table 4, the device performance of the device examples and the comparative example were tested; where the EL peak, the EL FWQM, and the EQE were measured at a current density of 10 mA/cm; LT95 refers to the relative value of the time at which the luminance of the device examples decreases to 9500 of the initial luminance at a constant current density of 50 mA/c^{m} compared with that of OLEDB1.

TABLE 4

| | | | weight | EL | | | LT95@J50 |
|---|---|---|---|---|---|---|---|
| | | | ratio of | peak | FWHM | EQE | (relative |
| Device | BD | | E1:E2 | (nm) | (nm) | (%) | value) |
| OLEDB1 | E1-1 | | \ | 454 | 33 | 10.5 | 100% |
| OLEDB2 | E1-2 | | \ | 460 | 34 | 10.4 | 99% |
| OLEDB3 | E1-3 | | \ | 456 | 36 | 10.4 | 104% |
| OLEDB4 | E1-4 | | \ | 454 | 35 | 10.1 | 102% |
| OLEDB5 | E2-1 | | \ | 460 | 21 | 8.9 | 65% |
| OLEDB6 | E2-2 | | \ | 459 | 18 | 9.7 | 27% |
| OLEDB7 | E2-3 | | \ | 465 | 22 | 8.4 | 39% |
| OLEDB8 | E2-4 | | \ | 463 | 23 | 8.9 | 48% |
| OLEDB9 | E2-5 | | \ | 460 | 20 | 9.8 | 63% |
| OLEDB10 | E1-1 | E2-1 | 1:1 | 460 | 22 | 10.5 | 112% |
| OLEDB11 | E1-2 | E2-1 | 1:1 | 460 | 24 | 10.1 | 105% |
| OLEDB12 | E1-2 | E2-2 | 3:1 | 460 | 23 | 10.2 | 117% |
| OLEDB13 | E1-2 | E2-2 | 2:1 | 460 | 21 | 10.3 | 138% |
| OLEDB14 | E1-2 | E2-2 | 1:1 | 460 | 19 | 10.3 | 125% |
| OLEDB15 | E1-2 | E2-3 | 1:1 | 465 | 22 | 10.4 | 124% |
| OLEDB16 | E1-2 | E2-4 | 1:1 | 463 | 23 | 10.3 | 127% |
| OLEDB17 | E1-2 | E2-5 | 1:1 | 460 | 22 | 10.2 | 119% |
| OLEDB18 | E1-3 | E2-5 | 3:1 | 460 | 21 | 10.3 | 118% |
| OLEDB19 | E1-3 | E2-5 | 2:1 | 460 | 20 | 10.2 | 136% |
| OLEDB20 | E1-3 | E2-5 | 1:1 | 460 | 20 | 10.3 | 147% |
| OLEDB21 | E1-3 | E2-5 | 1:2 | 460 | 20 | 10.3 | 112% |
| OLEDB22 | E1-4 | E2-2 | 1:1 | 459 | 18 | 10.1 | 106% |
| OLEDB23 | E1-4 | E2-5 | 1:1 | 460 | 20 | 10.0 | 117% |

Comparative Examples OLEDB 1 to OLEDB9 demonstrate that devices using a single BD struggle to simultaneously achieve narrow emission spectrum and long device lifetime. Comparative Examples OLEDB1-OLEDB4 exhibit an extended device lifetime by employing a single non-MR-TADF BD, but their FWHM values all exceed 30 nm, resulting in significantly lower color purity compared to OLEDB5-OLEDB9, which employ MR-TADF BDs. Meanwhile, although OLEDB5-OLEDB9 exhibit desirable narrow emission spectrum (all with FWHM<25 nm; OLEDB6 has the narrowest FWHM at only 18 nm), their device lifetimes are significantly shorter than those of OLEDB1-OLEDB3.

In contrast, OLEDB10-OLEDB23 using the organic mixture of the present disclosure as the dopant exhibit a narrower emission spectrum, higher device efficiency, and longer device lifetime compared to those using a single dopant. In the comparison between OLEDB1, OLEDB5, and OLEDB10, OLEDB10 utilizing the organic mixture of the present disclosure simultaneously exhibits a narrow spectrum close to that of OLEDB5 and an external quantum efficiency consistent with OLEDB1. Furthermore, its device lifetime exceeds that of OLEDB1 and is significantly longer than that of OLEDB5.

In the comparison between OLEDB1, OLEDB2, OLEDB10, and OLEDB11, when OLEDB1 and OLEDB2 using a single E1 dopant have similar EQE and lifetime, OLEDB10 exhibits higher device efficiency, narrower spectrum, and longer device lifetime, which may be related to the blue shift of E1-1 spectrum compared to E1-2 spectrum, resulting in more effective excited state energy transfer between E1 and E2.

In the comparison of OLEDB14 to OLEDB17, the consistency of their spectral full width at half maximum (FWHM) with that of a device employing a single E2 is correlated with the degree of overlap between the emission spectrum of E1 and the absorption spectrum of E2 in the mixture. This indicates that the realization of a narrow spectrum in devices utilizing the organic mixture of the present disclosure is associated with the energy transfer efficiency between E1 and E2. Additionally, the devices OLEDB14-OLEDB17 exhibit gains in lifetime compared to devices utilizing single E1 and E2 components.

OLEDB18-OLEDB21 exhibit high overall device performance across different E1:E2 doping ratios, which may be attributed to the inherent stability of E2 and the highly efficient excited-state energy transfer mechanism between E1 and E2. Among them, OLEDB18 with the highest E1 ratio exhibits a narrow emission spectrum highly comparable to that of devices utilizing pure E2. This indicates that the presence of an efficient energy transfer mechanism enables the attainment of desirable narrow emission spectrum even at relatively low E2 ratios. On the other hand, although OLEDB21 has a higher proportion of E2 than E1, it still exhibits a relatively long device lifetime. This observation suggests that specific combinations of E1 and E2 in the mixture can effectively protect the relatively unstable MR-TADF dopant, reducing exciton energy-induced structural degradation. Furthermore, although OLEDB20 contains a higher proportion of E2 in the emissive layer compared to OLEDB18 and OLEDB19, it nevertheless exhibits a longer operation lifetime than these two devices. In summary, the device performance improvement provided by the organic mixture of the present disclosure is unexpected and cannot be simply attributed to the averaging effects of the spectral and lifetime characteristics between the two distinct dopants (i.e., E1 and E2). A possible explanation is that the active excited-state energy transfer in the organic mixture of the present disclosure provides an additional energy dissipation pathway, thereby protecting the relatively weak chemical bonds in the dopants, while the dual-guest configuration further improves the carrier balance of the original device.

Furthermore, OLEDB22 and OLEDB23 also achieved certain lifetime gains compared to single-dopant devices, while their spectral FWHM remained consistent with that of OLEDB6 and OLEDB9, which utilized a single E2 dopant. This indicates that spectral narrowing and lifetime enhancement through effective energy transfer between E1 and E2 excited states exhibit a degree of universality within the organic mixtures of the present disclosure.

It should be noted that due to differences in host-dopant compatibility and the influence of the weak microcavity effect in bottom-emission devices, the FWHM of the electroluminescence spectrum in some embodiments may be higher than, lower than, or equal to that of the photoluminescence spectrum in a polystyrene film.

### 5. Preparation of Solutions

According to Table 5, the components of the emissive layer were added to toluene at a concentration of 20 mg/mL. The resulting mixture was then heated under stirring until complete dissolution of the solute was achieved, followed by the filtration to obtain solution 1-solution 18.

TABLE 5

| | Composition of Emissive layer (wt %) |
|---|---|
| Solution 1 | H1-3 (97%):E1-1 (3%) |
| Solution 2 | H1-3 (97%):E2-1 (3%) |
| Solution 3 | H1-3 (97%):E2-2 (3%) |
| Solution 4 | H1-3 (97%):E1-1 (1.5%):E2-1 (1.5%) |
| Solution 5 | H1-3 (97%):E1-1 (1.5%):E2-2 (1.5%) |
| Solution 6 | H1-4 (97%):E1-2 (3%) |
| Solution 7 | H1-4 (97%):E1-3 (3%) |
| Solution 8 | H1-4 (97%):E2-3 (3%) |
| Solution 9 | H1-4 (97%):E2-4 (3%) |
| Solution 10 | H1-4 (97%):E2-5 (3%) |
| Solution 11 | H1-4 (97%):E1-2 (2%):E2-2 (1%) |
| Solution 12 | H1-4 (97%):E1-2 (1.5%):E2-2 (1.5%) |
| Solution 13 | H1-4 (97%):E1-3 (1.5%):E2-2 (1.5%) |
| Solution 14 | H1-4 (97%):E1-2 (1.5%):E2-3 (1.5%) |
| Solution 15 | H1-4 (97%):E1-3 (1.5%):E2-3 (1.5%) |
| Solution 16 | H1-4 (97%):E1-3 (1.5%):E2-4 (1.5%) |
| Solution 17 | H1-4 (97%):E1-2 (1.5%):E2-5 (1.5%) |
| Solution 18 | H1-4 (97%):E1-3 (1.5%):E2-5 (1.5%) |

### 6. Preparation of Solution-Processed P-OLED Devices

In one embodiment, the specific steps are as follows:

1) Cleaning of the ITO transparent electrode (anode) glass substrate: the substrate was ultrasonically treated with a 5% o aqueous solution of Decon90 cleaning agent for 30 min, followed by multiple ultrasonic cleanings with deionized water, then ultrasonically cleaned with isopropanol, and dried with nitrogen gas. The result was treated with oxygen plasma for 5 min to clean the ITO surface and enhance the work function of the ITO electrode.

2) Preparation of the hole-transport layer: PEDOT:PSS solution was spin-coated onto an oxygen plasma-treated glass substrate to obtain a film with a thickness of 80 nm. After spin-coating, the as-fabricated film was annealed at 150° C. in air for 20 min. Subsequently, a 20 nm Poly-TFB (CAS: 223569-31-1, purchased from Lumtec Corp.; 5 mg/mL in toluene) film was deposited onto the PEDOT:PSS layer by spin-coating, followed by thermal treatment on a hot plate at 180° C. for 60 min.

3) Preparation of the emissive layer: the solution used for the emissive layer (see Table 5) was spin-coated in a nitrogen-regulated glove box to form a 35 nm film, which was then annealed at 120° C. for 10 min.

4) Preparation of the electron-transport layer: the resultant substrate was mounted on a vacuum deposition apparatus in high vacuum (1×10⁻⁶ mbar), compound ET and LiQ were placed in two different evaporation units, and co-deposited at a weight ratio of 50:50 to form an electron-transport layer having a thickness of 30 nm.

5) Preparation of the cathode: the spin-coated device was placed in a vacuum evaporation chamber, then 2 nm of barium and 100 nm of aluminum were sequentially deposited as cathode to complete the fabrication of the light-emitting device.

6) All fabricated devices were encapsulated in a nitrogen-regulated glove box using UV-curable resin and a glass cover plate.

As shown in Table 6, the device performance of the device examples and the comparative example were tested; where the driving voltage was measured at a current density of 10 mA/cm²; T95 refers to the relative value of the time at which the luminance of the device examples decreases to 95% of the initial luminance at a constant current density of 20 mA/cm² compared with that of P-OLEDA1.

TABLE 6

| | Solution used for | Driving | T95@J20 |
|---|---|---|---|
| | preparing the | Voltage | (relative |
| | emissive layer | (V) | value) |
| P-OLEDA1 | Solution 1 | 4.51 | 100% |
| P-OLEDA2 | Solution 2 | 4.54 | 75% |
| P-OLEDA3 | Solution 3 | 4.56 | 71% |
| P-OLEDA4 | Solution 4 | 4.52 | 410% |
| P-OLEDA5 | Solution 5 | 4.53 | 304% |

Compared with the Comparative Examples (i.e., P-OLEDA1, P-OLEDA2, and P-OLEDA3), P-OLEDA4 and P-OLEDA5 show no significant difference in driving voltage while exhibiting a substantial extension in operation lifetime. This indicates that for solution-processed OLEDs, the use of the dual emitter as described herein can also significantly extend the device lifetime.

In another embodiment, the specific steps are as follows.

1) Cleaning of the ITO transparent electrode (anode) glass substrate: the substrate was ultrasonically treated with a 5% aqueous solution of Decon90 cleaning agent for 30 min, followed by multiple ultrasonic cleanings with deionized water, then ultrasonically cleaned with isopropanol, and dried with nitrogen gas. The result was treated with oxygen plasma for 5 min to clean the ITO surface and enhance the work function of the ITO electrode.

2) Preparation of the hole-transport layer: PEDOT:PSS solution was spin-coated onto an oxygen plasma-treated glass substrate to obtain a film with a thickness of 80 nm. After spin-coating, the as fabricated film was annealed at 150° C. in air for 20 min. Subsequently, a 20 nm Poly-TFB (CAS: 223569-31-1, purchased from Lumtec Corp.; 5 mg/mL in toluene) film was deposited onto the PEDOT:PSS layer by spin-coating, followed by thermal treatment on a hot plate at 180° C. for 60 min.

3) Preparation of the emissive layer: the solution used for the emissive layer (see Table 5) was spin-coated in a nitrogen-regulated glove box to form a 35 nm film, which was then annealed at 120° C. for 10 min.

4) Preparation of the electron-transport layer: the resultant substrate was mounted on a vacuum deposition apparatus in high vacuum (1×10⁻⁶ mbar), compound ET and LiQ were placed in two different evaporation units, and co-deposited at a weight ratio of 25:75 to form an electron-transport layer having a thickness of 30 nm.

5) Preparation of the cathode: the spin-coated device was placed in a vacuum evaporation chamber, then 1 nm of ytterbium and 100 nm of silver were sequentially deposited as cathode to complete the fabrication of the light-emitting device.

6) All fabricated devices were encapsulated in a nitrogen-regulated glove box using UV-curable resin and a glass cover plate.

As shown in Table 7, the device performance of the device examples and the comparative example were tested; where the EL peak and the EL FWHM were measured at a device brightness of 1000 nits; T95 refers to the relative value of the time at which the luminance of the device examples decreases to 95% of the initial luminance (1000 nits) under constant current operation, compared with that of P-OLEDB1.

TABLE 7

| | Solution used for | EL | EL | LT95@1000 nits |
|---|---|---|---|---|
| | preparing the | peak | FWHM | (relative |
| | emissive layer | (nm) | (nm) | value) |
| P-OLEDB1 | Solution 6 | 461 | 35 | 100% |
| P-OLEDB2 | Solution 7 | 455 | 36 | 102% |
| P-OLEDB3 | Solution 3 | 459 | 20 | 58% |
| P-OLEDB4 | Solution 8 | 465 | 22 | 75% |
| P-OLEDB5 | Solution 9 | 464 | 21 | 64% |
| P-OLEDB6 | Solution 10 | 460 | 21 | 61% |
| P-OLEDB7 | Solution 11 | 460 | 23 | 136% |
| P-OLEDB8 | Solution 12 | 460 | 21 | 124% |
| P-OLEDB9 | Solution 13 | 460 | 20 | 145% |
| P-OLEDB10 | Solution 14 | 463 | 26 | 120% |
| P-OLEDB11 | Solution 15 | 464 | 24 | 143% |
| P-OLEDB12 | Solution 16 | 464 | 22 | 133% |
| P-OLEDB13 | Solution 17 | 460 | 23 | 154% |
| P-OLEDB14 | Solution 18 | 460 | 21 | 167% |

The examples P-OLEDB7-P-OLEDB14 exhibit a significantly prolonged lifetime compared to the comparative examples P-OLEDB1-P-OLEDB6. When compared with P-OLEDB1-P-OLEDB2, they also exhibit a markedly narrowed emission spectrum along with a discernible improvement in device lifetime relative to devices employing a single dopant. These results demonstrate that for solution-processed OLEDs, devices employing the dual-emitter of the present disclosure can achieve an ideal narrow emission spectrum while substantially prolonging the device lifetime.

The various technical features described in the above embodiments may be combined in any manner. For the sake of brevity, not all possible combinations of the technical features in the above embodiments have been described. However, any combination of these technical features that does not conflict with one another shall be deemed to fall within the scope of this specification.

What described above are several embodiments of the present disclosure, and they are specific and in detail, but not intended to limit the scope of the present disclosure. It will be understood that improvements can be made without departing from the concept of the present disclosure, and all these modifications and improvements are within the scope of the present disclosure. The scope of the present disclosure shall be subject to the appended claims.

What is claimed is:

1. An organic mixture, comprising a first emitter E1 and a second emitter E2, wherein,
both the first emitter E1 and the second emitter E2 are fluorescent emitters;
an absorption spectrum of the second emitter E2 at least partially overlaps with an emission spectrum of the first emitter E1; and
a full width at half maximum (FWHM) of the emission spectrum of the second emitter E2 is less than 50 nm.

2. The organic mixture according to claim 1, wherein the second emitter E2 is a compound represented by formula (1) or formula (2): 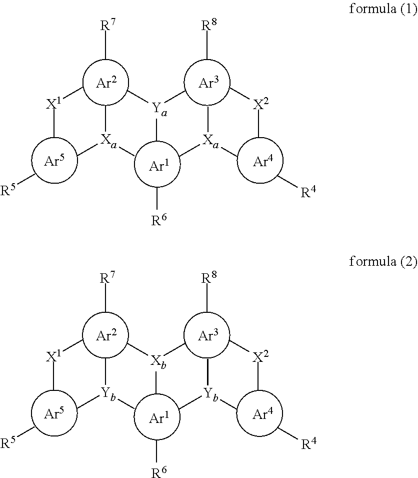
wherein:
each of Ar¹ to Ar³ is independently selected from an aromatic group or a heteroaromatic group containing 5 to 24 ring atoms;
each of Ar⁴ and Ar⁵ is independently selected from null, an aromatic group or a heteroaromatic group containing 5 to 24 ring atoms;
when neither Ar⁴ nor Ar⁵ is null, each of Xₐ and X_{b} is independently selected from N, C(R⁹), or Si(R⁹); each of Yₐ and Y_{b} is independently selected from B, P═O, C(R⁹), or Si(R⁹);
when Ar⁴ and/or Ar⁵ is null, each X_{b} is independently selected from N, C(R⁹), or Si(R⁹);
each Yₐ is independently selected from B, P═O, C(R⁹), or Si(R⁹); each of Xₐ and Y_{b} is independently selected from N(R⁹), C(R⁹R¹⁰), Si(R⁹R¹⁰), C═O, O, C═N(R⁹), C═C(R⁹R¹⁰), P(R⁹) P(═O)R⁹, S, S═O, or SO₂;
each of X¹ and X² is independently null or a bridging group; and
each of R⁴ to R¹⁰ is independently selected from —H, —D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, a disubstituted unit in any position of the above substituents, or any combination thereof, wherein one or more R⁴-R¹⁰ form a monocyclic or polycyclic aliphatic or aromatic ring system with each other and/or with the rings bonded thereto.

3. The organic mixture according to claim 1, wherein the second emitter E2 is selected from the group consisting of:

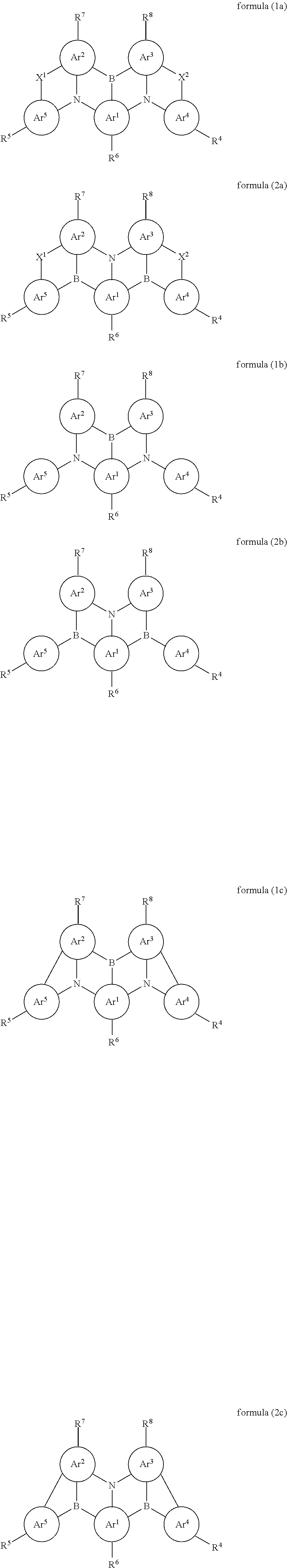

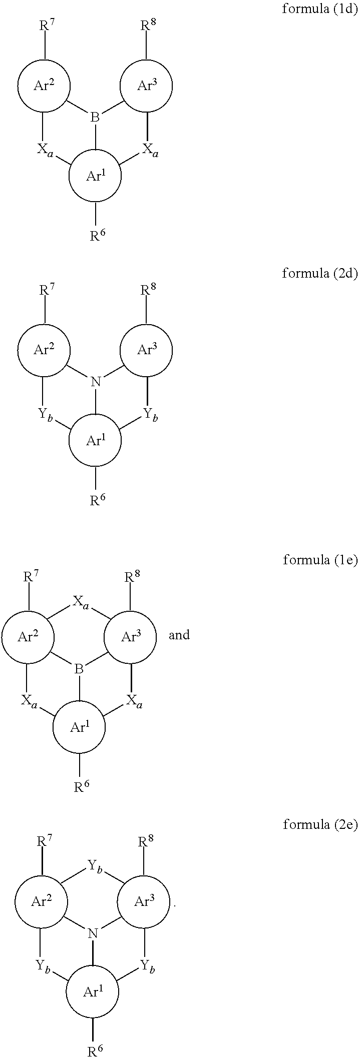

4. The organic mixture according to claim 2, wherein the second emitter E2 is selected from the group consisting of:

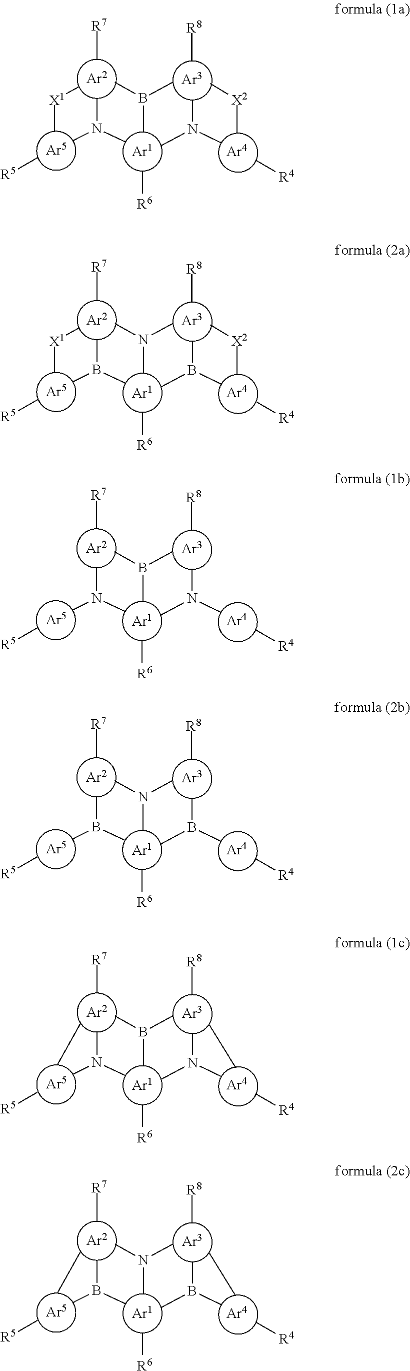

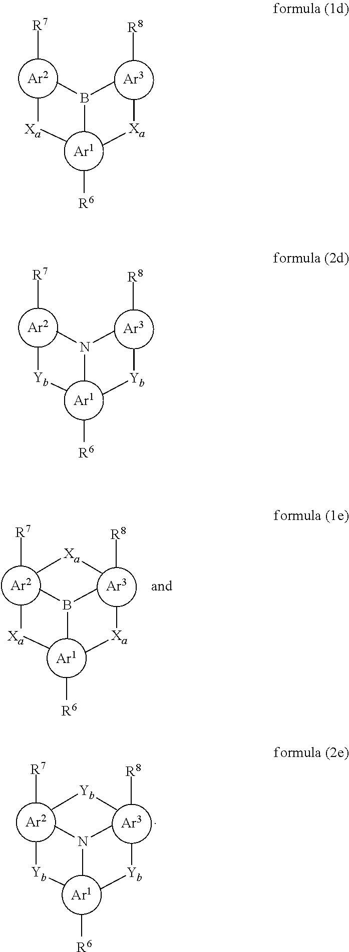

5. The organic mixture according to claim 1, wherein the second emitter E2 is selected from the group consisting of: 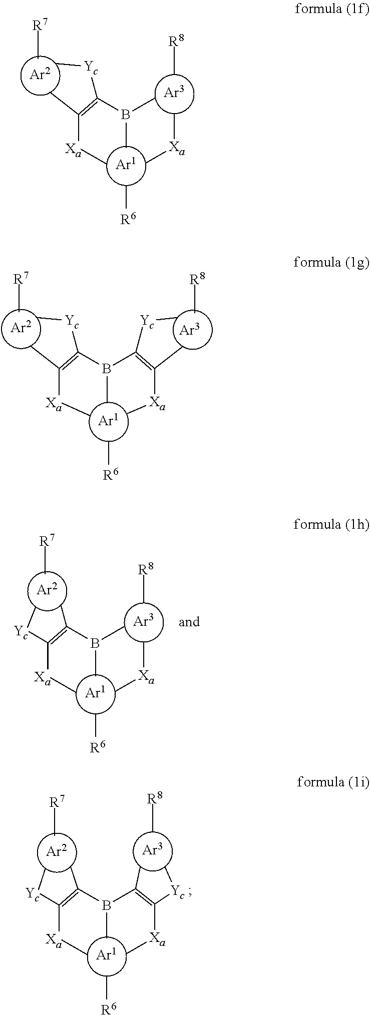
wherein, each Y_{c} is independently O or S.

6. The organic mixture according to claim 2, wherein the second emitter E2 is selected from the group consisting of: 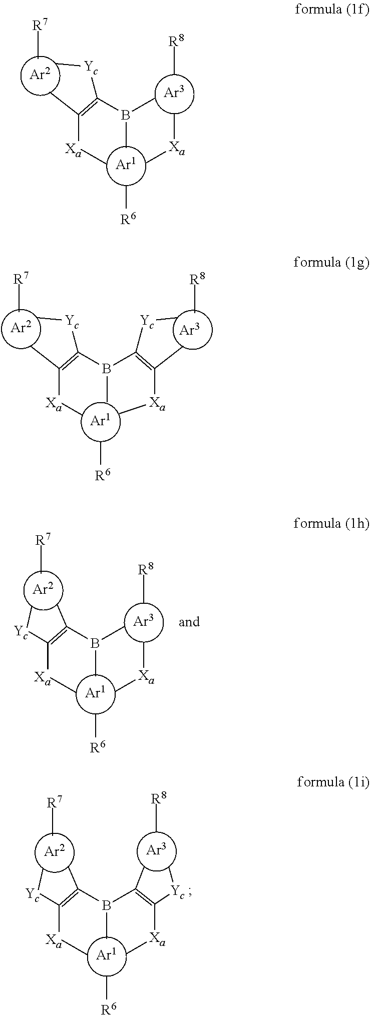
wherein, each Y_{c} is independently O or S.

7. The organic mixture according to claim 3, wherein the second emitter E2 is selected from the group consisting of: 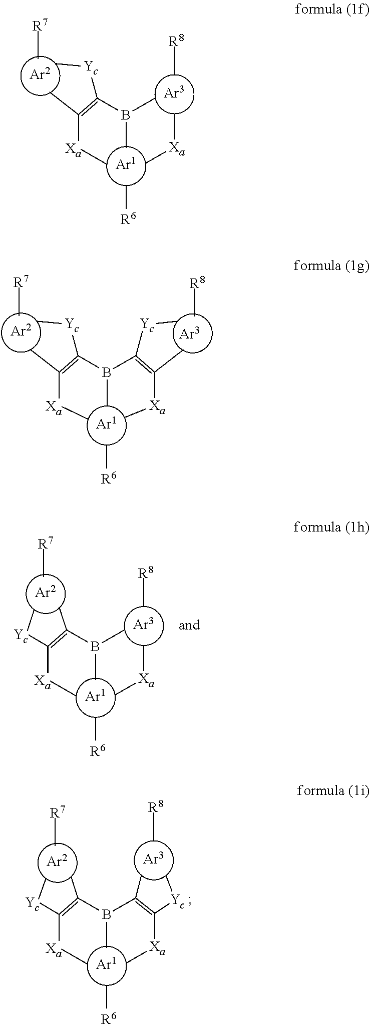
wherein, each Y_{c} is independently O or S.

8. The organic mixture according to claim 4, wherein the second emitter E2 is selected from the group consisting of: 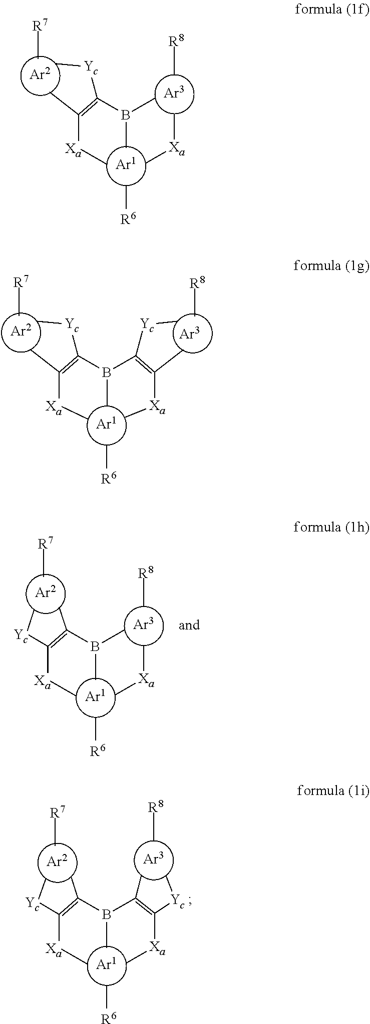
wherein, each Y_{c} is independently O or S.

9. The organic mixture according to claim 1, wherein the second emitter E2 is selected from the group consisting of: 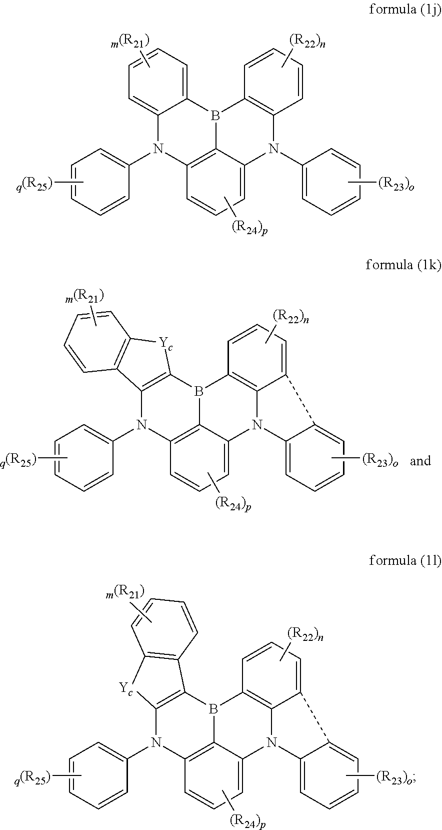
wherein: each of R₂₁ to R₂₅ is independently selected from —D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, —NO₂, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, wherein one or more R₂₁—R₂₅ form a monocyclic or polycyclic aliphatic or aromatic ring system with each other and/or with the rings bonded thereto; m and n are integers from 0 to 4, independently; o and q are integers from 0 to 5, independently; p is an integer from 0 to 3; and each dotted line independently represents null or a single bond.

10. The organic mixture according to claim 1, wherein the first emitter E1 is one of the compounds represented by any one of formulas (1), (2), (1a)-(1l), (2a)-(2e), or formula (3): 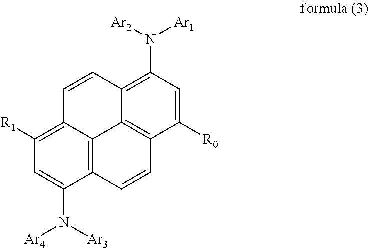
wherein:
each of R₀ and R₁ is independently selected from —H, —D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, a disubstituted unit in any position of the above substituents, or any combination thereof, wherein one or more R₀—R₁ form a monocyclic or polycyclic aliphatic or aromatic ring system with each other and/or with the rings bonded thereto; and
each of Ar₁ to Ar₄ is independently selected from an aromatic group or a heteroaromatic group containing 5 to 60 ring atoms.

11. The organic mixture according to claim 1, further comprising a host material H, wherein the host material H is one of the compounds represented by formula (4-1) or formula (4-2): 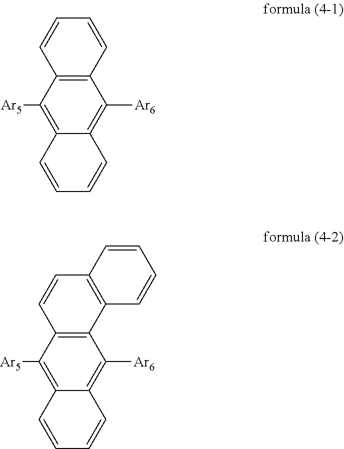
wherein, each of Ar₅ and Ar₆ is independently selected from an aromatic group or a heteroaromatic group containing 5 to 60 ring atoms.

12. A formulation, comprising the organic mixture according to claim 1, and at least one organic solvent.

13. An optoelectronic device, comprising the organic mixture according to claim 1.

14. The optoelectronic device according to claim 13, wherein the optoelectronic device is an organic electroluminescent device comprising a substrate, an anode, an emissive layer, and a cathode in sequence, and the emissive layer comprises at least one of the organic mixture.

15. An optoelectronic device, comprising the formulation according to claim 12.

16. The optoelectronic device according to claim 15, wherein the optoelectronic device is an organic electroluminescent device comprising a substrate, an anode, an emissive layer, and a cathode in sequence, and the emissive layer is formed by using the formulation.
